(19) United States
(12) Patent Application Publication
(10) Pub. No.: US 2026/0080908 A1
(43) Pub. Date: Mar. 19, 2026

(54) MEMORY CIRCUIT AND METHOD OF FORMING THE SAME

(71) Applicant: TAIWAN SEMICONDUCTOR MANUFACTURING COMPANY, LTD., Hsinchu (TW)

(72) Inventors: Yen-Lin CHUNG, Hsinchu (TW); Kao-Cheng LIN, Hsinchu (TW); Wei-Cheng WU, Hsinchu (TW); Pei-Yuan LI, Hsinchu (TW); Chien-Chen LIN, Hsinchu (TW); Chun-Tse CHOU, Hsinchu (TW); Chien Hui HUANG, Hsinchu (TW); Yung-Ning TU, Hsinchu (TW); Shang Lin WU, Hsinchu (TW); Chia-Che CHUNG, Hsinchu (TW); Chia-Chi HUNG, Hsinchu (TW); Kuan-Ying CHIU, Hsinchu (TW); Wei Min CHAN, Hsinchu (TW); Yen-Huei CHEN, Hsinchu (TW)

(21) Appl. No.: 19/018,367

(22) Filed: Jan. 13, 2025

Related U.S. Application Data
(60) Provisional application No. 63/695,605, filed on Sep. 17, 2024.

(51) Int. Cl. G11C 5/06; G11C 11/417

(52) U.S. Cl. CPC G11C 5/063; G11C 11/417

(57) ABSTRACT

A circuit includes a first dual-port cell, a first and second word line, and a first, second and third bit line. The first word line extends in a first direction, is coupled to the first dual-port cell, and is on a first metal layer above a front-side of a substrate. The second word line extends in the first direction, is coupled to the first dual-port cell, and is on a second metal layer below a back-side of the substrate. The first and second bit line extend in the first direction, are coupled to the first dual-port cell, and are on the first metal layer. The third bit line extends in the first direction, is coupled to the first dual-port cell, and is on at least the second metal layer.

### PRIORITY CLAIM

This application claims the benefit of U.S. Provisional Application No. 63/695,605, filed Sep. 17, 2024, which is incorporated herein by reference in its entirety.

### BACKGROUND

The semiconductor integrated circuit (IC) industry has produced a wide variety of digital devices to address issues in a number of different areas. Some of these digital devices, such as memory macros, are configured for the storage of data. As ICs have become smaller and more complex, the resistance of conductive lines within these digital devices are also changed affecting the operating voltages of these digital devices and overall IC performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a block diagram of a memory circuit, in accordance with some embodiments.

FIGS. 2A-2B are corresponding circuit diagrams of corresponding memory cells usable in FIG. 1, in accordance with some embodiments.

FIGS. 3A-3D are corresponding diagrams of corresponding portions of a layout design of a corresponding integrated circuit, in accordance with some embodiments.

FIGS. 4A-4I are diagrams of an integrated circuit, in accordance with some embodiments.

FIG. 5 is a diagram of a layout design of an integrated circuit, in accordance with some embodiments.

FIG. 6 is a diagram of an integrated circuit, in accordance with some embodiments.

FIG. 7 is a block diagram of an integrated circuit, in accordance with some embodiments.

FIG. 8 is a circuit diagram of an integrated circuit, in accordance with some embodiments.

FIGS. 9A-9B are diagrams of an integrated circuit, in accordance with some embodiments.

FIGS. 10A-10B are diagrams of an integrated circuit, in accordance with some embodiments.

FIG. 11 is a timing diagram of waveforms of a memory cell, in accordance with some embodiments.

FIG. 12 is a functional flow chart of a method of manufacturing an integrated circuit, in accordance with some embodiments.

FIG. 13 is a flow chart of a method of manufacturing an integrated circuit, in accordance with some embodiments.

FIG. 14 is a flowchart of a method of generating a layout design of an integrated circuit, in accordance with some embodiments.

FIG. 15 is a schematic view of a system for designing an IC layout design and manufacturing an IC circuit, in accordance with some embodiments.

FIG. 16 is a block diagram of an IC manufacturing system, and an IC manufacturing flow associated therewith, in accordance with at least one embodiment of the present disclosure.

FIG. 17A is a schematic diagram of a memory device, in accordance with some embodiments.

FIG. 17B is a schematic diagram of a neural network, in accordance with some embodiments.

FIG. 17C is a schematic diagram of an integrated circuit (IC) device, in accordance with some embodiments.

### DETAILED DESCRIPTION

The following disclosure provides different embodiments, or examples, for implementing features of the provided subject matter. Specific examples of components, materials, values, steps, arrangements, or the like, are described below to simplify the present disclosure. These are, of course, merely examples and are not limiting. Other components, materials, values, steps, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In accordance with some embodiments, a memory circuit includes a first dual-port memory cell.

In some embodiments, the memory circuit further includes a first word line. In some embodiments, the first word line extends in a first direction, and is coupled to the first dual-port memory cell. In some embodiments, the first word line is on at least a first metal layer above a front-side of a substrate.

In some embodiments, the memory circuit further includes a second word line. In some embodiments, the second word line extends in the first direction and is coupled to the first dual-port memory cell. In some embodiments, the second word line is on at least a second metal layer below a back-side of the substrate opposite from the front-side of the substrate.

In some embodiments, the memory circuit further includes a first bit line. In some embodiments, the first bit line extends in the first direction and is coupled to the first dual-port memory cell. In some embodiments, the first bit line is on at least the first metal layer.

In some embodiments, the memory circuit further includes a second bit line. In some embodiments, the second bit line extends in the first direction and is coupled to the first dual-port memory cell. In some embodiments, the second bit line is on at least the first metal layer. In some embodiments, the second bit line is separated from the first bit line in a second direction different from the first direction.

In some embodiments, the memory circuit further includes a third bit line. In some embodiments, the third bit line extends in the first direction and is coupled to the first dual-port memory cell. In some embodiments, the third bit line is on at least the second metal layer.

In some embodiments, the memory circuit further includes a second dual-port memory cell. In some embodiments, the second dual-port memory cell and the first dual-port memory cell are directly next to each other. In some embodiments, the memory circuit does not include one or more strap cells between the first dual-port memory cell and the second dual-port memory cell.

In some embodiments, by the memory circuit not including one or more strap cells, the memory circuit occupies less area than other approaches utilizing strap cells.

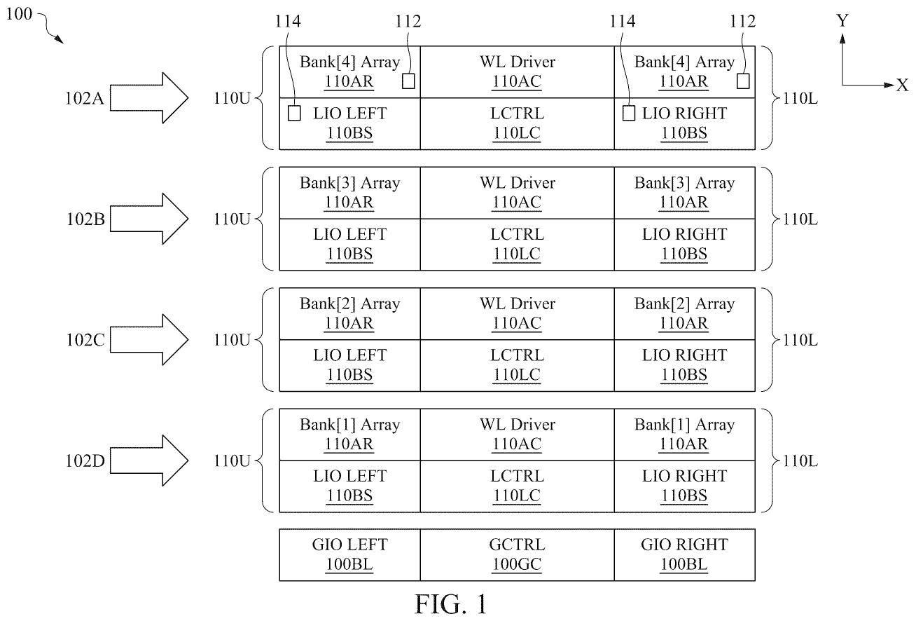

FIG. 1 is a block diagram of a memory circuit 100, in accordance with some embodiments.

FIG. 1 is simplified for the purpose of illustration. In some embodiments, memory circuit 100 includes various elements in addition to those depicted in FIG. 1 or is otherwise arranged to perform the operations discussed below.

Memory circuit 100 is an IC that includes memory partitions 102A-102D, a global control circuit 100GC and global input output (GIO) circuits 100BL.

Each memory partition 102A-102D includes memory banks 110U and 110L adjacent to a word line (WL) driver circuit 110AC and a local control circuit 110LC. Each memory bank 110U and 110L includes a memory cell array 110AR and a local input output (LIO) circuit 110BS.

A memory partition, e.g., a memory partition 102A-102D, is a portion of memory circuit 100 that includes a subset of memory devices (not shown in FIG. 1) and adjacent circuits configured to selectively access the subset of memory devices in program and read operations. In the FIG. 1 embodiment, memory circuit 100 includes a total of four partitions. In some embodiments, memory circuit 100 includes a total number of partitions greater or fewer than four.

GIO circuit 100BL is configured to control access to one or more electrical paths, e.g., bit lines, to each memory device of the corresponding memory bank 110U or 110L of each memory partition 102A-102D, e.g., by generating one or more bit line signals. In some embodiments, GIO circuit 100BL includes a global bit line driver circuit. In some embodiments, GIO circuit 100BL is coupled to each memory bank 110U and 110L by a corresponding global bit line (not shown).

Global control circuit 100GC is configured to control some or all of program and read operations on each memory partition 102A-102D, e.g., by generating and/or outputting one or more control and/or enable signals.

In some embodiments, global control circuit 100GC includes one or more analog circuits configured to interface with memory partitions 102A-102D, cause data to be programmed in one or more memory devices, and/or use data received from one or more memory devices in one or more circuit operations. In some embodiments, global control circuit 100GC includes one or more global address decoder or pre-decoder circuits configured to output one or more address signals to the WL driver circuit 110AC of each memory partition 102A-102D.

Each WL driver circuit 110AC is configured to generate word line signals on corresponding word lines WL. In some embodiments, each WL driver circuit 110AC is configured to output word line signals on corresponding word lines WL to the adjacent memory banks 110U and 110L of the corresponding memory partition 102A-102D.

Each local control circuit 110LC is an electronic circuit configured to receive one or more address signals. Each local control circuit 110LC is configured to generate signals corresponding to adjacent subsets of memory devices identified by the one or more address signals. In some embodiments, the adjacent subsets of memory devices correspond to columns of memory devices. In some embodiments, each local control circuit 110LC is configured to generate each signal as a complementary pair of signals. In some embodiments, each local control circuit 110LC is configured to output the signals to corresponding word line driver circuits within the adjacent WL driver circuit 110AC of the corresponding memory partition 102A-102D. In some embodiments, the local control circuit 110LC includes a bank decoder circuit.

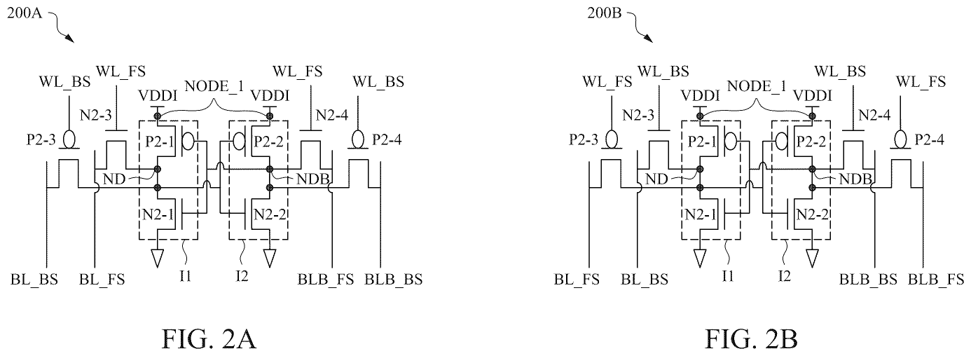

Each LIO circuit 110BS is configured to selectively access one or more bit lines (shown in FIGS. 2A-2B) coupled to adjacent subsets of memory devices of the corresponding memory cell array 110AR responsive to GIO circuit 100BL, e.g., based on one or more BL control signals. In some embodiments, the adjacent subsets of memory devices correspond to rows of memory devices. In some embodiments, the LIO circuit 110BS includes a bit line selection circuit.

Each LIO circuit 110BS includes one or more circuits 114. For case of illustration, circuit 114 is not shown in memory bank 110U and 110L of memory partitions 102B, 102C and 102D. In some embodiments, each circuit 114 includes at least a sense amplifier circuit. In some embodiments, during a read operation, the sense amplifier circuit is configured to read data from at least one memory cell 112 in a corresponding column of memory cells in the corresponding memory cell array 110AR, in accordance with some embodiments. In some embodiments, each circuit 114 in LIO circuit 110BS is coupled to a corresponding column of memory devices 112 in memory cell array 110AR.

Each memory bank 110U and 110L includes the corresponding memory cell array 110AR including memory cells or memory devices 112 configured to be accessed in program and read operations by the adjacent LIO circuit 110BS and the adjacent WL driver circuit 110AC.

Each memory cell array 110AR includes an array of memory devices 112 having N rows and M columns, where M and N are positive integers. The rows of cells in memory cell array 102 are arranged in a first direction X. The columns of cells in memory cell array 102 are arranged in a second direction Y. The second direction Y is different from the first direction X. In some embodiments, the second direction Y is perpendicular to the first direction X. In some embodiments, each memory cell array 110AR is divided into an upper region and a lower region (not shown). In some embodiments, each column of memory devices 112 in memory cell array 110AR is coupled to a corresponding circuit 114 in LIO circuit 110BS.

Memory device 112 is shown in memory bank 110U and 110L of memory partition 102A. For case of illustration, memory device 112 is not shown in memory bank 110U and 110L of memory partitions 102B, 102C and 102D.

Memory device 112 is an electrical, electromechanical, electromagnetic, or other device configured to store bit data represented by logical states. At least one logical state of memory device 112 is capable of being programmed in a write operation and detected in a read operation. In some embodiments, a logical state corresponds to a voltage level of an electrical charge stored in a given memory device 112. In some embodiments, a logical state corresponds to a physical property, e.g., a voltage, a current, a resistance or a magnetic orientation, of a component of a given memory device 112.

In some embodiments, memory device 112 includes one or more dual port (DP) static random access memory (SRAM) cells. In some embodiments, memory device 112 includes one or more single port (SP) SRAM cells. In some embodiments, memory device 112 includes one or more multi-port SRAM cells. Different types of memory cells in memory device 112 are within the contemplated scope of the present disclosure. In some embodiments, memory device 112 includes one or more dynamic random access memory (DRAM) cells. In some embodiments, memory device 112 includes one or more one-time programmable (OTP) memory devices such as electronic fuse (eFuse) or anti-fuse devices, flash memory devices, random-access memory (RAM) devices, resistive RAM devices, ferroelectric RAM devices, magneto-resistive RAM devices, erasable programmable read only memory (EPROM) devices, electrically erasable programmable read only memory (EEPROM) devices, or the like. In some embodiments, memory device 112 is an OTP memory device including one or more OTP memory cells.

Other configurations of memory circuit 100 are within the scope of the present disclosure.

FIGS. 2A-2B are corresponding circuit diagrams of corresponding memory cells 200A and 200B usable in FIG. 1, in accordance with some embodiments.

FIG. 2A is a circuit diagram of a memory cell 200A usable in FIG. 1, in accordance with some embodiments.

At least one of memory cell 200A or 200B is usable as one or more memory cells MCB in at least one of memory cell array 110AR of FIG. 1 or memory device 112 of FIG. 1.

At least one of memory cell 200A or 200B is an eight transistor (8T) dual port (DP) SRAM memory cell. In some embodiments, at least one of memory cell 200A or 200B employs a number of transistors other than eight. Other types of memory are within the scope of various embodiments. In some embodiments, a dual port memory cell is a type of RAM that is configured to support multiple reads or writes occurring at the same time at different addresses within a memory cell array (e.g., memory cell array 110AR in FIG. 1). In some embodiments, a dual-port memory cell is configured to support two memory cell accesses (e.g., reads or writes) per clock cycle.

Memory cell 200A comprises P field effect transistors (PFET) P2-1, P2-2, P2-3 and P2-4, and NFET transistors N2-1, N2-2, N2-3, and N2-4. PFET transistors P2-1 and P2-2 and NFET transistors N2-1 and N2-2 form a cross latch or a pair of cross-coupled inverters. For example, PFET transistor P2-1 and NFET transistor N2-1 form a first inverter while PFET transistor P2-2 and NFET transistor N2-2 form a second inverter.

A source terminal of each of PFET transistors P2-1 and P2-2 is configured as a voltage supply node NODE_1. Each voltage supply node NODE_1 is coupled to a first voltage supply VDDI.

Each of a drain terminal of PFET transistor P2-1, a drain terminal of NFET transistor N2-1, a gate terminal of PFET transistor P2-2, a gate terminal of NFET transistor N2-2, a source terminal of NFET transistor N2-3 and a source terminal of PFET transistor P2-3 are coupled together, and are configured as a storage node ND.

Each of a drain terminal of PFET transistor P2-2, a drain terminal of NFET transistor N2-2, a gate terminal of PFET transistor P2-1, a gate terminal of NFET transistor N2-1, a source terminal of NFET transistor N2-4 and a source terminal of PFET transistor P2-4 are coupled together, and are configured as a storage node NDB.

A source terminal of each of NFET transistors N2-1 and N2-2 is configured as a supply reference voltage node (not labelled) having a supply reference voltage VSS. The source terminal of each of NFET transistors N2-1 and N2-2 is also coupled to reference voltage supply VSS.

A word line WL_FS is coupled with a gate terminal of each of NFET transistors N2-3 and N2-4. Word line WL_FS is also called a write control line because NFET transistors N2-3 and N2-4 are configured to be controlled by a signal on word line WL_FS in order to transfer data between bit lines BL_FS, BL_BS and corresponding nodes ND, NDB.

A word line WL_BS is coupled with a gate terminal of each of PFET transistors P2-3 and P2-4. Word line WL_BS is also called a write control line because PFET transistors P2-3 and P2-4 are configured to be controlled by a signal on word line WL_BS in order to transfer data between bit lines BL_FS, BL_BS and corresponding nodes ND, NDB.

In some embodiments, the signal of the word line WL_BS is equal to a voltage supply VDD. In some embodiments, when the signal of the word line WL_BS is equal to the voltage supply VDD, the PFET transistors P2-3 and P2-4 are turned off.

A drain terminal of NFET transistor N2-3 is coupled to a bit line BL_FS. A drain terminal of NFET transistor N2-4 is coupled to a bit line bar BLB_FS. A drain terminal of PFET transistor P2-3 is coupled to the bit line BL_BS. A drain terminal of PFET transistor P2-4 is coupled to the bit line bar BLB_BS.

Bit lines BL_FS and BL_BS and bit line bars BLB_FS or BLB_BS are configured as both data input and output for memory cell 200A-200B. In some embodiments, in a write operation, applying a logical value to bit line BL_FS and the opposite logical value to bit line bar BLB_FS enables writing the logical values on the bit lines to memory cell 200A-200B. In some embodiments, in a write operation, applying a logical value to bit line BL_BS and the opposite logical value to bit line bar BLB_BS enables writing the logical values on the bit lines to memory cell 200A-200B.

Each of bit lines BL_FS or BL_BS and bit line bar BLB_FS or BLB_BS is called a data line because the data carried on bit lines BL_FS or BL_BS and bit line bar BLB_FS or BLB_BS are written to and read from corresponding nodes ND and NDB.

In some embodiments, memory cell 200A is a dual port memory cell, where word line WL_FS is a first word line (e.g., WL1), word line WL_BS is a second word line (e.g., WL2), bit line BL_FS is a first bit line (e.g., BL1), bit line WL_BS is a second bit line (e.g., BL2), bit line bar BLB_FS is a first bit line (e.g., BLB1) and bit line bar BLB_BS is a second bit line bar (e.g., BLB2).

Other configurations of memory cell 200A are within the scope of the present disclosure.

FIG. 2B is a circuit diagram of a memory cell 200B usable in FIG. 1, in accordance with some embodiments.

Memory cell 200B is a variation of memory cell 200A of FIG. 2A, and similar detailed description is therefore omitted. In comparison with memory cell 200A of FIG. 2A, the word lines WL_FS and WL_BS in FIG. 2B are flipped with the corresponding word lines WL_BS and WL_FS in FIG. 2A, and similar detailed description is therefore omitted.

In comparison with memory cell 200A of FIG. 2A, the bit lines BL_FS and BL_BS in FIG. 2B are flipped with the corresponding bit lines BL_BS and BL_FS in FIG. 2A, and similar detailed description is therefore omitted.

In comparison with memory cell 200A of FIG. 2A, the bit line bars BLB_FS and BLB_BS in FIG. 2B are flipped with the corresponding bit line bars BLB_BS and BLB_FS in FIG. 2A, and similar detailed description is therefore omitted.

In FIG. 2B, word line WL_BS is coupled with a gate terminal of each of NFET transistors N2-3 and N2-4.

In FIG. 2B, word line WL_FS is coupled with a gate terminal of each of PFET transistors P2-3 and P2-4.

In FIG. 2B, the drain terminal of NFET transistor N2-3 is coupled to a bit line BL_BS, and the drain terminal of NFET transistor N2-4 is coupled to a bit line bar BLB_BS.

In FIG. 2B, the drain terminal of PFET transistor P2-3 is coupled to the bit line BL_FS, and the drain terminal of PFET transistor P2-4 is coupled to the bit line bar BLB_FS.

In some embodiments, memory cell 200B is a dual port memory cell, where word line WL_BS is a first word line (e.g., WL1), word line WL_FS is a second word line (e.g., WL2), bit line BL_BS is a first bit line (e.g., BL1), bit line WL_FS is a second bit line (e.g., BL2), bit line bar BLB_BS is a first bit line (e.g., BLB1) and bit line bar BLB_FS is a second bit line bar (e.g., BLB2).

Other configurations of memory cell 200B are within the scope of the present disclosure.

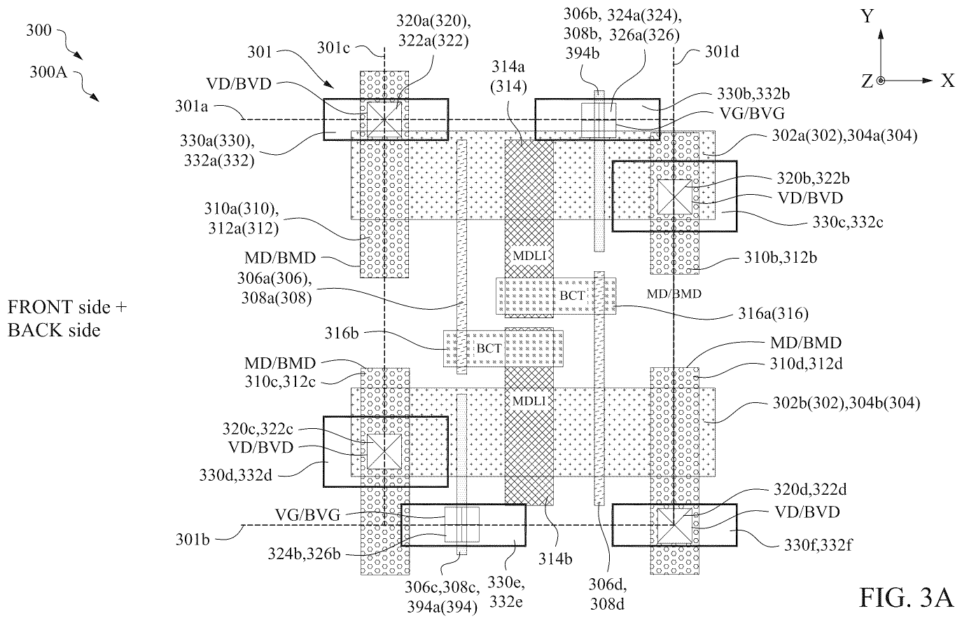

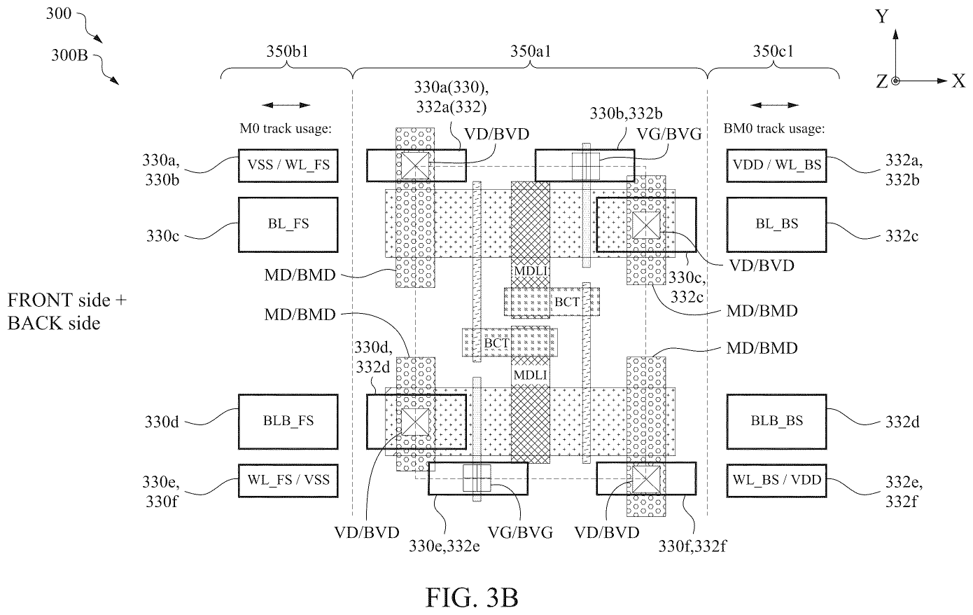

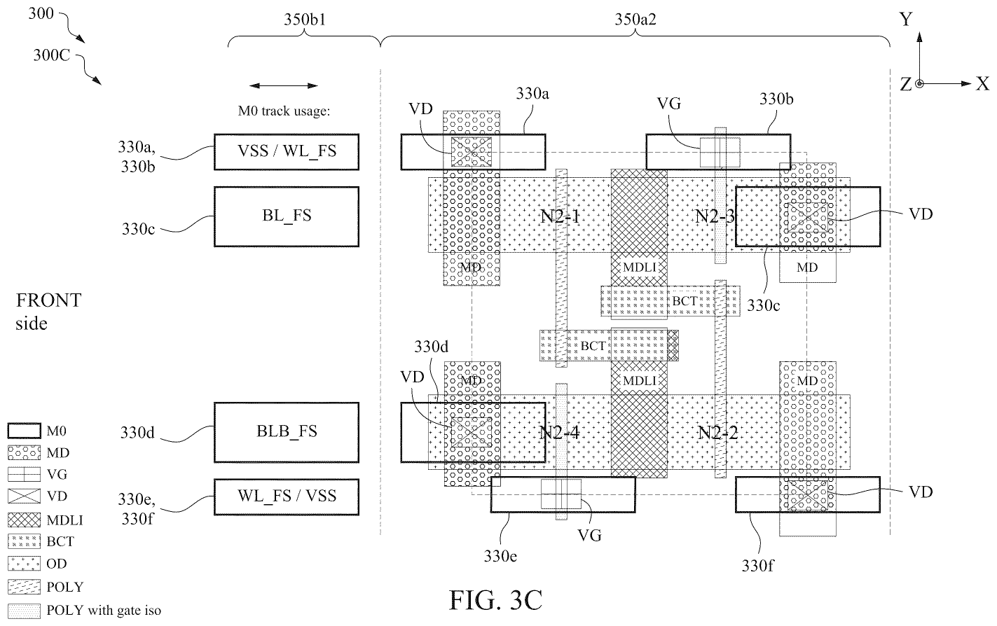

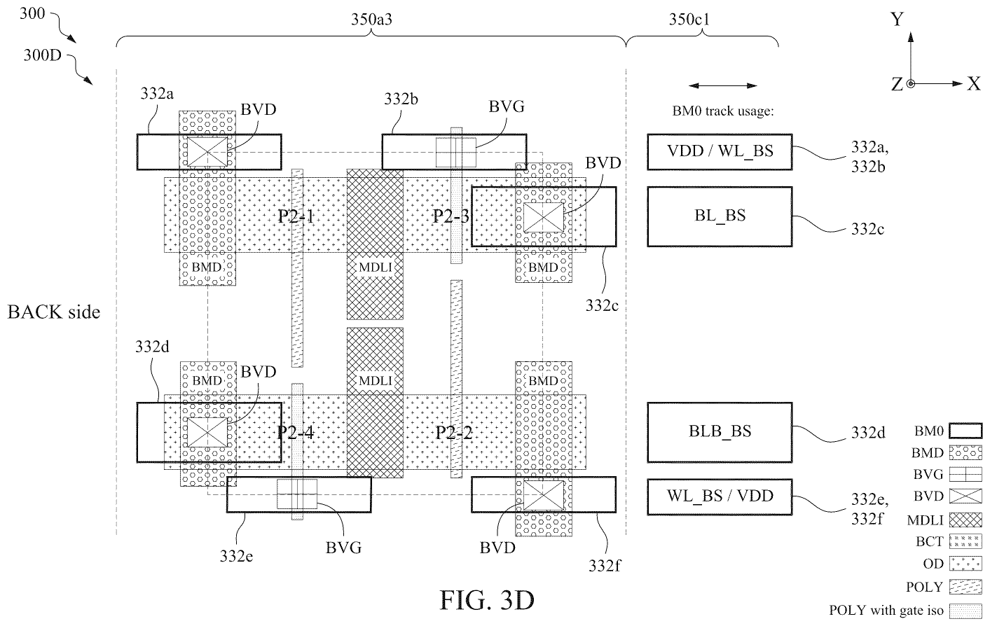

FIGS. 3A-3D are corresponding diagrams of corresponding portions 300A-300D of a layout design 300 of a corresponding integrated circuit, in accordance with some embodiments.

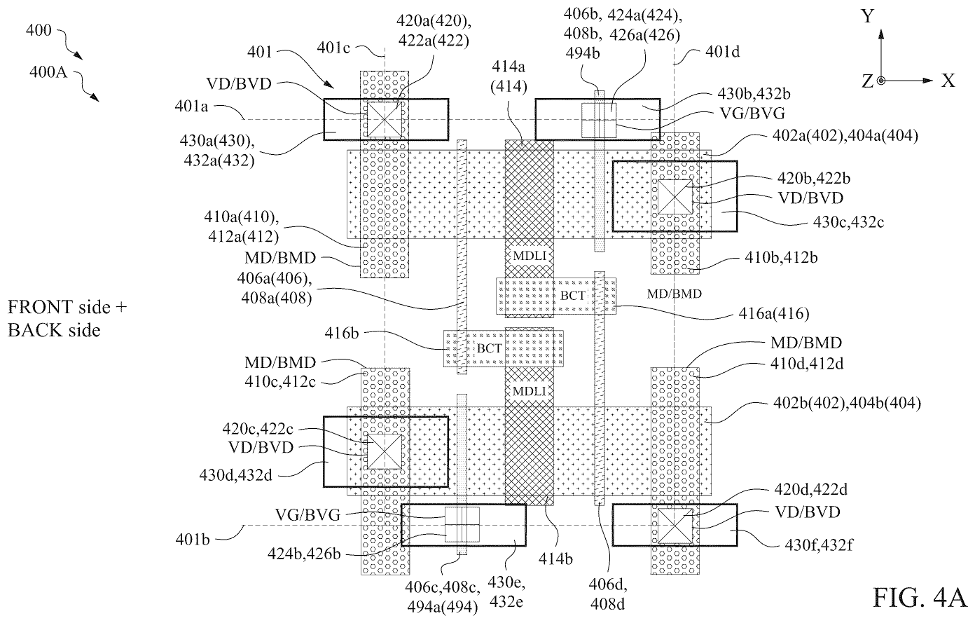

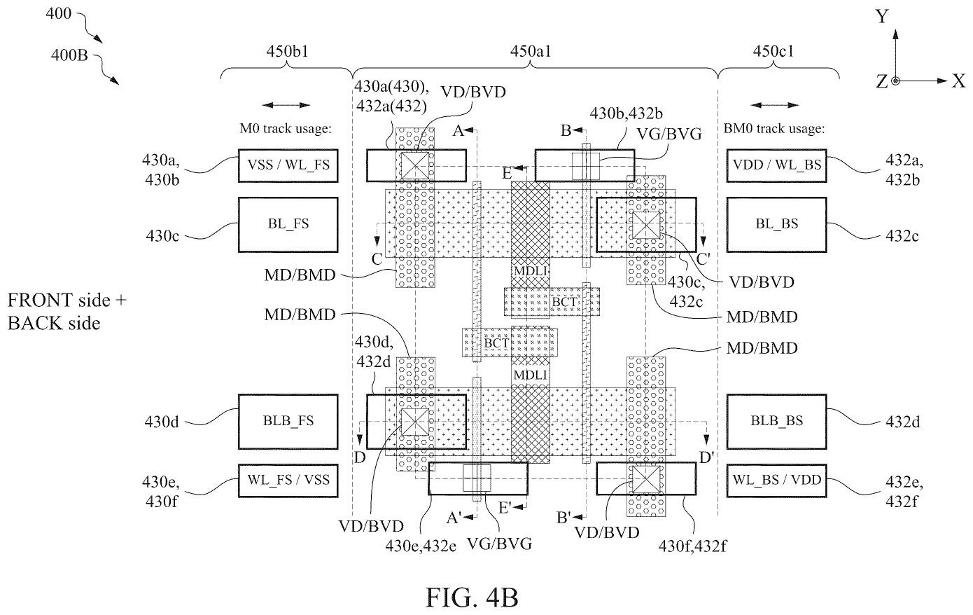

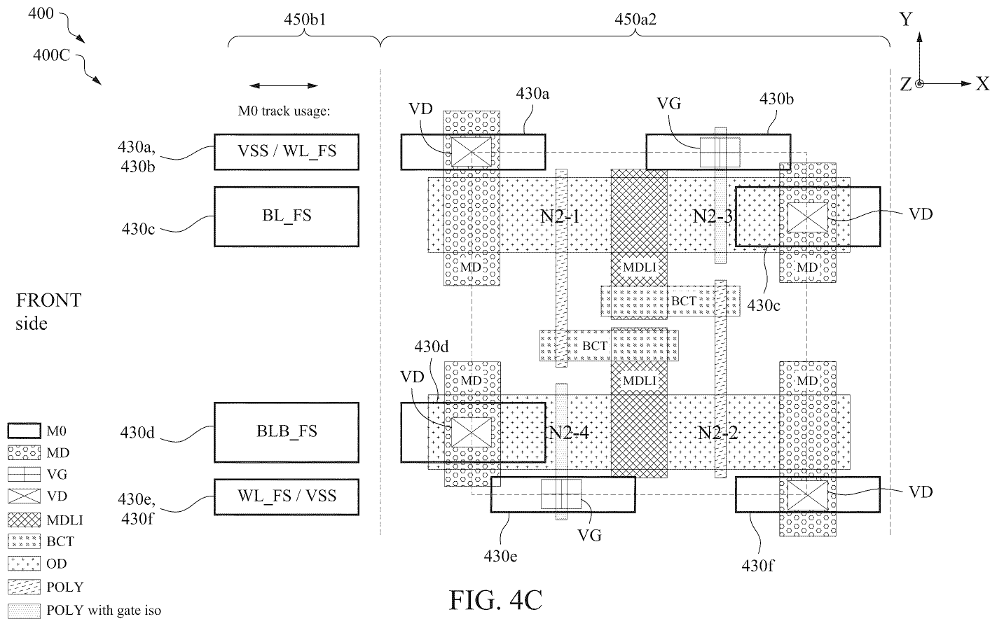

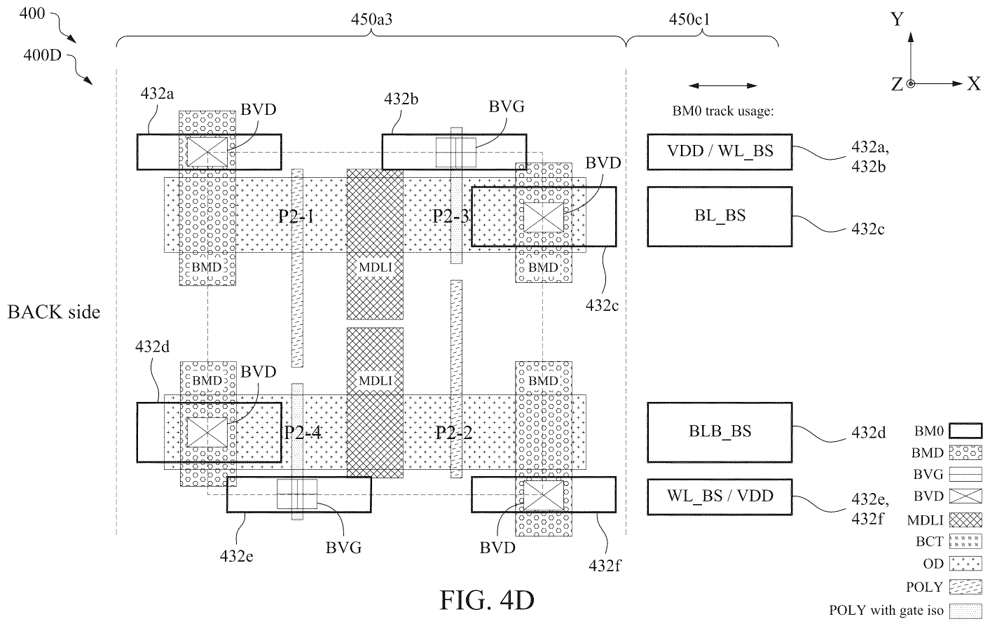

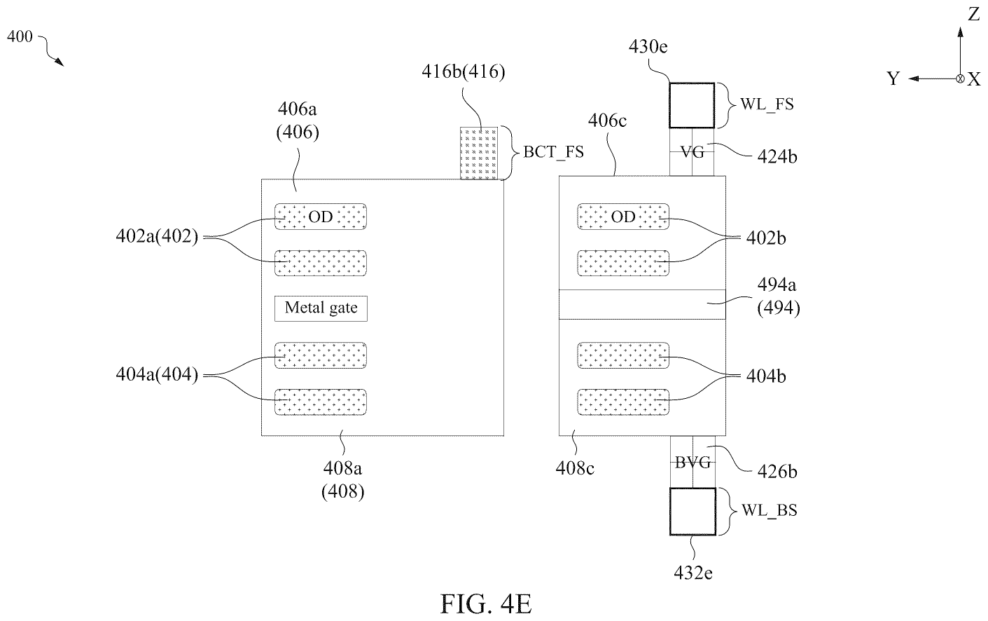

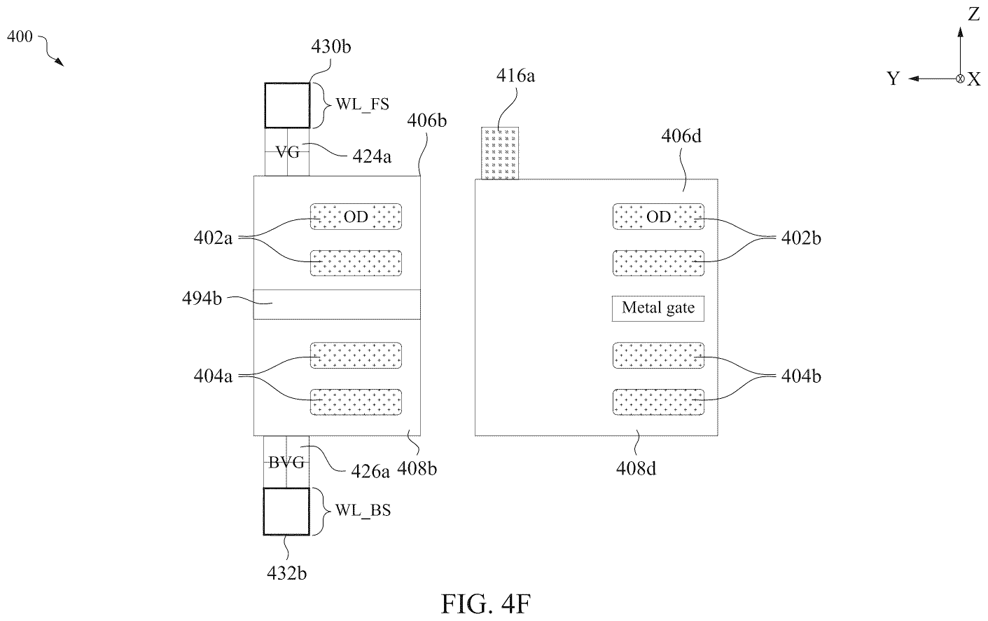

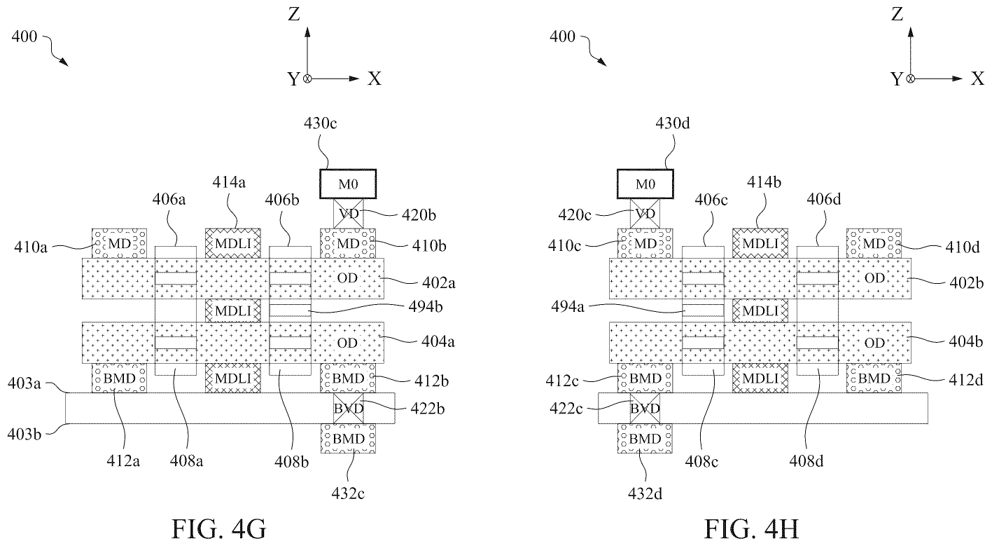

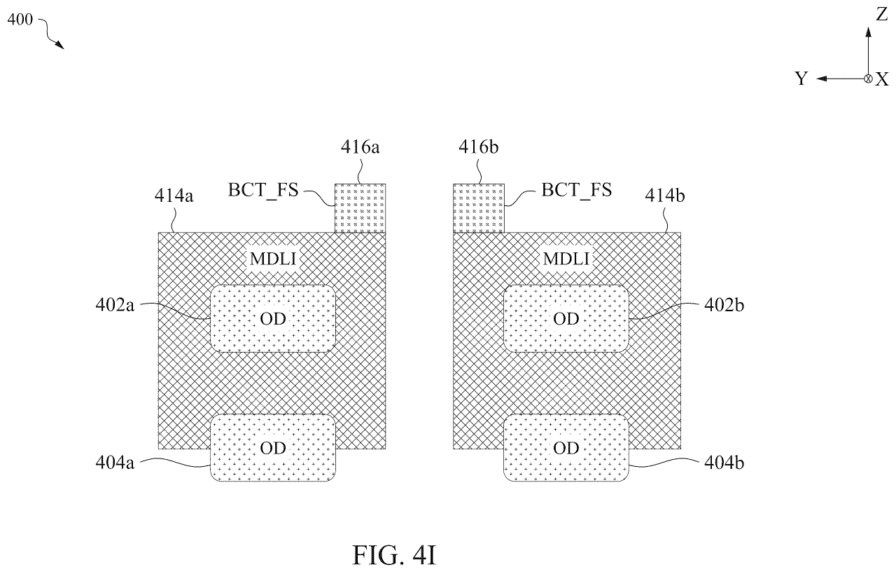

Layout design 300 is a layout of an integrated circuit 400 of FIGS. 4A-4I or memory cell 200A. Layout design 300 is a layout of memory cell 200A of FIG. 2A.

Portion 300A includes one or more features of layout design 300 of an active level or an oxide diffusion (OD) level, a gate (POLY) level, a metal over diffusion (MD) level, a backside metal over diffusion (BMD) level, a metal over diffusion local interconnect (MDLI) level, a butted contact (BCT) level, a metal 0 (M0) level, a backside metal 0 (BM0) level, a via over gate (VG) level, a backside via over gate (BVG) level, a via over diffusion (VD) level, and a backside via over diffusion (BVD) level.

Portion 300B includes one or more features of layout design 300 of the OD level, the POLY level, the MD level, the MDLI level, the BCT level, the M0 level, the VG level, the VD level, the BMD level, the BM0 level, the BVG level, and the BVD level.

Portion 300C includes one or more features of layout design 300 of the OD level, the POLY level, the MD level, the MDLI level, the BCT level, the M0 level, the VG level and the VD level.

Portion 300D include one or more features of layout design 300 of the OD level, the POLY level, the BMD level, the MDLI level, the BCT level, the BM0 level, the BVG level, and the BVD level.

FIGS. 3A-3D are corresponding diagrams of corresponding portions 300A-300D of layout design 300, simplified for ease of illustration.

For case of illustration, some of the labeled elements of one or more of FIGS. 1-6 are not labelled in one or more of FIGS. 1-6. In some embodiments, layout design 300 includes additional elements not shown in FIGS. 3A-3D.

Layout design 300 includes one or more features of the OD level, the POLY level, the MD level, the M0 level, the VG level, the VD level, the MI level, the VO level, the BMD level, the BM0 level, the BVG level and the BVD level. In some embodiments, at least layout design 300 or 500, or integrated circuit 400 or 600 includes additional elements not shown in FIGS. 3A-3D, 4A-4I, 5 or 6.

Layout design 300 is usable to manufacture integrated circuit 400 of FIGS. 4A-4I.

Portion 300A is a layout of portion 400A of integrated circuit 400 of FIG. 4A, portion 300B is a layout of portion 400B of integrated circuit 400 of FIG. 4B, portion 300C is a layout of portion 400C of integrated circuit 400 of FIG. 4C, and portion 300D is a layout of portion 400D of integrated circuit 400 of FIG. 4D, and similar detailed description is omitted for brevity.

Layout design 300 includes a cell 301. The cell 301 has cell boundaries 301a and 301b that extend in a first direction X, and cell boundaries 301c and 301d that extend in a second direction Y. In some embodiments, at least one of the first direction X, the second direction Y or a third direction Z is different from another of the first direction X, the second direction Y or the third direction Z. In some embodiments, layout design 300 abuts other cell layout designs (not shown) along cell boundaries 301c and 301d. In some embodiments, layout design 300 abuts other cell layout designs (not shown) along cell boundaries 301a and 301b that extend in the first direction X. In some embodiments, layout design 300 is a single height standard cell. In some embodiments, cell 301 is useable to manufacture a cell 401.

In some embodiments, cell 301 is a standard cell, and layout design 300 corresponds to a layout of a standard cell defined by cell boundaries 301a, 301b, 301c and 301d. In some embodiments, a cell 301 is a predefined portion of layout design 300 including one or more transistors and electrical connections configured to perform one or more circuit functions. In some embodiments, cell 301 is bounded by cell boundaries 301a, 301b, 301c and 301d, and thus corresponds to a region of functional circuit components or devices that are part of a standard cell. In some embodiments, layout design 300 is a layout design of a memory cell, such as memory cell 200A of FIG. 2A or 200B of FIG. 2B.

Layout design 300 includes one or more active region layout patterns 302a or 302b (collectively referred to as a “set of active region patterns 302”) or one or more active region layout patterns 304a or 304b (collectively referred to as a “set of active region patterns 304”) extending in the first direction X.

Embodiments of the present disclosure use the term “layout pattern” which is hereinafter also referred to as “patterns” in the remainder of the present disclosure for brevity.

The set of active region patterns 302 is above the set of active region patterns 304.

Active region patterns 302a and 302b of the set of active region patterns 302 are separated from one another in the second direction Y. Active region patterns 304a and 304b of the set of active region patterns 304 are separated from one another in the second direction Y.

Active region patterns 302a and 304a are separated from one another in a third direction Z. Active region patterns 302b and 304b are separated from one another in the third direction Z.

The set of active region patterns 302 is usable to manufacture a corresponding set of active regions 402 of integrated circuit 100, 200A, 200B, 400 or 600. The set of active region patterns 304 is usable to manufacture a corresponding set of active regions 404 of integrated circuit 100, 200A, 200B, 400 or 600.

In some embodiments, at least one of the set of active regions 402 or 404 are located on the front-side 403a of integrated circuit 100, 200A, 200B, 400 or 600. In some embodiments, at least one of the set of active regions 402 or 404 corresponds to source and drain regions of one or more complementary FET (CFET) transistors. In some embodiments, at least one of the set of active regions 402 or 404 correspond to source and drain regions of one or more nanosheet transistors or nanowire transistors. Other transistor types are within the scope of the present disclosure. In some embodiments, at least one of the set of active regions 402 or 404 corresponds to source and drain regions of one or more finFET transistors.

In some embodiments, active region patterns 302a, 302b are usable to manufacture corresponding active regions 402a, 402b of the set of active regions 402 of integrated circuit 100, 200A, 200B, 400 or 600. In some embodiments, active region patterns 304a, 304b are usable to manufacture corresponding active regions 404a, 404b of the set of active regions 404 of integrated circuit 100, 200A, 200B, 400 or 600.

In some embodiments, the set of active region patterns 302 and 304 are referred to as an oxide diffusion (OD) region which defines the source or drain diffusion regions of at least integrated circuit 100, 200A, 200B, 400 or 600 or layout design 300 or 500.

In some embodiments, active region patterns 302a and 302b are usable to manufacture source and drain regions of NFET transistors of integrated circuits 100, 200A, 200B, 400 or 600, and active region patterns 304a and 304b are usable to manufacture source and drain regions of PFET transistors of integrated circuits 100, 200A, 200B, 400 or 600.

In some embodiments, active region patterns 302a and 302b are usable to manufacture source and drain regions of PFET transistors of integrated circuits 100, 200A, 200B, 400 or 600, and active region patterns 304a and 304b are usable to manufacture source and drain regions of NFET transistors of integrated circuits 100, 200A, 200B, 400 or 600.

In some embodiments, the set of active region patterns 302 or 304 is located on a first layout level. In some embodiments, the first layout level corresponds to an active level or an OD level of one or more of layout design 300 or 500 or integrated circuits 100, 200A, 200B, 400 or 600. In some embodiments, the OD level is above the BM0 and the BMI level.

Other configurations, arrangements on other layout levels or quantities of patterns in the set of active region patterns 302 or 304 are within the scope of the present disclosure.

Layout design 300 further includes one or more gate patterns 306a, 306b, 306c or 306d (collectively referred to as a “set of gate patterns 306”), one or more gate patterns 308a, 308b, 308c or 308d (collectively referred to as a “set of gate patterns 308”) extending in the second direction Y. The set of gate patterns 306 is above the set of gate patterns 308.

Gate patterns 306a and 306c are separated from one another in the second direction Y. Gate patterns 308a and 308c are separated from one another in the second direction Y.

Gate patterns 306b and 306d are separated from one another in the second direction Y. Gate patterns 308b and 308d are separated from one another in the second direction Y.

Gate patterns 306a and 306b are separated from one another in the first direction X. Gate patterns 308a and 308b are separated from one another in the first direction X.

Gate patterns 306c and 306d are separated from one another in the first direction X. Gate patterns 308c and 308d are separated from one another in the first direction X.

In some embodiments, gate patterns 306b and 308b are separated from one another in the third direction Z. In some embodiments, gate patterns 306c and 308c are separated from one another in the third direction Z.

The set of gate patterns 306 is usable to manufacture a corresponding set of gates 406 of integrated circuit 100, 200A, 200B, 400 or 600. The set of gate patterns 308 is usable to manufacture a corresponding set of gates 408 of integrated circuit 100, 200A, 200B, 400 or 600.

In some embodiments, gate patterns 306a, 306b, 306c or 306d are usable to manufacture corresponding gates 406a, 406b, 406c or 406d of the set of gates 406 of integrated circuit 100, 200A, 200B, 400 or 600. In some embodiments, gate patterns 308a, 308b, 308c or 308d are usable to manufacture corresponding gates 408a, 408b, 408c or 408d of the set of gates 408 of integrated circuit 100, 200A, 200B, 400 or 600.

In some embodiments, at least one of the set of gates 406 or 408 are located on the front-side 403a of integrated circuit 100, 200A, 200B, 400 or 600.

In some embodiments, each of the gate patterns in the set of gate patterns 304 and 306 is shown in FIGS. 3C-3D with labels “N2-1, P2-1, N2-2, P2-2, N2-3, P2-3, N2-4, P2-4” that identify corresponding transistors of FIGS. 2A-2B manufactured by the corresponding gate pattern in FIGS. 3A-3D, and are omitted for brevity.

In some embodiments, the set of gate patterns 306 or 308 encapsulate the set of active region patterns 302 and 304. In some embodiments, a portion of the set of gate patterns 306 or 308 is above the set of active region patterns 302 and 304. In some embodiments, another portion of the set of gate patterns 306 or 308 is below the set of active region patterns 302 and 304.

The set of gate patterns 306 or 308 is positioned on a second layout level. In some embodiments, the second layout level is different from the first layout level. In some embodiments, the second layout level corresponds to the POLY level of one or more of layout design 300 or 500 or integrated circuits 100, 200A, 200B, 400 or 600. In some embodiments, the POLY level is above the BMD and the BM0 level.

Other configurations, arrangements on other layout levels or quantities of patterns in the set of gate patterns 306 or 308 are within the scope of the present disclosure.

Layout design 300 further includes one or more insulating region patterns 394a or 394b (collectively referred to as a “set of insulating region patterns 394”) extending in the second direction Y.

In some embodiments, the set of insulating region patterns 394 is between the set of gate patterns 306 and the set of gate patterns 308. In some embodiments, the set of insulating region patterns 394 is above the set of gate patterns 308. In some embodiments, the set of insulating region patterns 394 is below the set of gate patterns 306.

In some embodiments, gate pattern 306b and gate pattern 308b are separated from each other in the third direction Z by the insulating region pattern 394b of the set of insulating region patterns 394.

In some embodiments, gate pattern 306c and gate pattern 308c are separated from each other in the third direction Z by insulating region pattern 394a of the set of insulating region patterns 394.

The set of insulating region patterns 394 is usable to manufacture a corresponding set of insulating regions 494 of integrated circuit 100, 200A, 200B, 400 or 600. The set of insulating region patterns 394 is usable to manufacture a corresponding set of insulating region patterns 494a, 494b of integrated circuit 100, 200A, 200B, 400 or 600.

Other configurations, arrangements on other layout levels or other numbers of portions in insulating region pattern 394 are within the scope of the present disclosure.

Layout design 300 further includes one or more contact patterns 310a, 310b, 310c, 310d (collectively referred to as a “set of contact patterns 310”) extending in the second direction Y.

Each of the contact patterns of the set of contact patterns 310 is separated from an adjacent contact pattern of the set of contact patterns 310 in at least the first direction X or the second direction Y.

The set of contact patterns 310 is usable to manufacture a corresponding set of contacts 410 of integrated circuit 100, 200A, 200B, 400 or 600.

In some embodiments, contact pattern 310a, 310b, 310c, 310d of the set of contact patterns 310 is usable to manufacture corresponding contact 410a, 410b, 410c, 410d of the set of contact patterns 410. In some embodiments, the set of contact patterns 310 is also referred to as a set of metal over diffusion (MD) patterns.

In some embodiments, at least one of contact pattern 310a, 310b, 310c, 310d of the set of contact patterns 310 is usable to manufacture source or drain terminals of one of the NFET or PFET transistors of integrated circuit 100, 200A, 200B, 400 or 600.

In some embodiments, contact pattern 310a is usable to manufacture source terminals of NFET transistor N2-1, contact pattern 310b is usable to manufacture source terminals of NFET transistor N2-3, contact pattern 310c is usable to manufacture source terminals of NFET transistor N2-4, and contact pattern 310d is usable to manufacture source terminals of NFET transistor N2-2.

In some embodiments, the set of contact patterns 310 overlaps the set of active region patterns 302 or 304. The set of contact patterns 310 is located on a third layout level. In some embodiments, the third layout level corresponds to the contact level or an MD level of one or more of layout design 300 or 500 or integrated circuits 100, 200A, 200B, 400 or 600. In some embodiments, the third layout level is different from at least one of the first layout level or the second layout level. Other configurations, arrangements on other layout levels or quantities of patterns in the set of contact patterns 310 are within the scope of the present disclosure.

Layout design 300 further includes one or more contact patterns 312a, 312b, 312c, 312d (collectively referred to as a “set of contact patterns 312”) extending in the second direction Y.

Each of the contact patterns of the set of contact patterns 312 is separated from an adjacent contact pattern of the set of contact patterns 312 in at least the first direction X or the second direction Y.

The set of contact patterns 310 and 312 are separated from one another in the third direction Z. In some embodiments, contact patterns 310a and 312a are separated from one another in the third direction Z. In some embodiments, contact patterns 310b and 312b are separated from one another in the third direction Z. In some embodiments, contact patterns 310c and 312c are separated from one another in the third direction Z. In some embodiments, contact patterns 310d and 312d are separated from one another in the third direction Z.

The set of contact patterns 312 is usable to manufacture a corresponding set of contacts 412 of integrated circuit 100, 200A, 200B, 400 or 600.

In some embodiments, contact pattern 312a, 312b, 312c, 312d of the set of contact patterns 312 is usable to manufacture corresponding contact 412a, 412b, 412c, 412d of the set of contacts 412. In some embodiments, the set of contacts 412 are on a back-side 403b of integrated circuit 400. In some embodiments, the back-side 403b of integrated circuit 400 is opposite from the front-side of integrated circuit 400. In some embodiments, the set of contacts patterns 312 is also referred to as a set of back-side MD (BMD) patterns.

In some embodiments, contact pattern 312a is usable to manufacture source terminals of PFET transistor P2-1, contact pattern 312b is usable to manufacture source terminals of PFET transistor P2-3, contact pattern 312c is usable to manufacture source terminals of PFET transistor P2-4, and contact pattern 312d is usable to manufacture source terminals of PFET transistor P2-2.

In some embodiments, the set of contact patterns 312 are overlapped by the set of active region patterns 302 or 304. The set of contact patterns 312 is located on a fourth layout level. In some embodiments, the fourth layout level corresponds to the back-side contact level or a back-side MD (BMD) level of one or more of layout design 300 or 500 or integrated circuits 100, 200A, 200B, 400 or 600. In some embodiments, the fourth layout level is different from at least one of the first layout level, the second layout level or the third layout level.

In some embodiments, the BMD level is above the BM0 level. In some embodiments, the BMD level is below the back-side 403b of integrated circuit 400. In some embodiments, the BMD level is below the OD level, the POLY level, the MD level and the M0 level.

Other configurations, arrangements on other layout levels or quantities of patterns in the set of contact patterns 312 are within the scope of the present disclosure.

Layout design 300 further includes one or more contact patterns 314a, 314b (collectively referred to as a “set of contact patterns 314”) extending in the second direction Y.

Each of the contact patterns of the set of contact patterns 314 is separated from an adjacent contact pattern of the set of contact patterns 314 in at least the first direction X or the second direction Y.

In some embodiments, the set of contact patterns 314 is between the set of contact patterns 310 and 312. Contact pattern 314a is between contact patterns 310a and 310b. Contact pattern 314a is between contact patterns 312a and 312b. Contact pattern 314b is between contact patterns 310c and 310d. Contact pattern 314b is between contact patterns 312c and 312d.

In some embodiments, contact pattern 314a includes one or more separate discontinuous patterns. In some embodiments, contact pattern 314b includes one or more separate discontinuous patterns.

Contact patterns 314a and 314b are separated from one another in the second direction Y.

The set of contact patterns 314 is usable to manufacture a corresponding set of contacts 414 of integrated circuit 100, 200A, 200B, 400 or 600.

In some embodiments, contact pattern 314a, 314b of the set of contact patterns 314 is usable to manufacture corresponding contact 414a, 414b of the set of contacts 414. In some embodiments, the set of contacts 414 are on a front-side 403a of integrated circuit 400. In some embodiments, the set of contacts patterns 314 is also referred to as a set of local interconnect (MDLI) patterns.

In some embodiments, at least one of contact pattern 314a, 314b of the set of contact patterns 314 is usable to manufacture interconnect structures usable to connect source or drain terminals of one of the NFET or PFET transistors of integrated circuit 100, 200A, 200B, 400 or 600.

In some embodiments, contact pattern 314a is usable to manufacture drain terminals of PFET transistor P2-1, drain terminals of NFET transistor N2-1, drain terminals of PFET transistor P2-3 and drain terminals of NFET transistor N2-3.

In some embodiments, contact pattern 314b is usable to manufacture drain terminals of PFET transistor P2-2, drain terminals of NFET transistor N2-2, drain terminals of PFET transistor P2-4 and drain terminals of NFET transistor N2-4.

In some embodiments, at least a first portion of the set of contact patterns 314 are overlapped by one or more of the set of active region patterns 302 or 304. In some embodiments, at least a second portion of the set of contact patterns 314 is between the set of active region patterns 302 or 304. In some embodiments, at least a third portion of the set of contact patterns 314 is coplanar with the set of contact patterns 310 or the set of contact patterns 312.

The set of contact patterns 314 is located on a fifth layout level. In some embodiments, the fifth layout level corresponds to the MDLI level of one or more of layout design 300 or 500 or integrated circuits 100, 200A, 200B, 400 or 600. In some embodiments, the fifth layout level is different from at least one of the first layout level or the second layout level.

In some embodiments, the MDLI level includes the MD level and the BMD level. In some embodiments, the MDLI level is below the M0 level. In some embodiments, the MDLI level is above the BM0 level.

Other configurations, arrangements on other layout levels or quantities of patterns in the set of contact patterns 314 are within the scope of the present disclosure.

Layout design 300 further includes one or more contact patterns 316a and 316b (collectively referred to as a “set of contact patterns 316”) extending in the first direction X.

Each of the contact patterns of the set of contact patterns 316 is separated from an adjacent contact pattern of the set of contact patterns 316 in at least the first direction X or the second direction Y.

Contact patterns 316a and 316b are separated from one another in the second direction Y.

The set of contact patterns 316 is usable to manufacture a corresponding set of contacts 416 of integrated circuit 100, 200A, 200B, 400 or 600.

In some embodiments, contact pattern 316a, 326b of the set of contact patterns 316 is usable to manufacture corresponding contact 416a, 416b of the set of contacts 416. The set of contacts 416 is on the front-side 403a of integrated circuit 400. Contact 416a or 416b is on the front-side 403a of integrated circuit 400. In some embodiments, the set of contacts patterns 316 is also referred to as a set of butted contacts (BCT) patterns. In some embodiments, the set of contacts 416 is also referred to as a set of butted contacts (BCT).

In some embodiments, at least one of contact pattern 316a, 316b of the set of contact patterns 316 is usable to manufacture interconnect structures usable to connect at least a gate terminal of one of the NFET or PFET transistors of integrated circuit 100, 200A, 200B, 400 or 600 to source or drain terminals of another of the NFET or PFET transistors of integrated circuit 100, 200A, 200B, 400 or 600.

In some embodiments, the set of contact patterns 316 overlap one or more of the set of active region patterns 302, the set of active region patterns 304, the set of gate patterns 306 or the set of gate patterns 308.

In some embodiments, contact pattern 316a overlaps at least one of gate pattern 306d, gate pattern 308d or contact pattern 314a. In some embodiments, contact pattern 316b overlaps at least one of gate pattern 306a, gate pattern 308a or contact pattern 314b.

In some embodiments, the set of contact patterns 316 overlap one or more of the set of active region patterns 302 or 304, the set of gate patterns 306 or 308, the set of contact patterns 310 or 312 or the set of contact patterns 314. The set of contact patterns 316 is located on a sixth layout level. In some embodiments, the sixth layout level corresponds to the BCT level of one or more of layout design 300 or 600 or integrated circuits 100, 200A, 200B, 400 or 600. In some embodiments, the sixth layout level is different from at least one of the first layout level, the second layout level, the third layout level, the fourth layout level or the fifth layout level. In some embodiments, the BCT level is between the M0 level and at least one of the OD level, the POLY level, the MD level or the MDLI level. In some embodiments, the BCT level is above at least one of the OD level, the POLY level, the MD level or the MDLI level. In some embodiments, the MDLI level is below the M0 level.

Other configurations, arrangements on other layout levels or quantities of patterns in the set of contact patterns 316 are within the scope of the present disclosure.

Layout design 300 further includes one or more conductive feature patterns 330a, 330b, 330c, 330d, 330c, 330f (collectively referred to as a “set of conductive feature patterns 330”) extending in the first direction X.

Each conductive feature pattern in the set of conductive feature patterns 330 is separated from another conductive feature pattern in the set of conductive feature patterns 330 in the second direction Y.

The set of conductive feature patterns 330 overlap at least one of the set of active region patterns 302 or 304, the set of gate patterns 306 or 308 or the set of contact patterns 310, 312, 314 or 316.

The set of conductive feature patterns 330 is usable to manufacture a corresponding set of conductors 430 of integrated circuit 100, 200A, 200B, 400 or 600. Conductive feature patterns 330a, 330b, 330c, 330d, 330c, 330f are usable to manufacture corresponding conductors 430a, 430b, 430c, 430d, 430e, 430f of integrated circuit 100, 200A, 200B, 400 or 600. In some embodiments, at least one conductor of the set of conductors 430 is located on the front-side 403a of integrated circuit 100, 200A, 200B, 400 or 600.

In some embodiments, the set of conductive feature patterns 330 is located on a seventh layout level. In some embodiments, the seventh layout level is different from at least one of the first layout level, the second layout level, the third layout level, the fourth layout level, the fifth layout level or the sixth layout level. In some embodiments, the seventh layout level corresponds to the M0 level of one or more of layout design 300 or 500 or integrated circuits 100, 200A, 200B, 400 or 600. In some embodiments, the M0 level is above the OD level, the POLY level, the MD level, the BMD level and the BM0 level.

In some embodiments, the set of conductive feature patterns 330 correspond to 4 M0 routing tracks. Other numbers of M0 routing tracks are within the scope of the present disclosure.

Other configurations, arrangements on other layout levels or quantities of patterns in the set of conductive feature patterns 330 are within the scope of the present disclosure.

Layout design 300 further includes one or more conductive feature patterns 332a, 332b, 332c, 332d, 332c, 332f (collectively referred to as a “set of conductive feature patterns 332”) extending in the first direction X.

Each conductive feature pattern in the set of conductive feature patterns 332 is separated from another conductive feature pattern in the set of conductive feature patterns 332 in the second direction Y.

The set of conductive feature patterns 332 is overlapped by at least one of the set of active region patterns 302 or 304, the set of gate patterns 306 or 308 or the set of contact patterns 310, 312, 314 or 316.

The set of conductive feature patterns 330 and 332 are separated from one another in the third direction Z. In some embodiments, conductive feature patterns 330a and 332a are separated from one another in the third direction Z. In some embodiments, conductive feature patterns 330b and 332b are separated from one another in the third direction Z. In some embodiments, conductive feature patterns 330c and 332c are separated from one another in the third direction Z. In some embodiments, conductive feature patterns 330d and 332d are separated from one another in the third direction Z. In some embodiments, conductive feature patterns 330e and 332e are separated from one another in the third direction Z. In some embodiments, conductive feature patterns 330f and 332f are separated from one another in the third direction Z.

The set of conductive feature patterns 332 is usable to manufacture a corresponding set of conductors 432 of integrated circuit 100, 200A, 200B, 400 or 600. Conductive feature patterns 332a, 332b, 332c, 332d, 332c, 332f are usable to manufacture corresponding conductors 432a, 432b, 432c, 432d, 432c, 432f of integrated circuit 100, 200A, 200B, 400 or 600. In some embodiments, at least one conductor of the set of conductors 432 is located on the back-side 403b of integrated circuit 100, 200A, 200B, 400 or 600.

In some embodiments, the set of conductive feature patterns 332 is located on an eighth layout level. In some embodiments, the eighth layout level is different from at least one of the first layout level, the second layout level, the third layout level, the fourth layout level, the fifth layout level, the sixth layout level or the seventh layout level. In some embodiments, the eighth layout level corresponds to the BM0 level of one or more of layout design 300 or 500 or integrated circuits 100, 200A, 200B, 400 or 600. In some embodiments, the BM0 level is below the OD level, the POLY level, the MD level and the BMD level.

In some embodiments, the set of conductive feature patterns 332 correspond to 4 BM0 routing tracks. Other numbers of BM0 routing tracks are within the scope of the present disclosure.

Other configurations, arrangements on other layout levels or quantities of patterns in the set of conductive feature patterns 332 are within the scope of the present disclosure.

Layout design 300 further includes one or more via patterns 320a, 320b, 320c, 320d (collectively referred to as a “set of via patterns 320”).

The set of via patterns 320 is usable to manufacture a corresponding set of vias 420 of integrated circuit 100, 200A, 200B, 400 or 600. In some embodiments, via patterns 320a, 320b, 320c, 320d of the set of via patterns 320 are usable to manufacture corresponding vias 420a, 420b, 420c, 420d of the set of vias 420 of integrated circuit 100, 200A, 200B, 400 or 600.

In some embodiments, the set of via patterns 320 is between the set of contact patterns 310 and the set of conductive feature patterns 330. Via pattern 320a is between contact pattern 310a and conductive feature pattern 330a. Via pattern 320b is between contact pattern 310b and conductive feature pattern 330c. Via pattern 320c is between contact pattern 310c and conductive feature pattern 330d. Via pattern 320d is between contact pattern 310d and conductive feature pattern 330f.

The set of via patterns 320 is positioned at a via over diffusion (VD) level of one or more of layout design 300 or 500 or integrated circuits 100, 200A, 200B, 400 or 600. In some embodiments, the VD level is above the OD level, the POLY level, the MD level, the BMD level and the BM0 level. In some embodiments, the VD level is below the M0 level. In some embodiments, the VD level is between the MD level and the M0 level. In some embodiments, the VD level is between the third layout level and the seventh layout level. Other layout levels are within the scope of the present disclosure.

Other configurations, arrangements on other layout levels or quantities of patterns in at least set of via patterns 320 are within the scope of the present disclosure.

Layout design 300 further includes one or more via patterns 322a, 322b, 322c, 322d (collectively referred to as a “set of via patterns 322”).

The set of via patterns 322 is usable to manufacture a corresponding set of vias 422 of integrated circuit 100, 200A, 200B, 400 or 600. In some embodiments, via patterns 322a, 322b, 322c, 322d of the set of via patterns 322 are usable to manufacture corresponding vias 422a, 422b, 422c, 422d of the set of vias 422 of integrated circuit 100, 200A, 200B, 400 or 600.

In some embodiments, the set of via patterns 322 is between the set of contact patterns 312 and the set of conductive feature patterns 332. Via pattern 322a is between contact pattern 312a and conductive feature pattern 332a. Via pattern 322b is between contact pattern 312b and conductive feature pattern 332c. Via pattern 322c is between contact pattern 312c and conductive feature pattern 332d. Via pattern 322d is between contact pattern 312d and conductive feature pattern 332f.

The set of via patterns 322 is positioned at a back-side via over diffusion (BVD) level of one or more of layout design 300 or 500 or integrated circuits 100, 200A, 200B, 400 or 600. In some embodiments, the BVD level is below the OD level, the POLY level, the MD level, the BMD level and the M0 level. In some embodiments, the BVD level is above the BM0 level. In some embodiments, the BVD level is between the BMD level and the BM0 level. In some embodiments, the BVD level is between the fourth layout level and the eighth layout level. Other layout levels are within the scope of the present disclosure.

Other configurations, arrangements on other layout levels or quantities of patterns in at least set of via patterns 322 are within the scope of the present disclosure.

Layout design 300 further includes one or more via patterns 324a, 324b (collectively referred to as a “set of via patterns 324”).

The set of via patterns 324 is usable to manufacture a corresponding set of vias 424 of integrated circuit 100, 200A, 200B, 400 or 600. In some embodiments, via patterns 324a, 324b of the set of via patterns 324 are usable to manufacture corresponding vias 424a, 424b of the set of vias 424 of integrated circuit 100, 200A, 200B, 400 or 600.

In some embodiments, the set of via patterns 324 is between the set of gate patterns 306 and the set of conductive feature patterns 330. Via pattern 324a is between gate pattern 306b and conductive feature pattern 330b. Via pattern 324b is between gate pattern 306c and conductive feature pattern 330c.

The set of via patterns 324 is positioned at a via over gate (VG) level of one or more of layout design 300 or 500 or integrated circuits 100, 200A, 200B, 400 or 600. In some embodiments, the VG level is above the OD level, the POLY level, the MD level, the MDLI level, the BCT level, the BMD level, the BM0 level and the BMI level. In some embodiments, the VG level is below the M0 level. In some embodiments, the VG level is between the POLY level and the M0 level. In some embodiments, the VG level is between the second layout level and the seventh layout level. Other layout levels are within the scope of the present disclosure.

Other configurations, arrangements on other layout levels or quantities of patterns in at least set of via patterns 324 are within the scope of the present disclosure.

Layout design 300 further includes one or more via patterns 326a, 326b (collectively referred to as a “set of via patterns 326”).

The set of via patterns 326 is usable to manufacture a corresponding set of vias 426 of integrated circuit 100, 200A, 200B, 400 or 600. In some embodiments, via patterns 326a, 326b of the set of via patterns 326 are usable to manufacture corresponding vias 426a, 426b of the set of vias 426 of integrated circuit 100, 200A, 200B, 400 or 600.

In some embodiments, the set of via patterns 326 is between the set of gate patterns 308 and the set of conductive feature patterns 332. Via pattern 326a is between gate pattern 308b and conductive feature pattern 332b. Via pattern 326b is between gate pattern 308c and conductive feature pattern 332c.

The set of via patterns 326 is positioned at a back-side via over gate (BVG) level of one or more of layout design 300 or 500 or integrated circuits 100, 200A, 200B, 400 or 600. In some embodiments, the BVG level is below the OD level, the POLY level, the MD level, the MDLI level, the BCT level, the BMD level and the M0 level. In some embodiments, the BVG level is above the BM0 level. In some embodiments, the BVG level is between the POLY level and the BM0 level. In some embodiments, the BVG level is between the second layout level and the eighth layout level. Other layout levels are within the scope of the present disclosure.

Other configurations, arrangements on other layout levels or quantities of patterns in at least set of via patterns 326 are within the scope of the present disclosure.

FIG. 3B is a diagram of a portion 300B of layout design 300, simplified for case of illustration.

Portion 300B is a variation of portion 300A of layout design 300, and similar detailed description is omitted for brevity.

Portion 300B includes a region 350al, a region 350bl and a region 350cl.

Region 350al is portion 300A of FIG. 3A, and similar detailed description is omitted for brevity.

Region 350b1 identifies M0 track usage for the set of conductive feature patterns 330. Stated differently, region 350bl identifies M0 signals for corresponding conductive feature patterns in the set of conductive feature patterns 330 for the front-side of integrated circuit 400. For example, conductive feature pattern 330a is useable for the reference supply voltage VSS, conductive feature pattern 330b is useable for the word line WL_FS, conductive feature pattern 330c is useable for the bit line BL_FS, conductive feature pattern 330d is useable for the bit line bar BLB_FS, conductive feature pattern 330e is useable for the word line WL_FS, and conductive feature pattern 330f is useable for the reference supply voltage VSS, and in accordance with some embodiments.

Region 350cl identifies BM0 track usage for the set of conductive feature patterns 332. Stated differently, region 350cl identifies BM0 signals for corresponding conductive feature patterns in the set of conductive feature patterns 332 for the back-side of integrated circuit 400. For example, conductive feature pattern 332a is useable for the supply voltage VDD, conductive feature pattern 332b is useable for the word line WL_BS, conductive feature pattern 332c is useable for the bit line BL_BS, conductive feature pattern 332d is useable for the bit line bar BLB_BS, conductive feature pattern 332e is useable for the word line WL_BS, and conductive feature pattern 332f is useable for the supply voltage VDD, and in accordance with some embodiments.

Other M0 track assignments are within the scope of the present disclosure.

FIG. 3C is a diagram of a portion 300C of layout design 300, simplified for case of illustration. Portion 300C includes a region 350a2 and region 350b1.

Portion 300C is a variation of portion 300B, and similar detailed description is omitted for brevity. In comparison with portion 300B, region 350a2 of portion 300C replaces region 350al of FIG. 3B, and similar detailed description is omitted for brevity. In comparison with portion 300B, portion 300C does not include region 350c1, and similar detailed description is omitted for brevity.

Region 350a2 includes the set of active region patterns 302 and 304, the set of gate patterns 306 and 308, the set of contact patterns 310, 314 and 316, the set of via patterns 320 and 324, and the set of conductive feature patterns 330.

Other M0 track assignments are within the scope of the present disclosure.

FIG. 3D is a diagram of a portion 300D of layout design 300, simplified for ease of illustration. Portion 300D includes a region 350a3 and region 350cl.

Portion 300D is a variation of portion 300B, and similar detailed description is omitted for brevity. In comparison with portion 300B, region 350a3 of portion 300D replaces region 350al of FIG. 3B, and similar detailed description is omitted for brevity. In comparison with portion 300B, portion 300D does not include region 350b1, and similar detailed description is omitted for brevity.

Region 350a3 includes the set of active region patterns 302 and 304, the set of gate patterns 306 and 308, the set of contact patterns 312, 314 and 316, the set of via patterns 322 and 326, and the set of conductive feature patterns 332.

Other M0 track assignments are within the scope of the present disclosure.

In some embodiments, by including the set of insulating region patterns 394 in layout design 300, gate pattern 306b and 308b are separated from each other by insulating region pattern 394b, thereby allowing NFET transistor N2-3 and PFET transistor P2-3 to be used as pass gate transistors of different corresponding ports of a dual-port memory cell manufactured by layout design 300, thereby resulting in a layout design of a dual-port memory cell that occupies less area than other approaches.

In some embodiments, by including the set of insulating region patterns 394 in layout design 300, gate pattern 306c and 308c are separated from each other by insulating region pattern 394a, thereby allowing NFET transistor N2-4 and PFET transistor P2-4 to be used as pass gate transistors of different corresponding ports of a dual-port memory cell manufactured by layout design 300, thereby resulting in a layout design 300 of a dual-port memory cell that occupies less area than other approaches.

In some embodiments, by including the set of insulating region patterns 394 in layout design 300 causes layout design 300 to include less active region (OD) tracks than other approaches resulting in a layout design 300 of a dual port memory cell that occupies less area than other approaches.

Other configurations, arrangements on other layout levels or quantities of patterns in layout design 300 are within the scope of the present disclosure.

FIGS. 4A-4I are diagrams of an integrated circuit 400, in accordance with some embodiments.

FIGS. 4A-4D are corresponding diagrams of corresponding portions 400A-400D of an integrated circuit 400, simplified for ease of illustration.

Portion 400A includes one or more features of integrated circuit 400 of the OD level, the POLY level, the MD level, the MDLI level, the BCT level, the M0 level, the VG level, the VD level, the BMD level, the BM0 level, the BVG level, and the BVD level. Portion 400A is manufactured by portion 300A.

Portion 400B includes one or more features of integrated circuit 400 of the OD level, the POLY level, the MD level, the MDLI level, the BCT level, the M0 level, the VG level, the VD level, the BMD level, the BM0 level, the BVG level, and the BVD level. Portion 400B is manufactured by portion 300B.

Portion 400C includes one or more features of integrated circuit 400 of the OD level, the POLY level, the MD level, the MDLI level, the BCT level, the M0 level, the VG level and the VD level. Portion 400C is manufactured by portion 300C.

Portion 400D include one or more features of integrated circuit 400 of the OD level, the POLY level, the BMD level, the MDLI level, the BCT level, the BM0 level, the BVG level, and the BVD level. Portion 400D is manufactured by portion 300D.

FIGS. 4E-4I are corresponding cross-sectional views of integrated circuit 400, in accordance with some embodiments. FIG. 4E is a cross-sectional view of integrated circuit 400 as intersected by plane A-A′, in accordance with some embodiments. FIG. 4F is a cross-sectional view of integrated circuit 400 as intersected by plane B-B′, in accordance with some embodiments. FIG. 4G is a cross-sectional view of integrated circuit 400 as intersected by plane C-C′, in accordance with some embodiments. FIG. 4H is a cross-sectional view of integrated circuit 400 as intersected by plane D-D′, in accordance with some embodiments. FIG. 4I is a cross-sectional view of integrated circuit 400 as intersected by plane E-E′, in accordance with some embodiments.

Components that are the same or similar to those in one or more of FIGS. 1, 2A-2B, 3A-3D, 4A-4I, 5 and 6 are given the same reference numbers, and detailed description thereof is thus omitted.

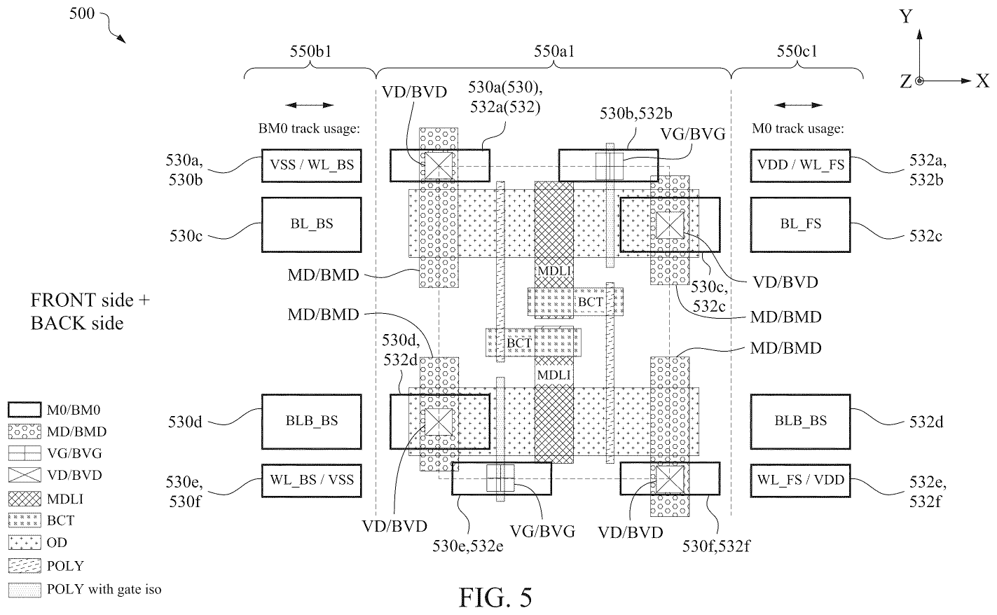

Integrated circuit 400 is manufactured by layout design 300. Integrated circuit 400 is cell 401. Structural relationships including alignment, lengths and widths, as well as configurations and layers of integrated circuit 400 and 600 are similar to the structural relationships and configurations and layers of layout design 300 or 500 of FIGS. 3A-3D and 5, and similar detailed description will not be described in at least FIGS. 4A-4I, for brevity. For example, in some embodiments, at least one or more widths, lengths or pitches of layout design 300 or 500 is similar to corresponding widths, lengths or pitches of integrated circuit 400 and 600, and similar detailed description is omitted for brevity. For example, in some embodiments, at least cell boundary 301a or 301b is similar to at least corresponding cell boundary 401a or 401b of integrated circuit 400, and similar detailed description is omitted for brevity.

Integrated circuit 400 includes at least the set of active regions 402 and 404, the set of gates 406 and 408, the set of contacts 410, the set of contacts 412, the set of contacts 414, the set of contacts 416, the set of conductors 430, the set of conductors 432, the set of vias 420, the set of vias 422, the set of vias 424, the set of vias 426, a substrate 490, an insulating region 492 and a set of insulating regions 494.

The set of active regions 402 and 404 are embedded in substrate 490. Substrate 490 has a front-side 403a and a back-side 403b opposite from the front-side 403a. In some embodiments, at least the set of active regions 402 and 404, the set of gates 406 and 408 or the set of contacts 410, 412, 414 and 416 are formed in the front-side 403a of substrate 490.

In some embodiments, the set of active regions 402 and 404 correspond to active regions of CFET transistors. In some embodiments, the set of active regions 402 and 404 correspond to nanosheet structures (not labelled) of nanosheet transistors. In some embodiments, the set of active regions 402 include drain regions and source regions grown by an epitaxial growth process. In some embodiments, the set of active regions 402 include drain regions and source regions that are grown with an epitaxial material at the corresponding drain regions and source regions.

Other transistor types are within the scope of the present disclosure. For example, in some embodiments, the set of active regions 402 corresponds to nanowire structures (not shown) of nanowire transistors. In some embodiments, the set of active regions 402 corresponds to planar structures (not shown) of planar transistors. In some embodiments, the set of active regions 402 corresponds to fin structures (not shown) of finFETs.

In some embodiments, active regions 402a and 402b correspond to source and drain regions of NFET transistors of integrated circuit 100, 200A, 200B, 400 or 600, and active regions 404a and 404b correspond to source and drain regions of PFET transistors of integrated circuit 100, 200A, 200B, 400 or 600.

In some embodiments, active regions 402a and 402b correspond to source and drain regions of PFET transistors of integrated circuit 100, 200A, 200B, 400 or 600, and active regions 404a and 404b correspond to source and drain regions of NFET transistors of integrated circuit 100, 200A, 200B, 400 or 600.

In some embodiments, at least active region 402a or 402b is an N-type doped S/D region, and at least active region 404a or 404b is a P-type doped S/D region embedded in a dielectric material of substrate 490. In some embodiments, at least active region 402a or 402b is a P-type doped S/D region, and at least active region 404a or 404b is an N-type doped S/D region embedded in a dielectric material of substrate 490.

Other configurations, arrangements on other layout levels or quantities of structures in the set of active regions 402 or 404 are within the scope of the present disclosure.

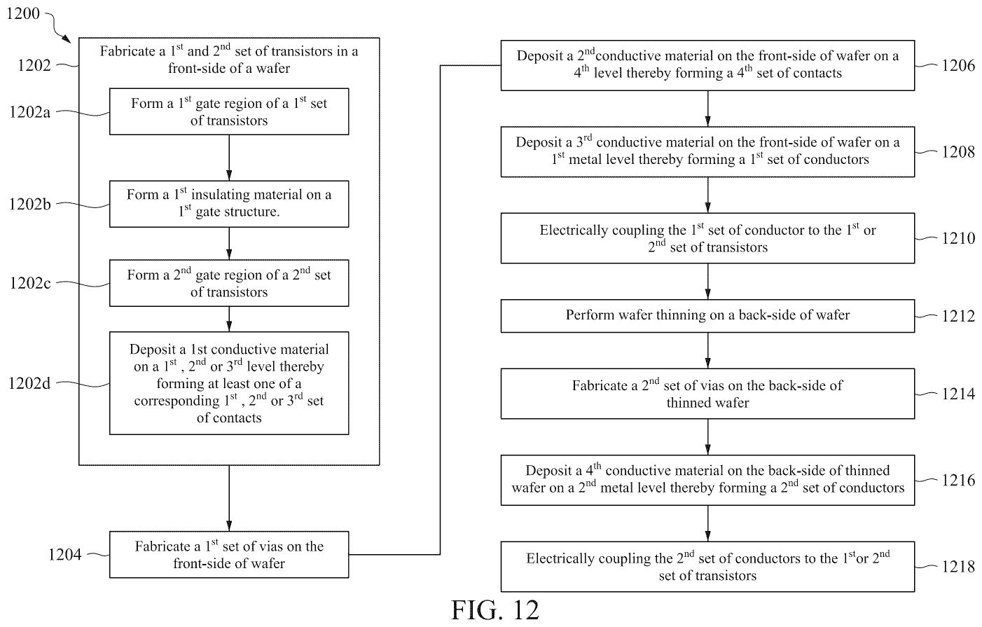

Insulating region 492 is configured to electrically isolate one or more elements of the set of active regions 402 and 404, the set of gates 406 and 408, the set of contacts 410, the set of contacts 412, the set of contacts 414, the set of contacts 416, the set of conductors 430, the set of conductors 432, the set of vias 420, the set of vias 422, the set of vias 424, the set of vias 426 from one another. In some embodiments, insulating region 492 includes multiple insulating regions deposited at different times from each other during method 1200 (FIG. 12). In some embodiments, insulating region 492 is a dielectric material. In some embodiments, the dielectric material includes silicon dioxide, silicon oxy-nitride, or the like.

Other configurations, arrangements on other layout levels or other numbers of portions in insulating region 492 are within the scope of the present disclosure.

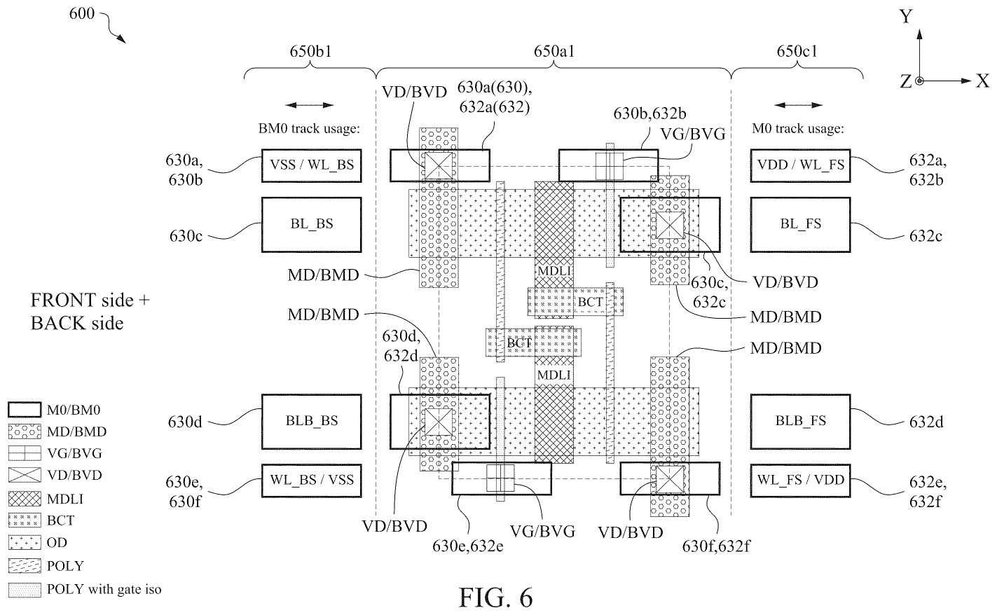

The set of gates 406 and 408 correspond to one or more gates of transistors N2-1, P2-1, N2-2, P2-2, N2-3, P2-3, N2-4, P2-4 of integrated circuits 100, 200A, 200B, 400 or 600. In some embodiments, each of the gates in the set of gates 406 and 408 are shown in FIGS. 4A-4F with labels “N2-1, P2-1, N2-2, P2-2, N2-3, P2-3, N2-4, P2-4” that identify corresponding transistors of FIGS. 2A-2B having corresponding gates in FIGS. 4A-4I and 6, and are omitted for brevity.

In some embodiments, gate 406a is a gate of NFET transistor N2-1, gate 408a is a gate of PFET transistor P2-1, gate 406b is a gate of NFET transistor N2-3, gate 408b is a gate of PFET transistor P2-3, gate 406c is a gate of NFET transistor N2-4, gate 408c is a gate of PFET transistor P2-4, gate 406d is a gate of NFET transistor N2-2, and gate 408d is a gate of PFET transistor P2-2.

In some embodiments, gate 406a and gate 408a are coupled together. In some embodiments, gate 406a and gate 408a are part of the same continuous structure. In some embodiments, gate 406d and gate 408d are coupled together. In some embodiments, gate 406d and gate 408d are part of the same continuous structure.

In some embodiments, gate 406b and gate 408b are separated from each other in the third direction Z. In some embodiments, gate 406b and gate 408b are separated from each other in the third direction Z by an insulating region 494b of the set of insulating regions 494.

In some embodiments, gate 406c and gate 408c are separated from each other in the third direction Z. In some embodiments, gate 406c and gate 408c are separated from each other in the third direction Z by an insulating region 494a of the set of insulating regions 494.

In some embodiments, the set of gates 406 or 408 encapsulates the set of active regions 402 or 404.

Other configurations, arrangements on other layout levels or quantities of gates in the set of gates 406 and 408 are within the scope of the present disclosure.

The set of insulating regions 494 includes at least one of insulating region 494a or 494b. In some embodiments, the set of insulating regions 494 are also referred to as a set of gate isolation layers. In some embodiments, at least one of insulating region 494a or 494b is referred to as a gate isolation layer.

The set of insulating regions 494 is configured to electrically isolate one or more gates of the set of gates 406 or 408 from another gate of the set of gates 406 or 408.

In some embodiments, insulating region 494a is configured to electrically isolate gate 406c and gate 408c from each other. In some embodiments, insulating region 494b is configured to electrically isolate gate 406b and gate 408b from each other.

In some embodiments, set of insulating regions 494a or 494b includes a single insulating region deposited at a single instant of time during method 1200 (FIG. 12). In some embodiments, insulating region 494a or 494b includes multiple insulating regions deposited at different times from each other during method 1200 (FIG. 12). In some embodiments, insulating region 494 is a dielectric material. In some embodiments, the dielectric material includes silicon dioxide, silicon oxy-nitride, or the like.

Other configurations, arrangements on other layout levels or other numbers of portions in the set of insulating regions 494 are within the scope of the present disclosure.

Each contact of the set of contacts 410 or 412 corresponds to one or more drain or source terminals of transistors N2-1, P2-1, N2-2, P2-2, N2-3, P2-3, N2-4, P2-4 of integrated circuits 100, 200A, 200B, 400 or 600. In some embodiments, one or more contacts of the set of contacts 410 or 412 overlaps a pair of active regions of the set of active regions 402 and 404, thereby electrically coupling the pair of active regions of the set of active regions 402 and 404, and the source or drain of the corresponding transistors.

In some embodiments, the set of contacts 410 or 412 encapsulates the set of active regions 402 or 404.

In some embodiments, contact 410a corresponds to the source terminal of NFET transistor N2-1. In some embodiments, contact 412a corresponds to the source terminal of PFET transistor P2-1.

In some embodiments, contact 410b corresponds to the source terminal of NFET transistor N2-3. In some embodiments, contact 412b corresponds to the source terminal of PFET transistor P2-3.

In some embodiments, contact 410c corresponds to the source terminal of NFET transistor N2-4. In some embodiments, contact 412c corresponds to the source terminal of PFET transistor P2-4.

In some embodiments, contact 410d corresponds to the source terminal of NFET transistor N2-2. In some embodiments, contact 412d corresponds to the source terminal of PFET transistor P2-2.

In some embodiments, contact 414a corresponds to the drain terminals of NFET transistors N2-1 and N2-3, and the drain terminals of PFET transistors P2-1 and P2-3.

In some embodiments, contact 414b corresponds to the drain terminals of NFET transistors N2-4 and N2-2, and the drain terminals of PFET transistors P2-4 and P2-2.

In some embodiments, contact 416a is in direct contact with at least one of gate 406d, gate 408d or contact 414a. In some embodiments, contact 416a couples gate 406d and gate 408d with contact 414a, thereby electrically coupling the gate terminals of transistors N2-2 and P2-2 with the drain terminals of transistors N2-1 and P2-1 and transistors N2-3 and P2-3 together.

In some embodiments, contact 416b is in direct contact with at least one of gate 406a, gate 408a or contact 414b. In some embodiments, contact 416b couples gate 406a and gate 408a with contact 414b, thereby electrically coupling the gate terminals of transistors N2-1 and P2-1 with the drain terminals of transistors N2-4 and P2-4 and transistors N2-2 and P2-2 together.

Other configurations, arrangements on other layout levels or quantities of contacts in the set of contacts 410, 412, 414 and 416 are within the scope of the present disclosure.

The set of conductors 420 and 422 are M0 routing tracks. In some embodiments, the set of conductors 420 and 422 are routing tracks in other layers. In some embodiments, the set of conductors 420 or 422 corresponds to 4 M0 routing tracks.

In some embodiments, the set of conductors 430 corresponds to at least one of the bit line BL_FS, the bit line bar BLB_FS or the word line WL_FS. In some embodiments, the set of conductors 430 is configured to supply the reference supply voltage VSS.

In some embodiments, the set of conductors 432 corresponds to at least one of the bit line BL_BS, the bit line bar BLB_BS or the word line WL_BS. In some embodiments, the set of conductors 432 is configured to supply the supply voltage VDD.

In some embodiments, conductor 430a is configured to supply the reference supply voltage VSS, conductor 430b is the word line WL_FS, conductor 430c is the bit line BL_FS, conductor 430d is the bit line bar BLB_FS, conductor 430e is the word line WL_FS, and conductor 430f is configured to supply the reference supply voltage VSS.

In some embodiments, conductor 432a is configured to supply the supply voltage VDD, conductor 432b is the word line WL_BS, conductor 432c is the bit line BL_BS, conductor 432d is the bit line bar BLB_BS, conductor 432e is the word line WL_BS, and conductor 432f is configured to supply the supply voltage VDD.

Other configurations, arrangements on other layout levels or quantities of conductors in the set of conductors 430 and 432 are within the scope of the present disclosure.

The set of vias 420 is configured to electrically couple a corresponding source or drain region of the set of active regions 402 to the set of conductors 430 by the set of contacts 410, and vice versa. The set of vias 420 is between the set of contacts 410 and the set of conductors 430.

The set of vias 422 is configured to electrically couple a corresponding source or drain region of the set of active regions 404 to the set of conductors 432 by the set of contacts 412, and vice versa. The set of vias 422 is between the set of contacts 412 and the set of conductors 432.

The set of vias 424 is configured to electrically couple one or more gates of the set of gates 406 to the set of conductors 430, and vice versa. The set of vias 424 is between the set of gates 406 and the set of conductors 430.

The set of vias 426 is configured to electrically couple one or more gates of the set of gates 408 to the set of conductors 432, and vice versa. The set of vias 426 is between the set of gates 408 and the set of conductors 432.

Via 420a electrically couples conductor 430a and contact 410a together. Via 420b electrically couples conductor 430c and contact 410b together. Via 420c electrically couples conductor 430d and contact 410c together. Via 420d electrically couples conductor 430f and contact 410d together.

Via 422a electrically couples conductor 432a and contact 412a together. Via 422b electrically couples conductor 432c and contact 412b together. Via 422c electrically couples conductor 432d and contact 412c together. Via 422d electrically couples conductor 432f and contact 412d together.

Via 424a electrically couples conductor 430b and gate 406b together. Via 424b electrically couples conductor 430e and gate 406c together.

Via 426a electrically couples conductor 432b and gate 408b together. Via 426b electrically couples conductor 432e and gate 408c together.

Other configurations, arrangements on other layout levels or quantities of vias in the set of vias 420, 422, 424 and 426 are within the scope of the present disclosure.

FIG. 4B is a diagram of a portion 400B of integrated circuit 400, simplified for case of illustration.

Portion 400B is a variation of integrated circuit 400A, and similar detailed description is omitted for brevity.

Portion 400B includes a region 450al, a region 450b1 and a region 450cl.

Region 450al is portion 400A of FIG. 4A, and similar detailed description is omitted for brevity.

Region 450bl identifies M0 track usage for the set of conductors 430. Stated differently, region 450b1 identifies M0 signals for corresponding conductors in the set of conductors 430 for the front-side of integrated circuit 400. For example, conductor 430a is useable for the reference supply voltage VSS, conductor 430b is useable for the word line WL_FS, conductor 430c is useable for the bit line BL_FS, conductor 430d is useable for the bit line bar BLB_FS, conductor 430e is useable for the word line WL_FS, and conductor 430f is useable for the reference supply voltage VSS, and in accordance with some embodiments.

Region 450cl identifies BM0 track usage for the set of conductors 432. Stated differently, region 450cl identifies BM0 signals for corresponding conductors in the set of conductors 432 for the back-side of integrated circuit 400. For example, conductor 432a is useable for the supply voltage VDD, conductor 432b is useable for the word line WL_BS, conductor 432c is useable for the bit line BL_BS, conductor 432d is useable for the bit line bar BLB_BS, conductor 432e is useable for the word line WL_BS, and conductor 432f is useable for the supply voltage VDD, and in accordance with some embodiments.

Other M0 track assignments are within the scope of the present disclosure.

FIG. 4C is a diagram of a portion 400C of integrated circuit 400, simplified for case of illustration.

Portion 400C includes a region 450a2 and region 450b1.

Portion 400C is a variation of portion 400B, and similar detailed description is omitted for brevity. In comparison with portion 400B, region 450a2 of portion 400C replaces region 450al of FIG. 4B, and similar detailed description is omitted for brevity. In comparison with portion 400B, portion 400C does not include region 450cl, and similar detailed description is omitted for brevity.

Region 450a2 includes the set of active regions 402 and 404, the set of gates 406 and 408, the set of contacts 410, 414 and 416, the set of vias 420 and 424, and the set of conductors 430. Other M0 track assignments are within the scope of the present disclosure.

FIG. 4D is a diagram of a portion 400D of integrated circuit 400, simplified for ease of illustration.

Portion 400D includes a region 450a3 and region 450b1.

Portion 400D is a variation of portion 400B, and similar detailed description is omitted for brevity. In comparison with portion 400B, region 450a3 of portion 400D replaces region 450al of FIG. 4B, and similar detailed description is omitted for brevity. In comparison with portion 400B, portion 400D does not include region 450b1, and similar detailed description is omitted for brevity.

Region 450a3 includes the set of active regions 402 and 404, the set of gates 406 and 408, the set of contacts 412, 414 and 416, the set of vias 422 and 426, and the set of conductors 432.

Other M0 track assignments are within the scope of the present disclosure.

In some embodiments, at least one gate of the set of gates 406 or 408 are formed using a doped or non-doped polycrystalline silicon (or polysilicon). In some embodiments, at least one gate of the set of gates 406 or 408 include a metal, such as Al, Cu, W, Ti, Ta, TiN, TaN, NiSi, CoSi, other suitable conductive materials, or combinations thereof.

In some embodiments, at least one contact of the set of contacts 410, 412, 414 or 416, or at least one conductor of the set of conductors 430 or 432, or at least one via of the set of vias 420, 422, 424 or 426 includes one or more layers of a conductive material, a metal, a metal compound or a doped semiconductor. In some embodiments, the conductive material includes Tungsten, Cobalt, Ruthenium, Copper, or the like or combinations thereof. In some embodiments, a metal includes at least Cu (Copper), Co, W, Ru, Al, or the like. In some embodiments, a metal compound includes at least AlCu, W—TiN, TiSix, NiSix, TIN, TaN, or the like. In some embodiments, a doped semiconductor includes at least doped silicon, or the like.

In some embodiments, the gate isolation layer 494b electrically insulates gate 406b and gate 408b from each other. In some embodiments, the gate isolation layer 494a electrically insulates gate 406c and gate 408c from each other. In some embodiments, by electrically insulating gate 406b and gate 408b from each other, and electrically insulating gate 406c and gate 408c from each other, memory cell 400 can be used as a dual-port memory cell with a first port and a second port that occupies less area than other approaches.

In some embodiments, by including the set of insulating regions 494 in memory cell 400, gate 406b and 408b are separated from each other by insulating region 494b, thereby allowing NFET transistor N2-3 and PFET transistor P2-3 to be used as pass gate transistors of different corresponding ports of a dual-port memory cell (e.g., memory cell 400), thereby resulting in a memory cell 400 that occupies less area than other approaches.

In some embodiments, by including the set of insulating regions 494 in memory cell 400, gate 406c and 408c are separated from each other by insulating region 494a, thereby allowing NFET transistor N2-4 and PFET transistor P2-4 to be used as pass gate transistors of different corresponding ports of a dual-port memory cell (e.g., memory cell 400), thereby resulting in a memory cell 400 that occupies less area than other approaches.

In some embodiments, by including the set of insulating regions 494 in memory cell 400 causes memory cell 400 to include less active region (OD) tracks than other approaches resulting in a memory cell 400 that occupies less area than other approaches.

Other configurations or arrangements of integrated circuit 400 are within the scope of the present disclosure.

FIG. 5 is a diagram of a layout design 500 of an integrated circuit 600, in accordance with some embodiments.

Layout design 500 is a layout of an integrated circuit 600 of FIG. 6 or memory cell 200B. Layout design 300 is a layout of memory cell 200B of FIG. 2B.

Layout design 500 is a variation of layout design 300 of FIGS. 3A-3D, and similar detailed description is omitted for brevity.

In comparison with layout design 300 of FIGS. 3A-3D, a set of conductive feature patterns 530 replaces set of conductive feature patterns 330 of layout design 300, and a set of conductive feature patterns 532 replaces set of conductive feature patterns 332 of layout design 300, and similar detailed description is omitted for brevity.

In some embodiments, the set of active region patterns 302 in FIG. 5 corresponds to p-type transistors. In some embodiments, the set of active region patterns 302 in FIG. 5 corresponds to PFET transistors P2-1, P2-2, P2-3 and P2-4.

In some embodiments, the set of active region patterns 304 in FIG. 5 corresponds to N-type transistors. In some embodiments, the set of active region patterns 304 in FIG. 5 corresponds to NFET transistors N2-1, N2-2, N2-3 and N2-4.

Layout design 500 includes a region 550al, a region 550b1 and a region 550cl.

In comparison with layout design 300 of FIGS. 3A-3D, region 550al replaces region 350al of layout design 300, region 550b1 replaces region 350b1 of layout design 300, region 550cl replaces region 350cl of layout design 300, and similar detailed description is omitted for brevity.

Region 550al is similar to layout design 300 of FIGS. 3A-3D, but the set of conductive feature patterns 530 of region 550al replaces set of conductive feature patterns 330 of layout design 300, and the set of conductive feature patterns 532 of region 550al replaces set of conductive feature patterns 332 of layout design 300, and similar detailed description is omitted for brevity.

The set of conductive feature patterns 530 includes at least one of conductive feature pattern 530a, 530b, 530c, 530d, 530c or 530f.

The set of conductive feature patterns 532 includes at least one of conductive feature pattern 532a, 532b, 532c, 532d, 532c or 532f.

In comparison with layout design 300, conductive feature patterns 530a, 530b, 530c, 530d, 530e or 530f of the set of conductive feature patterns 530 replaces corresponding conductive feature patterns 330a, 330b, 330c, 330d, 330c or 330f of the set of conductive feature patterns 330, and similar detailed description is omitted for brevity.

In comparison with layout design 300, conductive feature patterns 532a, 532b, 532c, 532d, 532c or 532f of the set of conductive feature patterns 532 replaces corresponding conductive feature patterns 332a, 332b, 332c, 332d, 332c or 332f of the set of conductive feature patterns 332, and similar detailed description is omitted for brevity.

Region 550bl identifies BM0 track usage for the set of conductive feature patterns 530. Stated differently, region 550b1 identifies BM0 signals for corresponding conductive feature patterns in the set of conductive feature patterns 530 for the back-side of integrated circuit 600. For example, conductive feature pattern 530a is useable for the reference supply voltage VSS, conductive feature pattern 530b is useable for the word line WL_BS, conductive feature pattern 530c is useable for the bit line BL_BS, conductive feature pattern 530d is useable for the bit line bar BLB_BS, conductive feature pattern 530e is useable for the word line WL_BS, and conductive feature pattern 530f is useable for the reference supply voltage VSS, and in accordance with some embodiments.

Region 550cl identifies M0 track usage for the set of conductive feature patterns 532. Stated differently, region 550cl identifies M0 signals for corresponding conductive feature patterns in the set of conductive feature patterns 532 for the front-side of integrated circuit 600. For example, conductive feature pattern 532a is useable for the supply voltage VDD, conductive feature pattern 532b is useable for the word line WL_FS, conductive feature pattern 532c is useable for the bit line BL_FS, conductive feature pattern 532d is useable for the bit line bar BLB_FS, conductive feature pattern 532e is useable for the word line WL_FS, and conductive feature pattern 532f is useable for the supply voltage VDD, and in accordance with some embodiments.

Other M0 track assignments are within the scope of the present disclosure.

In some embodiments, layout design 500 achieves one or more of the benefits described herein.

Other configurations, arrangements on other layout levels or quantities of patterns in layout design 500 are within the scope of the present disclosure.

FIG. 6 is a diagram of an integrated circuit 600, in accordance with some embodiments.

Integrated circuit 600 is manufactured by layout design 500. In some embodiments, integrated circuit 600 is memory cell 200B.

Integrated circuit 600 is a variation of integrated circuit 400 of FIGS. 4A-4I, and similar detailed description is omitted for brevity.

In comparison with integrated circuit 400 of FIGS. 4A-4I, a set of conductors 630 replaces set of conductors 430 of integrated circuit 400, and a set of conductors 632 replaces set of conductors 432 of integrated circuit 400, and similar detailed description is omitted for brevity.

In some embodiments, the set of active regions 402 in FIG. 6 corresponds to p-type transistors. In some embodiments, the set of active regions 402 in FIG. 6 corresponds to PFET transistors P2-1, P2-2, P2-3 and P2-4.

In some embodiments, the set of active regions 404 in FIG. 6 corresponds to N-type transistors. In some embodiments, the set of active regions 404 in FIG. 6 corresponds to NFET transistors N2-1, N2-2, N2-3 and N2-4.

Integrated circuit 600 includes a region 650al, a region 650bl and a region 650cl.

In comparison with integrated circuit 400 of FIGS. 4A-4I, region 650al replaces region 450al of integrated circuit 400, region 650bl replaces region 450bl of integrated circuit 400, region 650cl replaces region 450cl of integrated circuit 400, and similar detailed description is omitted for brevity.

Region 650al is similar to integrated circuit 400 of FIGS. 4A-4I, but the set of conductors 630 of region 650al replaces set of conductors 430 of integrated circuit 400, and the set of conductors 632 of region 650al replaces set of conductors 432 of integrated circuit 400, and similar detailed description is omitted for brevity.

The set of conductors 630 includes at least one of conductor 630a, 630b, 630c, 630d, 630e or 630f.

The set of conductors 632 includes at least one of conductor 632a, 632b, 632c, 632d, 632e or 632f.

In comparison with integrated circuit 400, conductors 630a, 630b, 630c, 630d, 630e or 630f of the set of conductors 630 replaces corresponding conductors 430a, 430b, 430c, 430d, 430e or 430f of the set of conductors 430, and similar detailed description is omitted for brevity.

In comparison with integrated circuit 400, conductors 632a, 632b, 632c, 632d, 632e or 632f of the set of conductors 632 replaces corresponding conductors 432a, 432b, 432c, 432d, 432e or 432f of the set of conductors 432, and similar detailed description is omitted for brevity.

Region 650bl identifies BM0 track usage for the set of conductors 630. Stated differently, region 650b1 identifies BM0 signals for corresponding conductors in the set of conductors 630 for the back-side of integrated circuit 600. For example, conductor 630a is configured to supply the reference supply voltage VSS, conductor 630b is the word line WL_BS, conductor 630c is the bit line BL_BS, conductor 630d is the bit line bar BLB_BS, conductor 630e is the word line WL_BS, and conductor 630f is configured to supply the reference supply voltage VSS, and in accordance with some embodiments.

Region 650cl identifies M0 track usage for the set of conductors 632. Stated differently, region 650cl identifies M0 signals for corresponding conductors in the set of conductors 632 for the front-side of integrated circuit 600. For example, conductor 632a is configured to supply the supply voltage VDD, conductor 632b is the word line WL_FS, conductor 632c is the bit line BL_FS, conductor 632d is the bit line bar BLB_FS, conductor 632e is the word line WL_FS, and conductor 632f is configured to supply the supply voltage VDD, and in accordance with some embodiments. Other M0 track assignments are within the scope of the present disclosure.

In some embodiments, integrated circuit 600 achieves one or more of the benefits described herein.

Other configurations, arrangements on other layout levels or quantities of patterns in integrated circuit 600 are within the scope of the present disclosure.

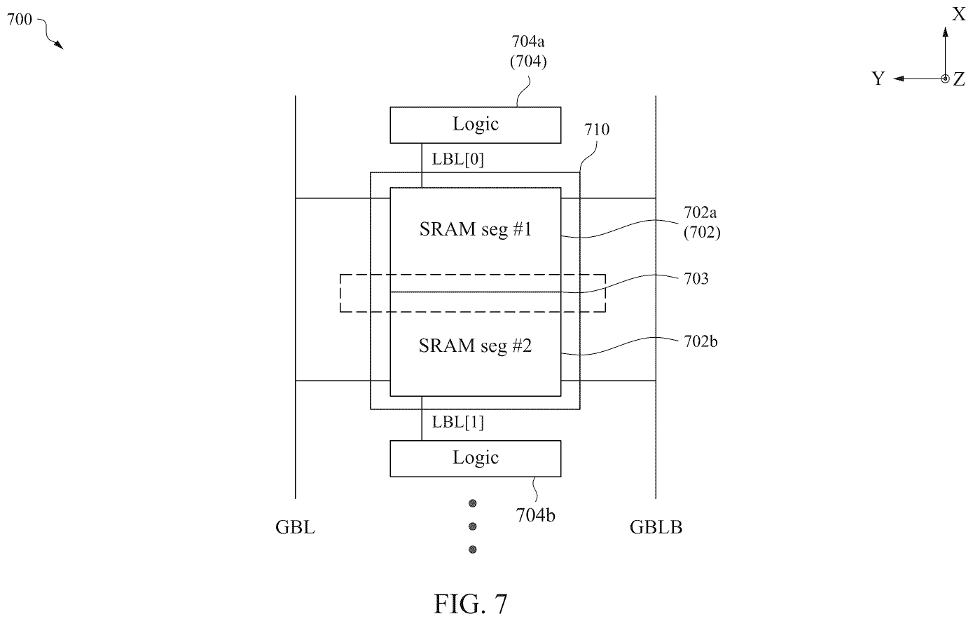

FIG. 7 is a block diagram of an integrated circuit 700, in accordance with some embodiments.

In some embodiments, integrated circuit 700 is at least one of memory partition 102A, 102B, 102C or 102D of FIG. 1, and similar detailed description is therefore omitted.

Integrated circuit 700 includes a memory circuit 701, a global bit line GBL, a global bit line bar GBLB, a local bit line LBL[0], a local bit line LBL[1] and a set of logic cells 704.

The memory circuit 701 is coupled to the global bit line GBL, the global bit line bar GBLB, the local bit line LBL[0], the local bit line LBL[1] and a set of logic cells 704.

In some embodiments, the set of logic cells 704 includes at least one of logic cell 704a or 704b.

The memory circuit 701 is coupled to the set of logic cells 704 by the local bit line LBL[0] and the local bit line LBL[1]. The memory circuit 701 is coupled to logic cell 704a by local bit line LBL[0] and coupled to logic cell 704b by local bit line LBL[1].

In some embodiments, the memory circuit 701 is coupled to GIO circuit 100BL (FIG. 1) by the global bit line GBL and the global bit line bar GBLB, and similar detailed description is therefore omitted.

In some embodiments, the memory circuit 701 includes one or more SRAM cells in an SRAM array (not labelled). In some embodiments, the memory circuit 701 includes one or more computing-in memory (CIM) SRAM cells in a CIM SRAM array (not labelled).

The memory circuit 701 includes a set of cells 702 and a set of set of edge cells 710. In some embodiments, the set of cells 702 includes a cell 702a and a cell 702b.

Cell 702a and cell 702b are adjacent to each other along a cell boundary 703. In some embodiments, adjacent elements are elements that are directly next to each other.

Cell 702a is coupled to logic cell 704a by local bit line LBL[0]. Cell 702a is further coupled to global bit line GBL and global bit line bar GBLB.

Cell 702b is coupled to logic cell 704b by local bit line LBL[1]. Cell 702b is further coupled to global bit line GBL and global bit line bar GBLB.

In some embodiments, cell 702a includes one or more first SRAM segments, and cell 702b includes one or more second SRAM segments. In some embodiments, the first SRAM segments are different from the second SRAM segments.

In some embodiments, cell 702a includes one or more first SRAM cells, and cell 702b includes one or more second SRAM cells. In some embodiments, the first SRAM cells are different from the second SRAM cells.

In some embodiments, at least one cell of cell 702a includes memory cell 200A of FIG. 2B, and similar detailed description is therefore omitted. In some embodiments, at least one cell of cell 702a includes memory cell 200B of FIG. 2B, and similar detailed description is therefore omitted.

In some embodiments, at least one cell of cell 702b includes memory cell 200A of FIG. 2B, and similar detailed description is therefore omitted. In some embodiments, at least one cell of cell 702b includes memory cell 200B of FIG. 2B, and similar detailed description is therefore omitted.

In some embodiments, cell 702a includes one or more first CIM SRAM cells, and cell 702b includes one or more second CIM SRAM cells. In some embodiments, the first CIM SRAM cells are different from the second CIM SRAM cells.

In some embodiments, integrated circuit 700 does not include one or more strap cells that are useable to separate the local bit line BL or the local bit line bar BLB of cell 702a from the local bit line BL or the local bit line bar BLB of cell 702b thereby reducing the use of multiplexers to separate the local bit line BL or the local bit line bar BLB of cell 702a from the local bit line BL or the local bit line bar BLB of cell 702b thus preventing one or more read disturbs when the pass gate transistors of one cell of the set of cells 702 that is coupled to the word line WL are turned on.

In some embodiments, memory circuit 701 does not include one or more strap cells that are useable to separate the local bit line BL or the local bit line bar BLB of cell 702a from the local bit line BL or the local bit line bar BLB of cell 702b thereby reducing the use of multiplexers to separate the local bit line BL or the local bit line bar BLB of cell 702a from the local bit line BL or the local bit line bar BLB of cell 702b thus preventing one or more read disturbs when the pass gate transistors of one cell of the set of cells 702 that is coupled to the word line WL are turned on.

Other configurations or arrangements of the set of cells 702 are within the scope of the present disclosure.

In some embodiments, the set of edge cells 710 includes one or more edge cells. In some embodiments, one or more edge cells of the set of edge cells 710 are arranged around a periphery of the set of cells 702.

In some embodiments, one or more edge cells of the set of edge cells 710 includes one or more dummy SRAM cells. In some embodiments, a dummy SRAM cell is a non-functional SRAM cell. In some embodiments, a non-functional SRAM cell does not perform any circuit function.

In some embodiments, an arrangement of one or more edge cells of the set of edge cells 710 is the same or similar to the set of cells 702. In some embodiments, one or more edge cells of the set of edge cells 710 is configured to have any suitable configuration.

In some embodiments, one or more edge cells of the set of edge cells 710 is configured to provide uniformity of one or more metal features, other features and/or fins. In some embodiments, the set of edge cells 710 is equal in quantity to a quantity of rows of the set of cells 702.

Other configurations or arrangements of the set of edge cells 710 are within the scope of the present disclosure.

The set of logic cells 704 includes at least one of a logic cell 704a or a logic cell 704b.

At least one of logic cell 704a or logic cell 704b includes one or more logic cells.

In some embodiments, logic cell 704a is the same as logic cell 704b. In some embodiments, logic cell 704a is different from logic cell 704b.

In some embodiments, the logic cell is part of a standard cell. In some embodiments, the logic cell includes an AND, OR, NAND, NOR, XOR, INV, AND-OR-Invert (AOI), OR-AND-Invert (OAI), MUX, Flip-flop, BUFF, Latch, delay, or clock cells. In some embodiments, the logic cell includes one or more active or passive elements. Examples of active elements include, but are not limited to, transistors and diodes. Examples of transistors include, but are not limited to, metal oxide semiconductor field effect transistors (MOSFET), complementary metal oxide semiconductor (CMOS) transistors, bipolar junction transistors (BJT), high voltage transistors, high frequency transistors, p-channel and/or n-channel field effect transistors (PFETs/NFETs), etc.), FinFETs, and planar MOS transistors with raised source/drain. Examples of passive elements include, but are not limited to, capacitors, inductors, fuses, and resistors.

Integrated circuit 700 is shown as including a single column and a single row of the set of cells 702. Other number of columns or other number of rows for integrated circuit 700 are within the scope of the present disclosure.

In some embodiments, integrated circuit 700 achieves one or more of the benefits described herein.

In some embodiments, by integrated circuit 700 not including one or more strap cells, integrated circuit 700 occupies less area than other approaches utilizing strap cells.

In some embodiments, by integrated circuit 700 not including one or more multiplexers, integrated circuit 700 occupies less area than other approaches utilizing or multiplexers.

Other configurations or arrangements of integrated circuit 700 are within the scope of the present disclosure.

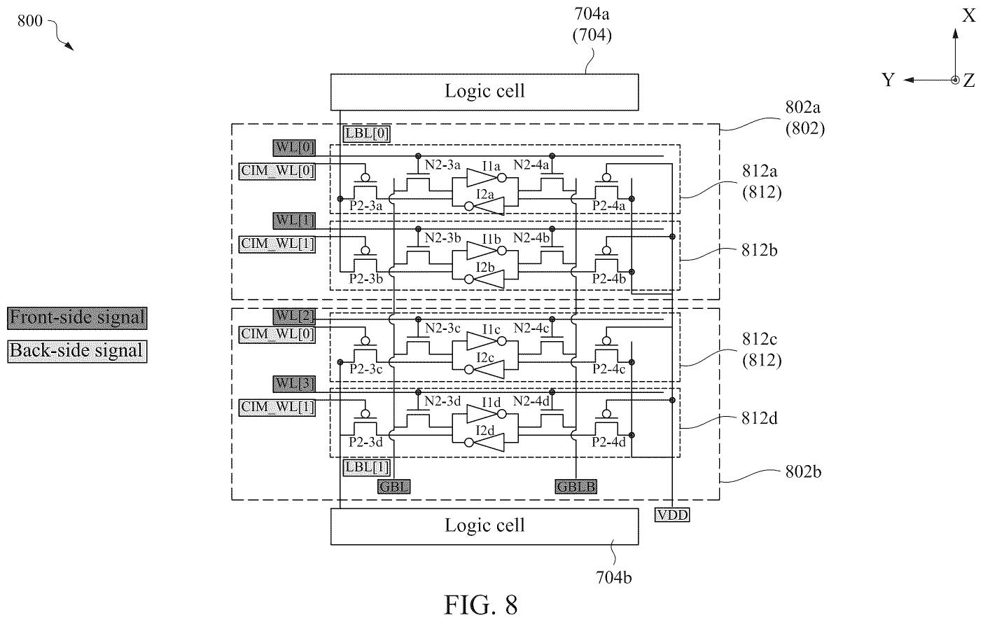

FIG. 8 is a circuit diagram of an integrated circuit 800, in accordance with some embodiments.

In some embodiments, integrated circuit 800 is at least one of memory partition 102A, 102B, 102C or 102D of FIG. 1, and similar detailed description is therefore omitted.

In some embodiments, integrated circuit 800 is usable in integrated circuit 700 of FIG. 7, in accordance with some embodiments.

Integrated circuit 800 includes the global bit line GBL, the global bit line bar GBLB, a set of cells 802, the local bit line LBL[0], the local bit line LBL[1] and the set of logic cells 704.

In some embodiments, the set of cells 802 is an embodiment the of set of cells 702, and similar detailed description is therefore omitted.

In some embodiments, the set of cells 802 includes at least one of a cell 802a or a cell 802b.

In some embodiments, cell 802a is an embodiment cell 702a, and similar detailed description is therefore omitted.

In some embodiments, cell 802b is an embodiment cell 702b, and similar detailed description is therefore omitted.

Cell 802a and cell 802b are adjacent to each other along cell boundary 703 (not labelled in FIG. 8).

Cell 802a includes a memory cell 812a and a memory cell 812b.

Cell 802b includes a memory cell 812c and a memory cell 812d.

Memory cells 812a and 812b are coupled to logic cell 704a by local bit line LBL[0]. Memory cells 812c and 812d are coupled to logic cell 704b by local bit line LBL[1].

Memory cells 812a, 812b 812c and 812d are coupled to the global bit line GBL and the global bit line bar GBLB.

In some embodiments, at least one of memory cell 812a or 812b is memory cell 200A of FIG. 2A, and similar detailed description is therefore omitted. In some embodiments, at least one of memory cell 812a or 812b is memory cell 200B of FIG. 2B, and similar detailed description is therefore omitted.

In some embodiments, at least one of memory cell 812c or 812d is memory cell 200A of FIG. 2A, and similar detailed description is therefore omitted. In some embodiments, at least one of memory cell 812c or 812d is memory cell 200B of FIG. 2B, and similar detailed description is therefore omitted.

In some embodiments, at least one or more of memory cells 812a, 812b, 812c or 812d is a corresponding CIM SRAM cell usable in performing one or more CIM operations.

Memory cell 812a comprises PFETs P2-3a and P2-4a, NFETs N2-3a and N2-4a and inverters I1a and I2a.

Memory cell 812b comprises PFETs P2-3b and P2-4b, and NFETs N2-3b and N2-4b and inverters I1b and I2b.

Memory cell 812c comprises PFETs P2-3c and P2-4c, and NFETs N2-3c and N2-4c and inverters I1c and I2c.

Memory cell 812d comprises PFETs P2-3d and P2-4d, and NFETs N2-3d and N2-4d and inverters I1d and I2d.

In some embodiments, at least one of PFETs P2-3a and P2-4a, NFETs N2-3a and N2-4a and inverters I1a and I2a is similar to corresponding PFETs P2-3 and P2-4 in FIG. 2A or 2B, corresponding NFETs N2-3 and N2-4 in FIG. 2A or 2B and corresponding inverters I1 and I2 in FIG. 2A or 2B, and similar detailed description is therefore omitted.

In some embodiments, at least one of PFETs P2-3b and P2-4b, NFETs N2-3b and N2-4b and inverters I1b and I2b is similar to corresponding PFETs P2-3 and P2-4 in FIG. 2A or 2B, corresponding NFETs N2-3 and N2-4 in FIG. 2A or 2B and corresponding inverters I1 and I2 in FIG. 2A or 2B, and similar detailed description is therefore omitted.

In some embodiments, at least one of PFETs P2-3c and P2-4c, NFETs N2-3c and N2-4c and inverters I1c and I2c is similar to corresponding PFETs P2-3 and P2-4 in FIG. 2A or 2B, corresponding NFETs N2-3 and N2-4 in FIG. 2A or 2B and corresponding inverters I1 and I2 in FIG. 2A or 2B, and similar detailed description is therefore omitted.

In some embodiments, at least one of PFETs P2-3d and P2-4d, NFETs N2-3d and N2-4d and inverters I1d and I2d is similar to corresponding PFETs P2-3 and P2-4 in FIG. 2A or 2B, corresponding NFETs N2-3 and N2-4 in FIG. 2A or 2B and corresponding inverters I1 and I2 in FIG. 2A or 2B, and similar detailed description is therefore omitted.

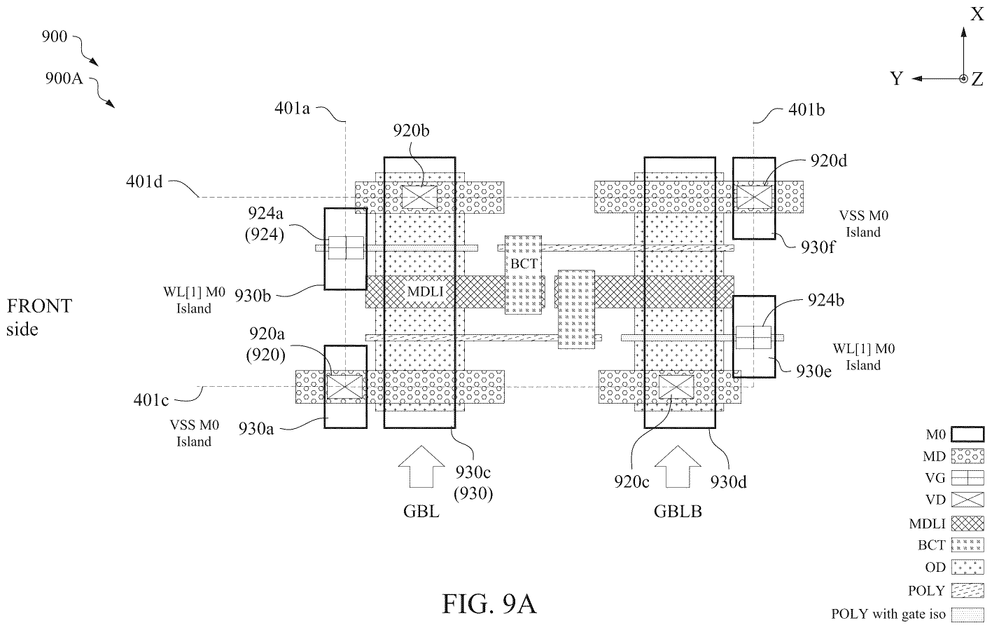

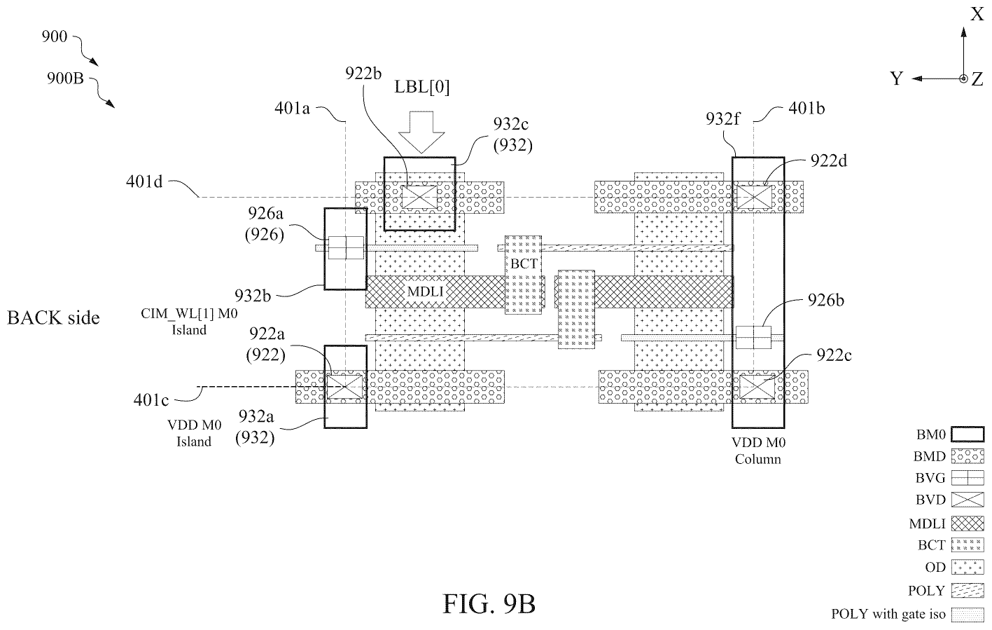

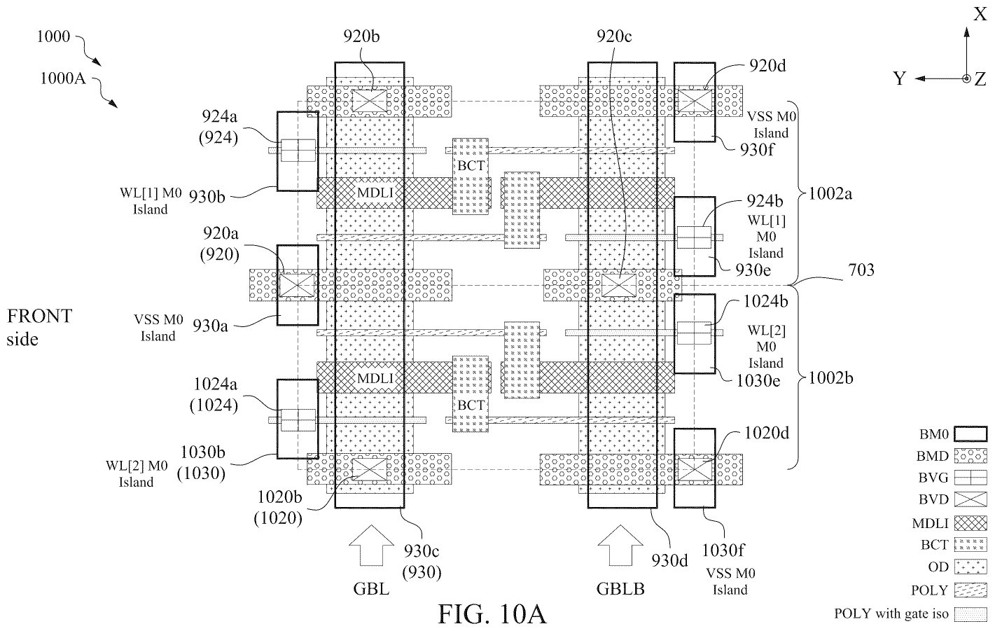

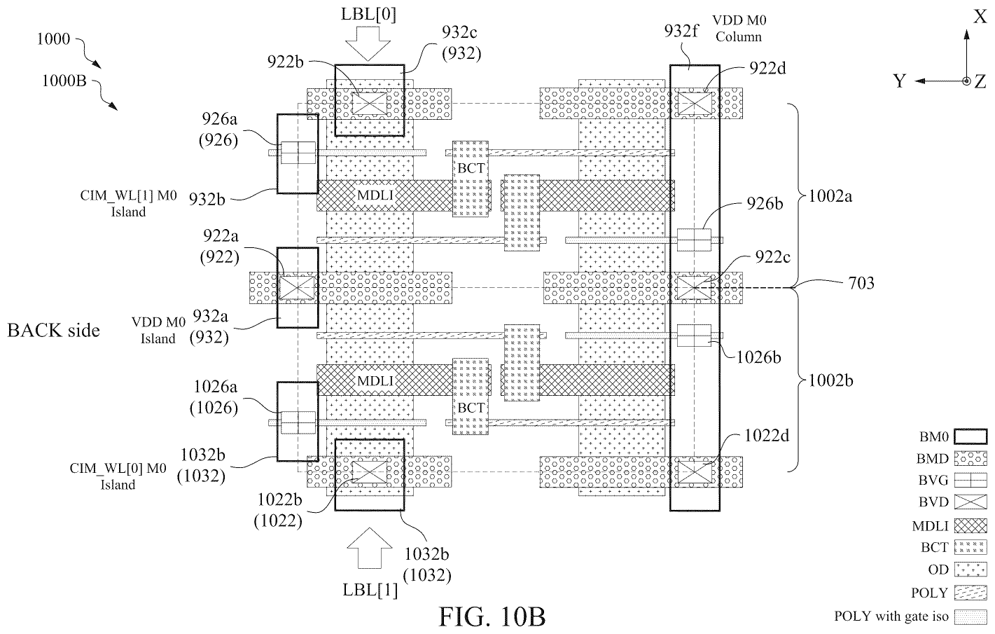

As shown in FIG. 8, each of a gate terminal of each of NFET transistors N2-3a and N2-4a are coupled with a word line WL[0]. In some embodiments, the word line WL[0] is located on a front-side of integrated circuit 900 (FIGS. 9A-9B) or 1000 (FIGS. 10A-10B).

As shown in FIG. 8, each of a gate terminal of each of NFET transistors N2-3b and N2-4b are coupled with a word line WL[1]. In some embodiments, the word line WL[1] is located on a front-side of integrated circuit 900 (FIGS. 9A-9B) or 1000 (FIGS. 10A-10B).

As shown in FIG. 8, each of a gate terminal of each of NFET transistors N2-3c and N2-4c are coupled with a word line WL[2]. In some embodiments, the word line WL[2] is located on a front-side of integrated circuit 900 (FIGS. 9A-9B) or 1000 (FIGS. 10A-10B).

As shown in FIG. 8, each of a gate terminal of each of NFET transistors N2-3d and N2-4d are coupled with a word line WL[3]. In some embodiments, the word line WL[3] is located on a front-side of integrated circuit 900 (FIGS. 9A-9B) or 1000 (FIGS. 10A-10B).

As shown in FIG. 8, a gate terminal of PFET transistor P2-3a is coupled with a CIM word line CIM_WL[0]. In some embodiments, the CIM word line CIM_WL[0] is located on a back-side of integrated circuit 900 (FIGS. 9A-9B) or 1000 (FIGS. 10A-10B). In some embodiments, the CIM word line CIM_WL[0] is usable to carry a corresponding CIM word line signal. In some embodiments, at least one of memory cell 812a or 812c is configured to perform a CIM operation based on the corresponding CIM word line signal.

As shown in FIG. 8, a gate terminal of PFET transistor P2-3b is coupled with a CIM word line CIM_WL[1]. In some embodiments, the CIM word line CIM_WL[1] is located on a back-side of integrated circuit 900 (FIGS. 9A-9B) or 1000 (FIGS. 10A-10B). In some embodiments, the CIM word line CIM_WL[1] is usable to carry a corresponding CIM word line signal. In some embodiments, at least one of memory cell 812b or 812d is configured to perform a CIM operation based on the corresponding CIM word line signal.

As shown in FIG. 8, a gate terminal of PFET transistor P2-3c is coupled with a CIM word line CIM_WL[0].

As shown in FIG. 8, a gate terminal of PFET transistor P2-3d is coupled with a CIM word line CIM_WL[1].

Each of a gate terminal of PFET transistor P2-4a, a gate terminal of PFET transistor P2-4b, a gate terminal of PFET transistor P2-4c, a gate terminal of PFET transistor P2-4d, a drain terminal of PFET transistor P2-4a, a drain terminal of PFET transistor P2-4b, a drain terminal of PFET transistor P2-4c and a drain terminal of PFET transistor P2-4d are coupled together, and are further coupled to the voltage supply VDD.

Each of a drain terminal of NFET transistor N2-3a, a drain terminal of NFET transistor N2-3b, a drain terminal of NFET transistor N2-3c and a drain terminal of NFET transistor N2-3d are coupled to the global bit line GBL.

Each of a drain terminal of NFET transistor N2-4a, a drain terminal of NFET transistor N2-4b, a drain terminal of NFET transistor N2-4c and a drain terminal of NFET transistor N2-4d are coupled to the global bit line bar GBLB.

Each of a drain terminal of PFET transistor P2-3a and a drain terminal of PFET transistor P2-3b are coupled together, and are further coupled to the logic cell 704a by the local bit line LBL[0].

Each of a drain terminal of PFET transistor P2-3c and a drain terminal of PFET transistor P2-3d are coupled together, and are further coupled to the logic cell 704b by the local bit line LBL[1].

In some embodiments, at least one of the global bit line GBL or the global bit line bar GBLB is located on the front-side of integrated circuit 900 (FIGS. 9A-9B) or 1000 (FIGS. 10A-10B).

In some embodiments, at least one of the local bit line LBL[0] or the local bit line LBL[1] is located on the back-side of integrated circuit 900 (FIGS. 9A-9B) or 1000 (FIGS. 10A-10B).

In some embodiments, at least the voltage supply VDD is located on the back-side of integrated circuit 900 (FIGS. 9A-9B) or 1000 (FIGS. 10A-10B).

Other configurations or arrangements of the set of cells 802 are within the scope of the present disclosure. For example, in some embodiments, one or more elements in integrated circuit 800 that is located on the front side can be located on the backside and vice versa.

Integrated circuit 800 is shown as including a single column and a single row of the set of cells 802. Other number of columns or other number of rows for integrated circuit 800 are within the scope of the present disclosure.

In some embodiments, integrated circuit 800 achieves one or more of the benefits described herein.

Other configurations or arrangements of integrated circuit 800 are within the scope of the present disclosure.

FIGS. 9A-9B are diagrams of an integrated circuit 900, in accordance with some embodiments.

FIGS. 9A-9B are corresponding diagrams of corresponding portions 900A-900B of an integrated circuit 900, simplified for case of illustration.

Portion 900A includes one or more features of integrated circuit 900 of the OD level, the POLY level, the MD level, the MDLI level, the BCT level, the M0 level, the VG level and the VD level. Portion 900A is manufactured by a layout design similar to portion 300C.

Portion 900B includes one or more features of integrated circuit 900 of the OD level, the POLY level, the BMD level, the MDLI level, the BCT level, the BM0 level, the BVG level, and the BVD level. Portion 900B is manufactured by a layout design similar to portion 300D.

In some embodiments, integrated circuit 900 is similar to at least a portion of integrated circuit 400 of FIG. 4A rotated by 90 degrees in the counterclockwise direction, and similar detailed description is therefore omitted. For example, as shown in FIGS. 9A-9B, each of gridlines 401a, 401b, 401c and 401d are rotated 90 degrees in the counterclockwise direction in comparison with corresponding gridlines 401a, 401b, 401c and 401d in FIG. 4A, and similar detailed description is therefore omitted.

In some embodiments, integrated circuit 900 is a top view of a portion of integrated circuit 800 of FIG. 8, and similar detailed description is therefore omitted. For example, in some embodiments, integrated circuit 800 is a top view of memory cell 812b, and similar detailed description is therefore omitted. In some embodiments, integrated circuit 800 is a top view of at least one of memory cell 812a, 812c or 812d, and similar detailed description is therefore omitted.

Integrated circuit 900 is manufactured by a layout design similar to at least layout design 300, and similar detailed description is therefore omitted.

Integrated circuit 900 includes at least the set of active regions 402 and 404, the set of gates 406 and 408, the set of contacts 410, the set of contacts 412, the set of contacts 414, the set of contacts 416, a set of conductors 930, a set of conductors 932, a set of vias 920, a set of vias 922, a set of vias 924, a set of vias 926, the substrate 490, the insulating region 492 and the set of insulating regions 494.

Integrated circuit 900 is a variation of integrated circuit 400 of FIGS. 4A-4I, and similar detailed description is omitted for brevity.

In comparison with integrated circuit 400 of FIGS. 4A-4I, a set of conductors 930 replaces set of conductors 430 of integrated circuit 400, a set of conductors 932 replaces set of conductors 432 of integrated circuit 400, a set of vias 920 replaces set of vias 420 of integrated circuit 400, a set of vias 922 replaces set of vias 422 of integrated circuit 400, a set of vias 924 replaces set of vias 424 of integrated circuit 400, a set of vias 926 replaces set of vias 426 of integrated circuit 400, and similar detailed description is omitted for brevity.

The set of conductors 930 includes at least one of conductor 930a, 930b, 930c, 930d, 930e or 930f.

In comparison with integrated circuit 400, conductors 930a, 930b, 930c, 930d, 930e or 930f of the set of conductors 930 replaces corresponding conductors 430a, 430b, 430c, 430d, 430e or 430f of the set of conductors 430, and similar detailed description is omitted for brevity.

In comparison with conductor 430c of integrated circuit 400, conductor 930c overlaps active regions 402a and 404a. In some embodiments, conductor 930c is configured as the global bit line GBL.

In comparison with conductor 430d of integrated circuit 400, conductor 930d overlaps active regions 402b and 404b. In some embodiments, conductor 930d is configured as the global bit line bar GBLB.

In some embodiments, conductor 930a is configured as a reference voltage supply VSS island that is coupled to the source terminal of NFET N2-1b of FIG. 8.

In some embodiments, conductor 930f is configured as a reference voltage supply VSS island that is coupled to the source terminal of NFET N2-2b of FIG. 8.

In some embodiments, conductor 930b is configured as a word line island WL[1] that is coupled to the gate terminal of NFET N2-3b of FIG. 8. In some embodiments, conductor 930b is configured as a word line island of WL[0], WL[2] or WL[3] of corresponding memory cells 812a, 812c or 812d.

In some embodiments, conductor 930e is configured as a word line island WL[1] that is coupled to the gate terminal of NFET N2-4b of FIG. 8. In some embodiments, conductor 930e is configured as a word line island of WL[0], WL[2] or WL[3] of corresponding memory cells 812a, 812c or 812d.

The set of conductors 932 includes at least one of conductor 932a, 932b, 932c, 932d, 932e or 932f.

In comparison with integrated circuit 400, conductors 932a, 932b or 932c of the set of conductors 932 replaces corresponding conductors 432a, 432b or 432c of the set of conductors 432, and similar detailed description is omitted for brevity.

In comparison with integrated circuit 400, conductor 932f of the set of conductors 932 replaces corresponding conductors 432e and 432f of the set of conductors 432, and similar detailed description is omitted for brevity.

In some embodiments, conductor 932c is configured as the local bit line LBL[0].

In comparison with conductors 432e and 432f of integrated circuit 400, conductor 932f is overlapped by contacts 410d and 412d, gates 406c and 408c and contacts 410c and 412c, and similar detailed description is omitted for brevity.

Conductor 932f is not overlapped by active regions 402b and 404b.

In some embodiments, conductor 932a is configured as a voltage supply VDD island that is coupled to the source terminal of PFET P2-1b of FIG. 8.

In some embodiments, conductor 932f is configured as a voltage supply VDD island that is coupled to the source terminal of PFET P2-2b of FIG. 8, the gate terminal of PFET P2-4b of FIG. 8 and the source terminal of PFET P2-4b of FIG. 8.

In some embodiments, conductor 932b is configured as a CIM word line island WL[1] that is coupled to the gate terminal of PFET P2-3b of FIG. 8. In some embodiments, conductor 932b is configured as a CIM word line island of WL[0], WL[2] or WL[3] of corresponding memory cells 812a, 812c or 812d.

Other configurations, arrangements on other levels or quantities of conductors in the set of conductors 930 and 932 are within the scope of the present disclosure.

The set of vias 920 includes at least one of via 920a, 920b, 920c or 920d.

In comparison with integrated circuit 400, vias 920a, 920b, 920c or 920d of the set of vias 920 replaces corresponding vias 420a, 420b, 420c or 420d of the set of vias 420, and similar detailed description is omitted for brevity.

Via 920a electrically couples conductor 930a and contact 410a together. Via 920b electrically couples conductor 930c and contact 410b together. Via 920c electrically couples conductor 930d and contact 410c together. Via 920d electrically couples conductor 930f and contact 410d together. The set of vias 922 includes at least one of via 922a, 922b, 922c or 922d.

In comparison with integrated circuit 400, vias 922a, 922b, 922c or 922d of the set of vias 922 replaces corresponding vias 422a, 422b, 422c or 422d of the set of vias 422, and similar detailed description is omitted for brevity.

Via 922a electrically couples conductor 932a and contact 412a together. Via 922b electrically couples conductor 932c and contact 412b together. Via 922c electrically couples conductor 932f and contact 412c together. Via 922d electrically couples conductor 932f and contact 412d together. The set of vias 924 includes at least one of via 924a or 924b.

In comparison with integrated circuit 400, vias 924a or 924b of the set of vias 924 replaces corresponding vias 424a or 424b of the set of vias 424, and similar detailed description is omitted for brevity.

Via 924a electrically couples conductor 930b and gate 406b together. Via 924b electrically couples conductor 930e and gate 406c together.

The set of vias 926 includes at least one of via 926a or 926b.

In comparison with integrated circuit 400, vias 926a or 926b of the set of vias 926 replaces corresponding vias 426a or 426b of the set of vias 426, and similar detailed description is omitted for brevity.

Via 926a electrically couples conductor 932b and gate 408b together. Via 926b electrically couples conductor 932f and gate 408c together.

Other configurations, arrangements on other levels or quantities of vias in the set of vias 920, 922, 924 and 926 are within the scope of the present disclosure.

Other M0 and BM0 track assignments are within the scope of the present disclosure.

In some embodiments, integrated circuit 900 achieves one or more of the benefits described herein.

Other configurations, arrangements on other levels or quantities of patterns in integrated circuit 900 are within the scope of the present disclosure.

FIGS. 10A-10B are diagrams of an integrated circuit 1000, in accordance with some embodiments.

FIGS. 10A-10B are corresponding diagrams of corresponding portions 1000A-1000B of an integrated circuit 1000, simplified for ease of illustration.

Portion 1000A includes one or more features of integrated circuit 1000 of the OD level, the POLY level, the MD level, the MDLI level, the BCT level, the M0 level, the VG level and the VD level. Portion 1000A is manufactured by a layout design similar to portion 300C.

Portion 1000B includes one or more features of integrated circuit 1000 of the OD level, the POLY level, the BMD level, the MDLI level, the BCT level, the BM0 level, the BVG level, and the BVD level. Portion 1000B is manufactured by a layout design similar to portion 300D.

Integrated circuit 1000 includes a region 1002a and a region 1002b.

Region 1002a is adjacent to region 1002b.

Region 1002a is aligned with region 1002b along boundary 703.

In some embodiments, region 1002a is integrated circuit 900 of FIGS. 9A-9B, and similar detailed description is therefore omitted.

In some embodiments, region 1002b is a mirror image of region 1002a with respect to boundary 703, and similar detailed description is omitted for brevity. Stated differently, region 1002b is region 1002a rotated 180 degrees with respect to boundary 703, and similar detailed description is omitted for brevity.

In some embodiments, integrated circuit 1000 is a top view of a portion of integrated circuit 800 of FIG. 8, and similar detailed description is therefore omitted. For example, in some embodiments, integrated circuit 800 is a top view of memory cells 812b and 812c, and similar detailed description is therefore omitted. In some embodiments, integrated circuit 800 is a top view of memory cells 812a and 812b, and similar detailed description is therefore omitted. In some embodiments, integrated circuit 800 is a top view of memory cells 812c and 812d, and similar detailed description is therefore omitted.

Integrated circuit 1000 is manufactured by a layout design similar to at least layout design 300, and similar detailed description is therefore omitted.

Region 1002a includes at least the set of active regions 402 and 404, the set of gates 406 and 408, the set of contacts 410, the set of contacts 412, the set of contacts 414, the set of contacts 416, a set of conductors 930, a set of conductors 932, a set of vias 920, a set of vias 922, a set of vias 924, a set of vias 926, the substrate 490, the insulating region 492 and the set of insulating regions 494.

Region 1002b includes at least the set of active regions 402 and 404, the set of gates 406 and 408, the set of contacts 410, the set of contacts 412, the set of contacts 414, the set of contacts 416, a set of conductors 1030, a set of conductors 1032, a set of vias 1020, a set of vias 1022, a set of vias 1024, a set of vias 1026, the substrate 490, the insulating region 492 and the set of insulating regions 494.

Region 1002b is a variation of region 1002a of FIGS. 10A-10B, and similar detailed description is omitted for brevity.

In comparison with region 1002a of FIGS. 10A-10B, a set of conductors 1030 replaces set of conductors 930 of region 1002a, a set of conductors 1032 replaces set of conductors 932 region 1002a, a set of vias 1020 replaces set of vias 920 of region 1002a, a set of vias 1022 replaces set of vias 922 of region 1002a, a set of vias 1024 replaces set of vias 924 of region 1002a, a set of vias 1026 replaces set of vias 926 of region 1002a, and similar detailed description is omitted for brevity. The set of conductors 1030 includes at least one of conductor 1030b, 1030e or 1030f.

In comparison with region 1002a, conductors 1030b, 1030e or 1030f of the set of conductors 1030 replace corresponding conductors 930b, 930e or 930f of the set of conductors 930, and similar detailed description is omitted for brevity.

In comparison with conductor 430c of integrated circuit 400, conductor 930c of FIGS. 10A-10B overlaps active regions 402a and 404a of regions 1002a and 1002b. In some embodiments, conductor 930c is configured as the global bit line GBL.

In comparison with conductor 430d of integrated circuit 400, conductor 930d of FIGS. 10A-10B overlaps active regions 402b and 404b of regions 1002a and 1002b. In some embodiments, conductor 930d is configured as the global bit line bar GBLB.

In some embodiments, conductor 1030f is configured as a reference voltage supply VSS island that is coupled to the source terminal of NFET N2-2c of FIG. 8.

In some embodiments, conductor 1030b is configured as a word line island WL[2] that is coupled to the gate terminal of NFET N2-3c of FIG. 8. In some embodiments, conductor 1030b is configured as a word line island of WL[0], WL[1] or WL[3] of corresponding memory cells 812a, 812b or 812d.

In some embodiments, conductor 1030e is configured as a word line island WL[2] that is coupled to the gate terminal of NFET N2-4c of FIG. 8. In some embodiments, conductor 1030e is configured as a word line island of WL[0], WL[1] or WL[3] of corresponding memory cells 812a, 812b or 812d.

The set of conductors 1032 includes at least one of conductor 1032b or 1032c.

In comparison with region 1002a, conductors 1032b or 1032c of the set of conductors 1032 replaces corresponding conductors 932b or 932c of the set of conductors 932, and similar detailed description is omitted for brevity.

In some embodiments, conductor 1032c is configured as the local bit line LBL[1].

In some embodiments, conductor 1032b is configured as a CIM word line island WL[0] that is coupled to the gate terminal of PFET P2-3c of FIG. 8. In some embodiments, conductor 1032b is configured as a CIM word line island of WL[1] of memory cells 812a, 812b or 812d.

In comparison with integrated circuit 900, conductor 932f of the set of conductors 932 of FIG. 10B is overlapped by contacts 410d and 412d of region 1002a, gates 406c and 408c of region 1002a, contacts 410c and 412c of region 1002a, contacts 410d and 412d of region 1002b, gates 406c and 408c of region 1002b and contacts 410c and 412c of region 1002b.

In comparison with integrated circuit 900, conductor 932f of the set of conductors 932 of FIG. 10B is not overlapped by active regions 402b and 404b of region 1002a and active regions 402b and 404b of region 1002b.

In some embodiments, conductor 932f of FIG. 10B is configured as a voltage supply VDD island that is coupled to the source terminal of PFET P2-2b of FIG. 8, the gate terminal of PFET P2-4b of FIG. 8, the source terminal of PFET P2-4b of FIG. 8, the source terminal of PFET P2-2c of FIG. 8, the gate terminal of PFET P2-4c of FIG. 8 and the source terminal of PFET P2-4c of FIG. 8.

In some embodiments, conductor 932f of FIG. 10B is configured to electrically couple contacts 410d and 412d of region 1002a, gates 406c and 408c of region 1002a, contacts 410c and 412c of region 1002a, contacts 410d and 412d of region 1002b, gates 406c and 408c of region 1002b and contacts 410c and 412c of region 1002b together.

Other configurations, arrangements on other levels or quantities of conductors in the set of conductors 1030 and 1032 are within the scope of the present disclosure.

The set of vias 1020 includes at least one of via 1020b or 1020d.

In comparison with region 1002a, vias 1020b or 1020d of the set of vias 1020 replaces corresponding vias 920b or 920d of the set of vias 920, and similar detailed description is omitted for brevity.

Via 1020b electrically couples conductor 930c and contact 410b of region 1002b together. Via 1020d electrically couples conductor 1030f and contact 410d of region 1002b together.

In some embodiments, the conductor 930c in FIG. 10A is configured as the global bit line GBL.

In some embodiments, the conductor 930d in FIG. 10A is configured as the global bit line bar GBLB.

The set of vias 1022 includes at least one of via 1022b or 1022d.

In comparison with region 1002a, vias 1022b or 1022d of the set of vias 1022 replaces corresponding vias 922b or 922d of the set of vias 922, and similar detailed description is omitted for brevity.

Via 1022b electrically couples conductor 1032c and contact 412b of region 1002b together. Via 1022d electrically couples conductor 932f and contact 412d of region 1002b together.

The set of vias 1024 includes at least one of via 1024a or 1024b.

In comparison with region 1002a, vias 1024a or 1024b of the set of vias 1024 replaces corresponding vias 924a or 924b of the set of vias 924, and similar detailed description is omitted for brevity.

Via 1024a electrically couples conductor 1030b and gate 406b of region 1002b together. Via 1024b electrically couples conductor 1030e and gate 406c of region 1002b together.

The set of vias 1026 includes at least one of via 1026a or 1026b.

In comparison with region 1002a, vias 1026a or 1026b of the set of vias 1026 replaces corresponding vias 926a or 926b of the set of vias 926, and similar detailed description is omitted for brevity.

Via 1026a electrically couples conductor 1032b and gate 408b of region 1002b together. Via 1026b electrically couples conductor 932f and gate 408c of region 1002b together.

In some embodiments, conductor 932f of FIGS. 10A-10B is configured to supply the voltage supply VDD from the back-side of integrated circuit 1000.

In some embodiments, conductor 932f of FIGS. 10A-10B is configured to supply the voltage supply VDD to each of the gate terminal of PFET transistor P2-4b, the gate terminal of PFET transistor P2-4c, the drain terminal of PFET transistor P2-4b and the drain terminal of PFET transistor P2-4c.

Other configurations, arrangements on other levels or quantities of vias in the set of vias 1020, 1022, 1024 and 1026 are within the scope of the present disclosure.

Other M0 and BM0 track assignments are within the scope of the present disclosure.

In some embodiments, integrated circuit 1000 achieves one or more of the benefits described herein.

Other configurations, arrangements on other levels or quantities of patterns in integrated circuit 1000 are within the scope of the present disclosure.

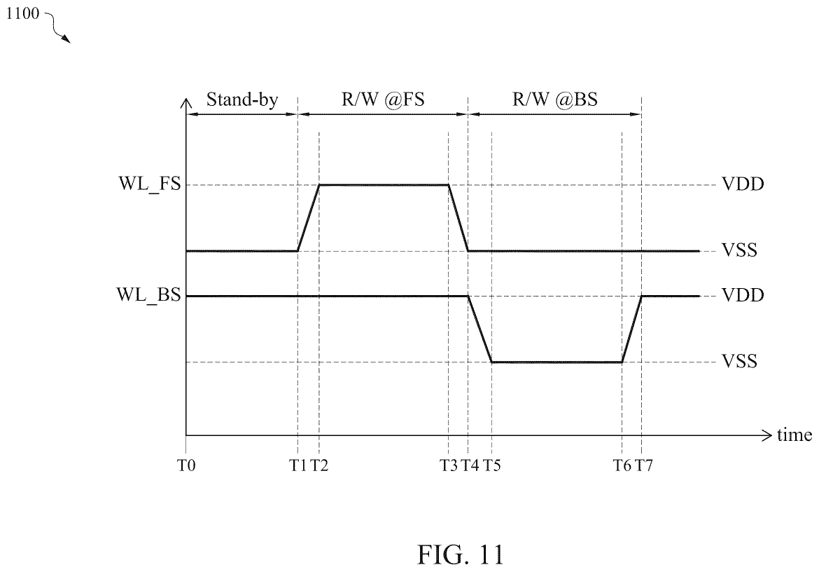

FIG. 11 is a timing diagram 1100 of waveforms of a memory cell 200A, in accordance with some embodiments.

In some embodiments, FIG. 11 is a corresponding timing diagram 1100 of waveforms of memory circuit 100 in FIG. 1, in accordance with some embodiments.

In some embodiments, timing diagram 1100 includes waveforms of signals during a read operation and/or a write operation of memory cell 200A. In some embodiments, the waveforms of signals during a write operation of memory cell 200A are the same as the waveforms of signals during a read operation of memory cell 200A, and are shown as timing diagram 1100.

In some embodiments, FIG. 11 is usable as a timing diagram of waveforms of memory cell 200B in FIG. 2B, but in these embodiments the waveforms are inverted with respect to the waveforms of memory cell 200A in FIG. 2A, in accordance with some embodiments.

Timing diagram 1100 includes waveforms of a front-side word line signal WL_FS and a back-side word line signal WL_BS.

In some embodiments, the front-side word line signal WL_FS of FIG. 11 is useable as one or more of word line signal WL[0], WL[1], WL[2] or WL[3] of FIG. 8, and similar detailed description is therefore omitted.

In some embodiments, the back-side word line signal WL_BS of FIG. 11 is useable as one or more of word line signal CIM_WL[0] or CIM_WL[1] of FIG. 8, and similar detailed description is therefore omitted.

FIG. 11 is a timing diagram 1100 of waveforms of memory circuit 200A in FIG. 2A, in accordance with some embodiments.

In some embodiments, timing diagram 1100 is described with respect to memory cell 812b, but is also applicable to one or more of memory cells 812a, 812c or 812d, and similar detailed description is therefore omitted.

In some embodiments, timing diagram 1100 is described with respect to memory cell 812b, and thus the front-side word line signal WL_FS of FIG. 11 is useable as word line signal WL[1], and the back-side word line signal WL_BS of FIG. 11 is useable as word line signal CIM_WL[1], and similar detailed description is therefore omitted.

At time TO in FIG. 11, word line signal WL[1] is logically low (e.g., reference voltage VSS or “Logic 0”), and word line signal CIM_WL[1] is logically high (e.g., voltage VDD or “Logic 1”).

For example, at time TO, NFET transistors N2-3b and N2-4b are turned off in response to the word line signal WL[1] being logically low. For example, at time TO, PFET transistors P2-3b and P2-4b are turned off in response to the word line signal CIM_WL[1] being logically high.

At time T1 in FIG. 11, the word line signal WL[1] transitions from logically low to logically high, thereby causing NFET transistors N2-3b and N2-4b to turn on, thereby coupling the global bit line GBL and node ND together, and coupling the global bit line bar GBLB and node NDB together.

At time T2 in FIG. 11, the word line signal WL[1] is logically high, and the NFET transistors N2-3b and N2-4b are turned on.

At time T3 in FIG. 11, the word line signal WL[1] transitions from logically high to logically low, thereby causing NFET transistors N2-3b and N2-4b to turn off, thereby decoupling the global bit line GBL and node ND from each other, and decoupling the global bit line bar GBLB and node NDB from each other.

At time T4 in FIG. 11, the word line signal WL[1] is logically low, and the NFET transistors N2-3b and N2-4b are turned off.

At time T4 in FIG. 11, the word line signal CIM_WL[1] transitions from logically high to logically low, thereby causing PFET transistors P2-3b and P2-4b to turn on, thereby coupling the local bit line LBL[0] and node ND together, and coupling the voltage supply VDD and node NDB together.

At time T5 in FIG. 11, the word line signal CIM_WL[1] is logically low, and the PFET transistors P2-3b and P2-4b are turned on.

At time T6 in FIG. 11, the word line signal CIM_WL[1] transitions from logically low to logically high, thereby causing PFET transistors P2-3b and P2-4b to turn off, thereby decoupling the local bit line LBL[0] and node ND from each other, and decoupling the voltage supply VDD and node NDB from each other.

At time T7 in FIG. 11, the word line signal CIM_WL[1] is logically high, and the PFET transistors P2-3b and P2-4b are turned off.

In some embodiments, the front-side pass gate transistors (e.g., NFET transistors N2-3b and N2-4b) of memory cell 200A are turned on by the word line signal WL[1]. In some embodiments, the front-side pass gate transistors (e.g., NFET transistors N2-3b and N2-4b) of memory cell 200A are turned on between time T1 and time T4, and time T1 and time T4 corresponds to the front-side read/write operation of memory cell 200A.

In some embodiments, the back-side pass gate transistors (e.g., PFET transistors P2-3b and P2-4b) of memory cell 200A are turned on by the word line signal CIM_WL[1]. In some embodiments, the back-side pass gate transistors (e.g., PFET transistors P2-3b and P2-4b) of memory cell 200A are turned on between time T4 and time T7, and time T4 and time T7 corresponds to the back-side read/write operation of memory cell 200A.

In some embodiments, the back-side pass gate transistors (e.g., PFET transistors P2-3b and P2-4b) of memory cell 200A are turned on during a different time window from when the front-side pass gate transistors (e.g., NFET transistors N2-3b and N2-4b) of memory cell 200A are turned on, thereby preventing a dummy read disturb from occurring in memory cell 200A during a write operation thereby improving the performance of memory cell 200A compared to other approaches.

In some embodiments, by utilizing timing diagram 1100, memory circuit 200A operates to achieve one or more benefits described herein including the details discussed herein.

Other configurations of timing diagram 1100 are within the scope of the present disclosure.

FIG. 12 is a functional flow chart of a method 1200 of manufacturing an IC device, in accordance with some embodiments. It is understood that additional operations may be performed before, during, and/or after the method 1200 depicted in FIG. 12, and that some other processes may only be briefly described herein.

In some embodiments, other order of operations of method 1200-1400 is within the scope of the present disclosure. Method 1200-1400 includes exemplary operations, but the operations are not necessarily performed in the order shown. Operations may be added, replaced, changed order, and/or eliminated as appropriate, in accordance with the spirit and scope of disclosed embodiments. In some embodiments, one or more of the operations of at least method 1200, 1300 or 1400 is not performed.

In some embodiments, method 1200 is an embodiment of operation 1304 of method 1300. In some embodiments, the methods 1200-1400 are usable to manufacture or fabricate at least integrated circuit 100, 200A, 200B, 400, 600, 700, 800, 900 or 1000, or an integrated circuit with similar features as at least layout design 300 or 500.

In operation 1202 of method 1200, a first set of transistors and a second set of transistors are fabricated on a front-side 403a of a semiconductor wafer or substrate. In some embodiments, the first set of transistors or the second set of transistors of method 1200 includes one or more transistors in at least the set of active regions 402 or 404. In some embodiments, the first set of transistors or the second set of transistors of method 1200 includes one or more transistors described herein.

In some embodiments, operation 1202 includes fabricating source and drain regions of the set of transistors in a first well. In some embodiments, the first well comprises p-type dopants. In some embodiments, the p-dopants include boron, aluminum or other suitable p-type dopants. In some embodiments, the first well comprises an epi-layer grown over a substrate. In some embodiments, the epi-layer is doped by adding dopants during the epitaxial process. In some embodiments, the epi-layer is doped by ion implantation after the epi-layer is formed. In some embodiments, the first well is formed by doping the substrate. In some embodiments, the doping is performed by ion implantation. In some embodiments, the first well has a dopant concentration ranging from 1×10¹² atoms/cm³ to 1×10¹⁴ atoms/cm³.

In some embodiments, the first well comprises n-type dopants. In some embodiments, the n-type dopants include phosphorus, arsenic or other suitable n-type dopants. In some embodiments, the n-type dopant concentration ranges from about 1×10¹² atoms/cm³ to about 1×10¹⁴ atoms/cm³.

In some embodiments, the formation of the source/drain features includes, a portion of the substrate is removed to form recesses at an edge of spacers, and a filling process is then performed by filling the recesses in the substrate. In some embodiments, the recesses are etched, for example, a wet etching or a dry etching, after removal of a pad oxide layer or a sacrificial oxide layer. In some embodiments, the etch process is performed to remove a top surface portion of the active region adjacent to an isolation region, such as an STI region. In some embodiments, the filling process is performed by an epitaxy or epitaxial (cpi) process. In some embodiments, the recesses are filled using a growth process which is concurrent with an etch process where a growth rate of the growth process is greater than an etch rate of the etch process. In some embodiments, the recesses are filled using a combination of growth process and etch process. For example, a layer of material is grown in the recess and then the grown material is subjected to an etch process to remove a portion of the material. Then a subsequent growth process is performed on the etched material until a desired thickness of the material in the recess is achieved. In some embodiments, the growth process continues until a top surface of the material is above the top surface of the substrate. In some embodiments, the growth process is continued until the top surface of the material is co-planar with the top surface of the substrate. In some embodiments, a portion of the first well is removed by an isotropic or an anisotropic etch process. The etch process selectively etches the first well without etching a gate structure and any spacers. In some embodiments, the etch process is performed using a reactive ion etch (RIE), wet etching, or other suitable techniques. In some embodiments, a semiconductor material is deposited in the recesses to form the source/drain features. In some embodiments, an epi process is performed to deposit the semiconductor material in the recesses. In some embodiments, the epi process includes a selective epitaxy growth (SEG) process, CVD process, molecular beam epitaxy (MBE), other suitable processes, and/or combination thereof. The epi process uses gaseous and/or liquid precursors, which interacts with a composition of substrate. In some embodiments, the source/drain features include epitaxially grown silicon (epi Si), silicon carbide, or silicon germanium. Source/drain features of the IC device associated with the gate structure are in-situ doped or undoped during the epi process in some instances. When source/drain features are undoped during the epi process, source/drain features are doped during a subsequent process in some instances. The subsequent doping process is achieved by an ion implantation, plasma immersion ion implantation, gas and/or solid source diffusion, other suitable processes, and/or combination thereof. In some embodiments, source/drain features are further exposed to annealing processes after forming source/drain features and/or after the subsequent doping process.

In some embodiments, operation 1202 further includes operation 1202a. In some embodiments, operation 1202a includes forming a first gate region of the first set of transistors. In some embodiments, the first gate region of the first set of transistors of method 1200 includes the set of gates 408.

In some embodiments, operation 1202 further includes operation 1202b. In some embodiments, operation 1202b includes forming a first insulating material on a first gate structure of the first set of transistors. In some embodiments, operation 1202b includes forming a first insulating material over at least the first gate structure of the first gate regions of the first set of transistors. In some embodiments, the first gate structure of the first gate regions of the first set of transistors includes at least one of gate 408b or 408c. In some embodiments, the first insulating material includes the set of insulating regions 494. In some embodiments, the first insulating material includes at least one of insulating region 494a or 494b.

In some embodiments, operation 1202 further includes operation 1202c. In some embodiments, operation 1202c includes forming a second gate region of the second set of transistors. In some embodiments, the second gate regions of the second set of transistors of method 1200 include the set of gates 406.

In some embodiments, the first and second gate region is between the drain region and the source region. In some embodiments, the first and second gate region is over the first well and the substrate. In some embodiments, fabricating the first and second gate regions of operations 1202a and 1202c include performing one or more deposition processes to form one or more dielectric material layers. In some embodiments, a deposition process includes a chemical vapor deposition (CVD), a plasma enhanced CVD (PECVD), an atomic layer deposition (ALD), or other process suitable for depositing one or more material layers. In some embodiments, fabricating the first and second gate regions includes performing one or more deposition processes to form one or more conductive material layers. In some embodiments, fabricating the first and second gate regions includes forming gate electrodes or dummy gate electrodes. In some embodiments, fabricating the gate regions includes depositing or growing at least one dielectric layer, e.g., gate dielectric. In some embodiments, gate regions are formed using a doped or non-doped polycrystalline silicon (or polysilicon). In some embodiments, the first and second gate regions include a metal, such as Al, Cu, W, Ti, Ta, TiN, TaN, NiSi, CoSi, other suitable conductive materials, or combinations thereof.

In some embodiments, forming the first insulating material on the first gate structure of the first set of transistors of operation 1202b includes performing one or more deposition processes to form one or more dielectric material layers and/or insulating material layers. In some embodiments, the one or more deposition processes to form one or more dielectric material layers and/or insulating material layers includes CVD, a PECVD, ALD, or other process suitable for depositing one or more material layers. In some embodiments, forming the first insulating material on the first gate structure of the first set of transistors includes performing one or more deposition processes to form one or more insulating material layers. In some embodiments, the first insulating material is a dielectric material. In some embodiments, the dielectric material includes silicon dioxide, silicon oxy-nitride, or the like.

In some embodiments, operation 1202a, 1202b and 1202c are replaced by forming the first gate regions of the first set of transistors and the second gate regions of the second set of transistors, removing a portion of the first gate regions of the first set of transistors and the second gate regions of the second set of transistors, and forming the first insulating material between the first gate structure of the first set of transistors and the second gate structure of the second set of transistors. In some embodiments, the gate removal process is a POLY cut process that includes one or more etching processes. In some embodiments, the gate removal process includes one or more etching processes suitable to remove a portion of the gate structure. In some embodiments, a mask is used to specify portions of the gate structure that are to be cut or removed. In some embodiments the mask is a hard mask. In some embodiments, the mask is a soft mask. In some embodiments, etching corresponds to plasma etching, reactive ion etching, chemical etching, dry etching, wet etching, other suitable processes, any combination thereof, or the like.

In some embodiments, operation 1202 further includes operation 1202d. In some embodiments, operation 1202d includes depositing a first conductive material on at least one of a first level, a second level or a third level thereby forming at least one of a corresponding first set of contacts, a second set of contacts or a third set of contacts.

In some embodiments, the first set of contacts, the second set of contacts and the third set of contacts are part of the first set of transistors and the second set of transistors.

In some embodiments, the first set of contacts includes the set of contacts 410.

In some embodiments, the second set of contacts includes the set of contacts 412.

In some embodiments, the third set of contacts includes the set of contacts 414.

In operation 1204 of method 1200, a first set of vias are formed on the front-side 403a of the wafer or substrate on a VD level or a VG level (e.g., VD or VG). In some embodiments, the first set of vias of method 1200 includes one or more portions at least the set of vias 420, 424, 920, 924, 1020 or 1024.

In some embodiments, operation 1204 includes forming a first set of self-aligned contacts (SACs) in the insulating layer over the front-side 403a of the wafer. In some embodiments, the first set of vias is electrically coupled to at least the first set of transistors or the second set of transistors.

In operation 1206 of method 1200, a second conductive material is deposited on the front-side 403a of the substrate on a fourth level thereby forming a fourth set of contacts on the front-side 403a of the wafer or substrate.

In some embodiments, operation 1206 includes at least depositing a first set of conductive regions over the front-side 403a of the integrated circuit. In some embodiments, the fourth set of contacts of method 1200 includes one or more portions of at least the set of contacts 416.

In operation 1208 of method 1200, a third conductive material is deposited on the front-side 403a of the substrate on a first metal level thereby forming a first set of conductors on the front-side 403a of the wafer or substrate on a first metal level (e.g., M0).

In some embodiments, operation 1208 includes at least depositing a second set of conductive regions over the front-side 403a of the integrated circuit. In some embodiments, the first set of conductors of method 1200 includes one or more portions of at least the set of conductors 430, 632, 930 or 1030.

In operation 1210 of method 1200, the first set of conductors is electrically coupled to the first or second set of transistors.

In some embodiments, operation 1210 includes electrically coupling the first set of conductors to the first or second set of transistors by the first set of vias.

In some embodiments, operation 1210 includes electrically coupling the first set of conductors to the second set of transistors from the front-side of the substrate.

In operation 1212 of method 1200, thinning is performed on the back-side 403b of the wafer or substrate. In some embodiments, operation 1212 includes a thinning process performed on the back-side 403b of the semiconductor wafer or substrate. In some embodiments, the thinning process includes a grinding operation and a polishing operation (such as chemical mechanical polishing (CMP)) or other suitable processes. In some embodiments, after the thinning process, a wet etching operation is performed to remove defects formed on the back-side 403b of the semiconductor wafer or substrate.

In operation 1214 of method 1200, a second set of vias are formed on the back-side 403b of the thinned wafer or substrate on a BVD level or a BVG level (e.g., BVD or BVG). In some embodiments, the second set of vias of method 1200 includes one or more portions at least the set of vias 422, 426, 922, 926, 1022 or 1026.

In some embodiments, operation 1214 includes forming a second set of self-aligned contacts (SACs) in the insulating layer over the back-side 403b of the wafer. In some embodiments, the second set of vias is electrically coupled to at least the first set of transistors or the second set of transistors.

In operation 1216 of method 1200, a fourth conductive material is deposited on the back-side 403b of the substrate on a second metal level thereby forming a second set of conductors on the back-side 403b of the wafer or substrate on a second metal level (e.g., BM0).

In some embodiments, operation 1216 includes at least depositing a third set of conductive regions over the back-side 403b of the integrated circuit. In some embodiments, the second set of conductors of method 1200 includes one or more portions of at least the set of conductors 432, 630, 932 or 1032.

In operation 1218 of method 1200, the second set of conductors is electrically coupled to the first or second set of transistors.

In some embodiments, operation 1218 includes electrically coupling the second set of conductors to the first or second set of transistors by the second set of vias.

In some embodiments, operation 1218 includes electrically coupling the second set of conductors to the first set of transistors from the back-side of the substrate.

In some embodiments, one or more of operations 1202, 1204, 1206, 1210, 1212, 1214 or 1216 of method 1200 include using a combination of photolithography and material removal processes to form openings in an insulating layer (not shown) over the substrate. In some embodiments, the photolithography process includes patterning a photoresist, such as a positive photoresist or a negative photoresist. In some embodiments, the photolithography process includes forming a hard mask, an antireflective structure, or another suitable photolithography structure. In some embodiments, the material removal process includes a wet etching process, a dry etching process, an RIE process, laser drilling or another suitable etching process. The openings are then filled with conductive material, e.g., copper, aluminum, titanium, nickel, tungsten, or other suitable conductive material. In some embodiments, the openings are filled using CVD, PVD, sputtering, ALD or other suitable formation process.

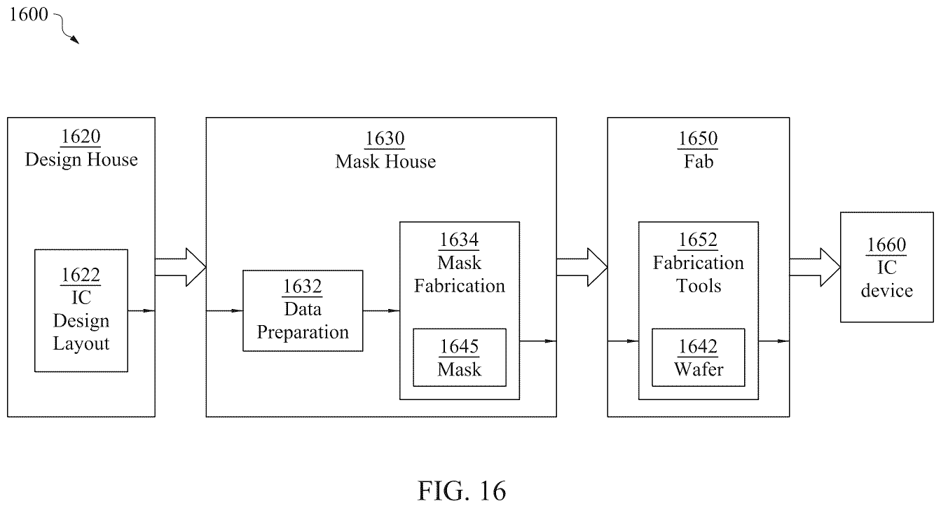

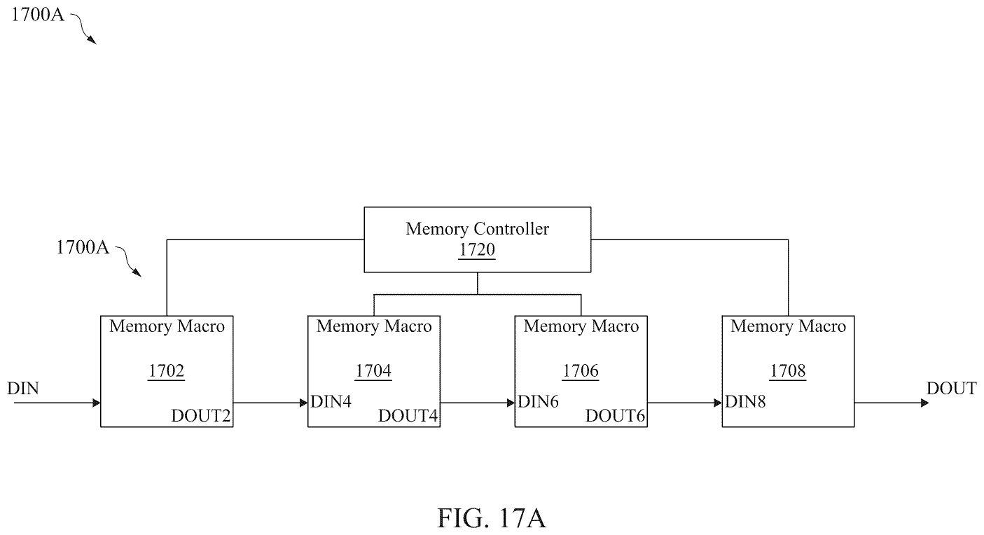

In some embodiments, at least one or more operations of method 1200 is performed by system 1600 of FIG. 16. In some embodiments, at least one method(s), such as method 1200 discussed above, is performed in whole or in part by at least one manufacturing system, including system 1600. One or more of the operations of method 1200 is performed by IC fab 1640 (FIG. 16) to fabricate IC device 1660. In some embodiments, one or more of the operations of method 1200 is performed by fabrication tools 1652 to fabricate wafer 1642.

In some embodiments, the conductive material includes copper, aluminum, titanium, nickel, tungsten, or other suitable conductive material. In some embodiments, the openings and trench are filled using CVD, PVD, sputtering, ALD or other suitable formation process. In some embodiments, after conductive material is deposited in one or more of operations 1202d, 1206, 1208 or 1216, the conductive material is planarized to provide a level surface for subsequent steps.

In some embodiments, one or more of the operations of method 1200, 1300 or 1400 is not performed.

One or more of the operations of methods 1300-1400 is performed by a processing device configured to execute instructions for manufacturing an integrated circuit, such as at least integrated circuit 100, 200A, 200B, 400, 600, 700, 800, 900 or 1000. In some embodiments, one or more operations of methods 1300-1400 is performed using a same processing device as that used in a different one or more operations of methods 1300-1400. In some embodiments, a different processing device is used to perform one or more operations of methods 1300-1400 from that used to perform a different one or more operations of methods 1300-1400. In some embodiments, other order of operations of method 1200, 1300 or 1400 is within the scope of the present disclosure. Method 1200, 1300 or 1400 includes exemplary operations, but the operations are not necessarily performed in the order shown. Operations in method 1200, 1300 or 1400 may be added, replaced, changed order, and/or eliminated as appropriate, in accordance with the spirit and scope of disclosed embodiments.

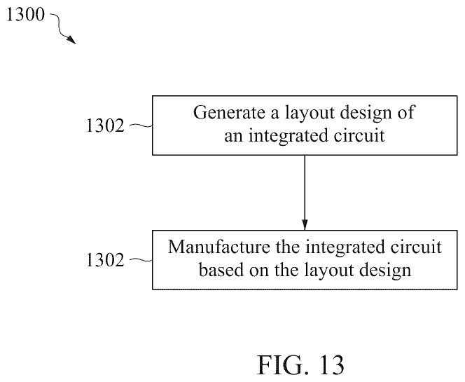

FIG. 13 is a flowchart of a method 1300 of forming or manufacturing an integrated circuit in accordance with some embodiments. It is understood that additional operations may be performed before, during, and/or after the method 1300 depicted in FIG. 13, and that some other operations may only be briefly described herein. In some embodiments, the method 1300 is usable to form integrated circuits, such as at least integrated circuit 100, 200A, 200B, 400, 600, 700, 800, 900 or 1000. In some embodiments, the method 1300 is usable to form integrated circuits having similar features and similar structural relationships as one or more of layout design 300 or 500.

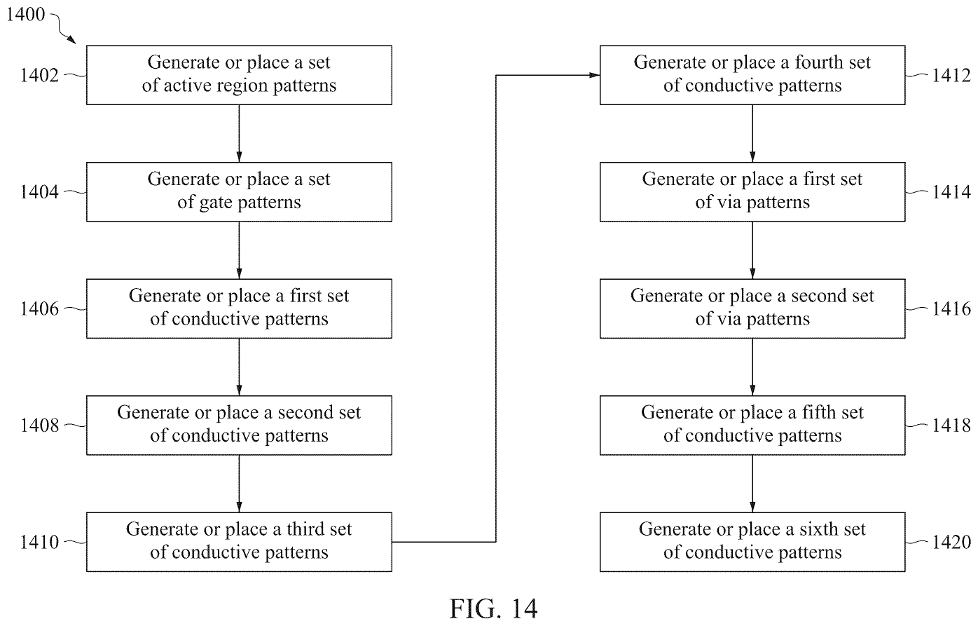

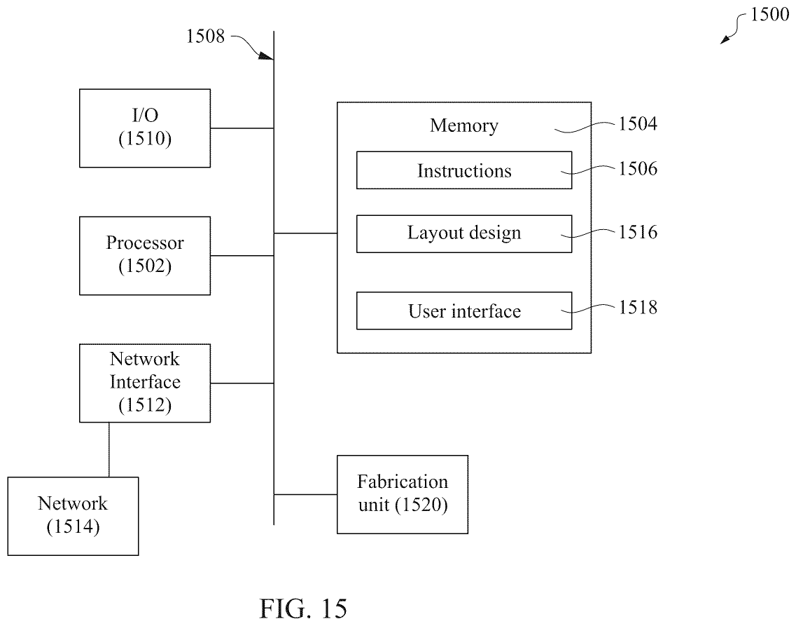

In operation 1302 of method 1300, a layout design of an integrated circuit is generated. Operation 1302 is performed by a processing device (e.g., processor 1502 (FIG. 15)) configured to execute instructions for generating a layout design. In some embodiments, the layout design of method 1300 includes one or more patterns of at least layout design 300 or 500, or one or more features similar to at least integrated circuit 100, 200A, 200B, 400, 600, 700, 800, 900 or 1000. In some embodiments, the layout design of the present application is in a graphic database system (GDSII) file format. In some embodiments, operation 1302 corresponds to method 1400 of FIG. 14.

In operation 1304 of method 1300, the integrated circuit is manufactured based on the layout design. In some embodiments, operation 1304 of method 1300 comprises manufacturing at least one mask based on the layout design, and manufacturing the integrated circuit based on the at least one mask. In some embodiments, operation 1304 corresponds to method 1200 of FIG. 12.

FIG. 14 is a flowchart of a method 1400 of generating a layout design of an integrated circuit, in accordance with some embodiments. It is understood that additional operations may be performed before, during, and/or after the method 1400 depicted in FIG. 14, and that some other processes may only be briefly described herein. In some embodiments, method 1400 is an embodiment of operation 1302 of method 1300. In some embodiments, method 1400 is usable to generate one or more layout patterns of at least layout design 300 or 500, or one or more features similar to at least integrated circuit 100, 200A, 200B, 400, 600, 700, 800, 900 or 1000.

In some embodiments, method 1400 is usable to generate one or more layout patterns having structural relationships including alignment, lengths and widths, as well as configurations and layers of at least layout design 300 or 500, or one or more features similar to at least integrated circuit 100, 200A, 200B, 400, 600, 700, 800, 900 or 1000, and similar detailed description will not be described in FIG. 14, for brevity.

In operation 1402 of method 1400, a set of active region patterns is generated or placed on the layout design. In some embodiments, the set of active region patterns of method 1400 includes at least portions of one or more patterns of the set of active region patterns 302 or 304. In some embodiments, the set of active region patterns of method 1400 includes one or more regions similar to the set of active regions 402 or 404. In some embodiments, the set of active region patterns of method 1400 includes one or more patterns or similar patterns in the OD layer.

In operation 1404 of method 1400, a set of gate patterns is generated or placed on the layout design. In some embodiments, the set of gate patterns of method 1400 includes at least portions of one or more patterns of the set of gate patterns 306 or 308. In some embodiments, the set of active gate patterns of method 1400 includes one or more regions similar to the set of gates 406 or 408. In some embodiments, the set of gate patterns of method 1400 includes at least portions of one or more patterns of the set of insulating patterns 394. In some embodiments, the set of gate patterns of method 1400 includes one or more regions similar to the set of insulating regions 494. In some embodiments, the set of gate patterns of method 1400 includes one or more patterns or similar patterns in the POLY layer.

In operation 1406 of method 1400, a first set of conductive patterns is generated or placed on the layout design. In some embodiments, the first set of conductive patterns of method 1400 includes at least portions of one or more patterns of the set of contact patterns 310. In some embodiments, the first set of conductive patterns of method 1400 includes one or more patterns similar to the set of contacts 410. In some embodiments, the first set of conductive patterns of method 1400 includes one or more patterns or similar patterns in the MD layer.

In operation 1408 of method 1400, a second set of conductive patterns is generated or placed on the layout design. In some embodiments, the second set of conductive patterns of method 1400 includes at least portions of one or more patterns of the set of contact patterns 312. In some embodiments, the second set of conductive patterns of method 1400 includes one or more patterns similar to the set of contacts 412. In some embodiments, the second set of conductive patterns of method 1400 includes one or more patterns or similar patterns in the BMD layer.

In operation 1410 of method 1400, a third set of conductive patterns is generated or placed on the layout design. In some embodiments, the third set of conductive patterns of method 1400 includes at least portions of one or more patterns of the set of contact patterns 314. In some embodiments, the third set of conductive patterns of method 1400 includes one or more patterns similar to the set of contacts 414. In some embodiments, the third set of conductive patterns of method 1400 includes one or more patterns or similar patterns in the MDLI layer.

In operation 1412 of method 1400, a fourth set of conductive patterns is generated or placed on the layout design. In some embodiments, the fourth set of conductive patterns of method 1400 includes at least portions of one or more patterns of the set of contact patterns 316. In some embodiments, the fourth set of conductive patterns of method 1400 includes one or more patterns similar to the set of contacts 416. In some embodiments, the fourth set of conductive patterns of method 1400 includes one or more patterns or similar patterns in the BCT layer.

In operation 1414 of method 1400, a first set of via patterns is generated or placed on the layout design. In some embodiments, the first set of via patterns of method 1400 includes at least portions of one or more patterns of the set of via patterns 320 or 324. In some embodiments, the first set of via patterns of method 1400 includes one or more via patterns similar to at least the set of vias 420, 424, 920, 924, 1020 or 1024. In some embodiments, the first set of via patterns of method 1400 includes one or more patterns or similar vias in the VG or VD layer.

In operation 1416 of method 1400, a second set of via patterns is generated or placed on the layout design. In some embodiments, the second set of via patterns of method 1400 includes at least portions of one or more patterns of the set of via patterns 322 or 326. In some embodiments, the second set of via patterns of method 1400 includes one or more via patterns similar to at least the set of vias 422, 426, 922, 926, 1022 or 1026. In some embodiments, the second set of via patterns of method 1400 includes one or more patterns or similar vias in the BVG or BVD layer.

In operation 1418 of method 1400, a fifth set of conductive patterns is generated or placed on the layout design. In some embodiments, the fifth set of conductive patterns of method 1400 includes at least portions of one or more patterns of at least the set of conductive patterns 330 or 532. In some embodiments, the fifth set of conductive patterns of method 1400 includes one or more conductive patterns similar to at least the set of conductors 430, 632, 930 or 1030. In some embodiments, the fifth set of conductive patterns of method 1400 includes one or more patterns or similar conductors in the M0 layer.

In operation 1420 of method 1400, a sixth set of conductive patterns is generated or placed on the layout design. In some embodiments, the sixth set of conductive patterns of method 1400 includes at least portions of one or more patterns of at least the set of conductive patterns 332 or 530. In some embodiments, the sixth set of conductive patterns of method 1400 includes one or more conductive patterns similar to at least the set of conductors 432, 630, 932 or 1032. In some embodiments, the sixth set of conductive patterns of method 1400 includes one or more patterns or similar conductors in the BM0 layer.

FIG. 15 is a schematic view of a system 1500 for designing an IC layout design and manufacturing an IC circuit in accordance with some embodiments.

In some embodiments, system 1500 generates or places one or more IC layout designs described herein. System 1500 includes a hardware processor 1502 and a non-transitory, computer readable storage medium 1504 (e.g., memory 1504) encoded with, i.e., storing, the computer program code 1506, i.e., a set of executable instructions 1506. Computer readable storage medium 1504 is configured for interfacing with manufacturing machines for producing the integrated circuit. The processor 1502 is electrically coupled to the computer readable storage medium 1504 via a bus 1508. The processor 1502 is also electrically coupled to an I/O interface 1510 by bus 1508. A network interface 1512 is also electrically connected to the processor 1502 via bus 1508. Network interface 1512 is connected to a network 1514, so that processor 1502 and computer readable storage medium 1504 are capable of connecting to external elements via network 1514. The processor 1502 is configured to execute the computer program code 1506 encoded in the computer readable storage medium 1504 in order to cause system 1500 to be usable for performing a portion or all of the operations as described in method 1300-1400.

In some embodiments, the processor 1502 is a central processing unit (CPU), a multi-processor, a distributed processing system, an application specific integrated circuit (ASIC), and/or a suitable processing unit.

In some embodiments, the computer readable storage medium 1504 is an electronic, magnetic, optical, electromagnetic, infrared, and/or a semiconductor system (or apparatus or device). For example, the computer readable storage medium 1504 includes a semiconductor or solid-state memory, a magnetic tape, a removable computer diskette, a random access memory (RAM), a read-only memory (ROM), a rigid magnetic disk, and/or an optical disk. In some embodiments using optical disks, the computer readable storage medium 1504 includes a compact disk-read only memory (CD-ROM), a compact disk-read/write (CD-R/W), and/or a digital video disc (DVD).

In some embodiments, the storage medium 1504 stores the computer program code 1506 configured to cause system 1500 to perform method 1300-1400. In some embodiments, the storage medium 1504 also stores information needed for performing method 1300-1400 as well as information generated during performing method 1300-1400, such as layout design 1516, user interface 1518 and fabrication unit 1520, and/or a set of executable instructions to perform the operation of method 1300-1400. In some embodiments, layout design 1516 comprises one or more of layout patterns of at least layout design 300 or 500, or features similar to at least integrated circuit 100, 200A, 200B, 400, 600, 700, 800, 900 or 1000.

In some embodiments, the storage medium 1504 stores instructions (e.g., computer program code 1506) for interfacing with manufacturing machines. The instructions (e.g., computer program code 1506) enable processor 1502 to generate manufacturing instructions readable by the manufacturing machines to effectively implement method 1300-1400 during a manufacturing process.

System 1500 includes I/O interface 1510. I/O interface 1510 is coupled to external circuitry. In some embodiments, I/O interface 1510 includes a keyboard, keypad, mouse, trackball, trackpad, and/or cursor direction keys for communicating information and commands to processor 1502.

System 1500 also includes network interface 1512 coupled to the processor 1502. Network interface 1512 allows system 1500 to communicate with network 1514, to which one or more other computer systems are connected. Network interface 1512 includes wireless network interfaces such as BLUETOOTH, WIFI, WIMAX, GPRS, or WCDMA; or wired network interface such as ETHERNET, USB, or IEEE-2094. In some embodiments, method 1300-1400 is implemented in two or more systems 1500, and information such as layout design, and user interface are exchanged between different systems 1500 by network 1514.

System 1500 is configured to receive information related to a layout design through I/O interface 1510 or network interface 1512. The information is transferred to processor 1502 by bus 1508 to determine a layout design for producing at least integrated circuit 100, 200A, 200B, 400, 600, 700, 800, 900 or 1000. The layout design is then stored in computer readable medium 1504 as layout design 1516. System 1500 is configured to receive information related to a user interface through I/O interface 1510 or network interface 1512. The information is stored in computer readable medium 1504 as user interface 1518. System 1500 is configured to receive information related to a fabrication unit 1520 through I/O interface 1510 or network interface 1512. The information is stored in computer readable medium 1504 as fabrication unit 1520. In some embodiments, the fabrication unit 1520 includes fabrication information utilized by system 1500. In some embodiments, the fabrication unit 1520 corresponds to mask fabrication 1134 of FIG. 16.

In some embodiments, method 1300-1400 is implemented as a standalone software application for execution by a processor. In some embodiments, method 1300-1400 is implemented as a software application that is a part of an additional software application. In some embodiments, method 1300-1400 is implemented as a plug-in to a software application. In some embodiments, method 1300-1400 is implemented as a software application that is a portion of an EDA tool. In some embodiments, method 1300-1400 is implemented as a software application that is used by an EDA tool. In some embodiments, the EDA tool is used to generate a layout of the integrated circuit device. In some embodiments, the layout is stored on a non-transitory computer readable medium. In some embodiments, the layout is generated using a tool such as VIRTUOSO® available from CADENCE DESIGN SYSTEMS, Inc., or another suitable layout generating tool. In some embodiments, the layout is generated based on a netlist which is created based on the schematic design. In some embodiments, method 1300-1400 is implemented by a manufacturing device to manufacture an integrated circuit using a set of masks manufactured based on one or more layout designs generated by system 1500. In some embodiments, system 1500 is a manufacturing device configured to manufacture an integrated circuit using a set of masks manufactured based on one or more layout designs of the present disclosure. In some embodiments, system 1500 of FIG. 15 generates layout designs of an integrated circuit that are smaller than other approaches. In some embodiments, system 1500 of FIG. 15 generates layout designs of integrated circuit structure that occupy less area and provide better routing resources than other approaches.

FIG. 16 is a block diagram of an integrated circuit (IC) manufacturing system 1600, and an IC manufacturing flow associated therewith, in accordance with at least one embodiment of the present disclosure. In some embodiments, based on a layout diagram, at least one of (A) one or more semiconductor masks or (B) at least one component in a layer of a semiconductor integrated circuit is fabricated using manufacturing system 1600.

In FIG. 16, IC manufacturing system 1600 (hereinafter “system 1600”) includes entities, such as a design house 1620, a mask house 1630, and an IC manufacturer/fabricator (“fab”) 1640, that interact with one another in the design, development, and manufacturing cycles and/or services related to manufacturing an IC device 1660. The entities in system 1600 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, one or more of design house 1620, mask house 1630, and IC fab 1640 is owned by a single larger company. In some embodiments, one or more of design house 1620, mask house 1630, and IC fab 1640 coexist in a common facility and use common resources.

Design house (or design team) 1620 generates an IC design layout 1622. IC design layout 1622 includes various geometrical patterns designed for an IC device 1660. The geometrical patterns correspond to patterns of metal, oxide, or semiconductor layers that make up the various components of IC device 1660 to be fabricated. The various layers combine to form various IC features. For example, a portion of IC design layout 1622 includes various IC features, such as an active region, gate electrode, source electrode and drain electrode, metal lines or vias of an interlayer interconnection, and openings for bonding pads, to be formed in a semiconductor substrate (such as a silicon wafer) and various material layers disposed on the semiconductor substrate. Design house 1620 implements a proper design procedure to form IC design layout 1622. The design procedure includes one or more of logic design, physical design or place and route. IC design layout 1622 is presented in one or more data files having information of the geometrical patterns. For example, IC design layout 1622 can be expressed in a GDSII file format or DFII file format.

Mask house 1630 includes data preparation 1632 and mask fabrication 1634. Mask house 1630 uses IC design layout 1622 to manufacture one or more masks 1645 to be used for fabricating the various layers of IC device 1660 according to IC design layout 1622. Mask house 1630 performs mask data preparation 1632, where IC design layout 1622 is translated into a representative data file (RDF). Mask data preparation 1632 provides the RDF to mask fabrication 1634. Mask fabrication 1634 includes a mask writer. A mask writer converts the RDF to an image on a substrate, such as a mask (reticle) 1645 or a semiconductor wafer 1642. The IC design layout 1622 is manipulated by mask data preparation 1632 to comply with particular characteristics of the mask writer and/or requirements of IC fab 1640. In FIG. 16, mask data preparation 1632 and mask fabrication 1634 are illustrated as separate elements. In some embodiments, mask data preparation 1632 and mask fabrication 1634 can be collectively referred to as mask data preparation.

In some embodiments, mask data preparation 1632 includes optical proximity correction (OPC) which uses lithography enhancement techniques to compensate for image errors, such as those that can arise from diffraction, interference, other process effects and the like. OPC adjusts IC design layout 1622. In some embodiments, mask data preparation 1632 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1632 includes a mask rule checker (MRC) that checks the IC design layout that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout to compensate for limitations during mask fabrication 1634, which may undo part of the modifications performed by OPC in order to meet mask creation rules.

In some embodiments, mask data preparation 1632 includes lithography process checking (LPC) that simulates processing that will be implemented by IC fab 1640 to fabricate IC device 1660. LPC simulates this processing based on IC design layout 1622 to create a simulated manufactured device, such as IC device 1660. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (DOF), mask error enhancement factor (MEEF), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout 1622.

It should be understood that the above description of mask data preparation 1632 has been simplified for the purposes of clarity. In some embodiments, data preparation 1632 includes additional features such as a logic operation (LOP) to modify the IC design layout according to manufacturing rules. Additionally, the processes applied to IC design layout 1622 during data preparation 1632 may be executed in a variety of different orders.

After mask data preparation 1632 and during mask fabrication 1634, a mask 1645 or a group of masks 1645 are fabricated based on the modified IC design layout 1622. In some embodiments, mask fabrication 1634 includes performing one or more lithographic exposures based on IC design layout 1622. In some embodiments, an electron-beam (e-beam) or a mechanism of multiple e-beams is used to form a pattern on a mask (photomask or reticle) 1645 based on the modified IC design layout 1622. The mask 1645 can be formed in various technologies. In some embodiments, the mask 1645 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary version of mask 1645 includes a transparent substrate (e.g., fused quartz) and an opaque material (e.g., chromium) coated in the opaque regions of the binary mask. In another example, the mask 1645 is formed using a phase shift technology. In the phase shift mask (PSM) version of mask 1645, various features in the pattern formed on the mask are configured to have proper phase difference to enhance the resolution and imaging quality. In various examples, the phase shift mask can be attenuated PSM or alternating PSM. The mask(s) generated by mask fabrication 1634 is used in a variety of processes. For example, such a mask(s) is used in an ion implantation process to form various doped regions in the semiconductor wafer, in an etching process to form various etching regions in the semiconductor wafer, and/or in other suitable processes.

IC fab 1640 is an IC fabrication entity that includes one or more manufacturing facilities for the fabrication of a variety of different IC products. In some embodiments, IC Fab 1640 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry entity.

IC fab 1640 includes wafer fabrication tools 1652 (hereinafter “fabrication tools 1652”) configured to execute various manufacturing operations on semiconductor wafer 1642 such that IC device 1660 is fabricated in accordance with the mask(s), e.g., mask 1645. In various embodiments, fabrication tools 1652 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 1640 uses mask(s) 1645 fabricated by mask house 1630 to fabricate IC device 1660. Thus, IC fab 1640 at least indirectly uses IC design layout 1622 to fabricate IC device 1660. In some embodiments, a semiconductor wafer 1642 is fabricated by IC fab 1640 using mask(s) 1645 to form IC device 1660. In some embodiments, the IC fabrication includes performing one or more lithographic exposures based at least indirectly on IC design 1622. Semiconductor wafer 1642 includes a silicon substrate or other proper substrate having material layers formed thereon. Semiconductor wafer 1642 further includes one or more of various doped regions, dielectric features, multilevel interconnects, and the like (formed at subsequent manufacturing steps).

System 1600 is shown as having design house 1620, mask house 1630 or IC fab 1640 as separate components or entities. However, it is understood that one or more of design house 1620, mask house 1630 or IC fab 1640 are part of the same component or entity.

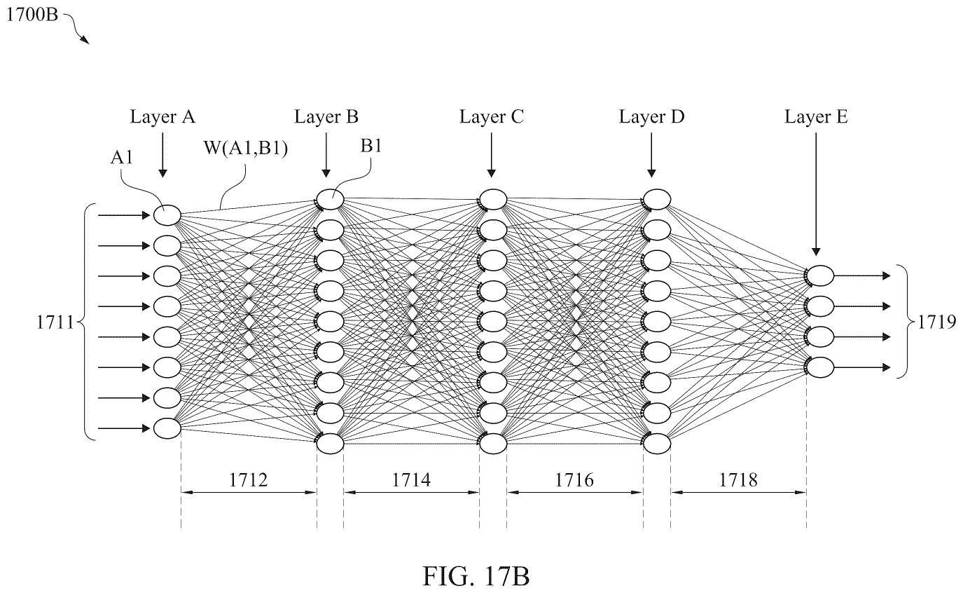

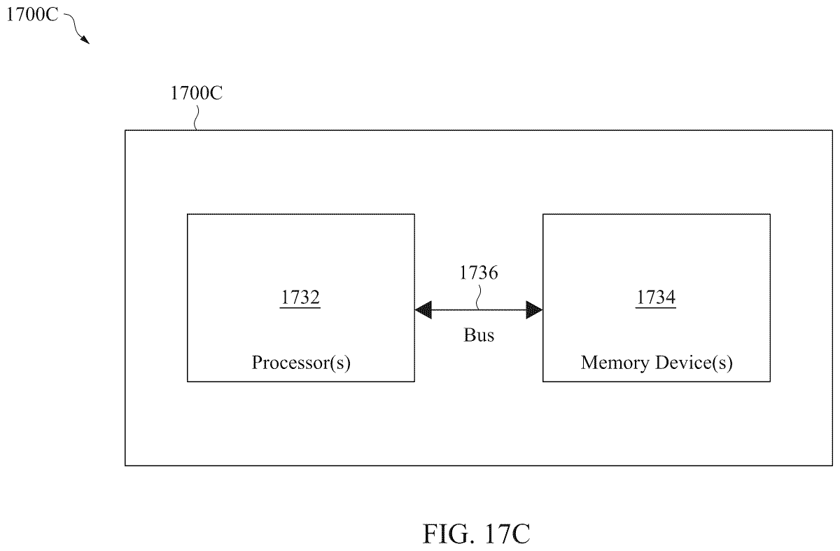

FIG. 17A is a schematic diagram of a memory device 1700A, in accordance with some embodiments.

The memory device 1700A comprises memory macros 1702, 1704, 1706, 1708 and memory controller 1720. In some embodiments, one or more of the memory macros 1702, 1704, 1706, 1708 correspond to at least one of memory cell array 110AR, integrated circuit 400, integrated circuit 600, memory cell 812a, memory cell 812b, memory cell 812c, memory cell 812d, integrated circuit 900 or integrated circuit 1000, and/or memory controller 1720 corresponds to at least one of local control circuit 110LC or global control circuit 100GC.

In the example configuration in FIG. 17A, the memory controller 1720 is a common memory controller for the memory macros 1702, 1704, 1706, 1708. In at least one embodiment, at least one of the memory macros 1702, 1704, 1706, 1708 has its own memory controller. The number of four memory macros in the memory device 1700A is an example. Other configurations are within the scopes of various embodiments.

The memory macros 1702, 1704, 1706, 1708 are coupled to each other in sequence, with output data of a preceding memory macro being input data for a subsequent memory macro. For example, input data DIN are input into the memory macro 1702. The memory macro 1702 performs one or more CIM operations based on the data signal A and data signal B stored in the memory macro 1702, and generates output data DOUT2 as results of the CIM operations. The output data DOUT2 are supplied as input data DIN4 of the memory macro 1704. The memory macro 1704 performs one or more CIM operations based on the input data DIN4 and one of the data signal A and data signal B stored in the memory macro 1704, and generates output data DOUT4 as results of the CIM operations. The output data DOUT4 are supplied as input data DIN6 of the memory macro 1706. The memory macro 1706 performs one or more CIM operations based on the input data DIN6 and one of the data signal A and data signal B stored in the memory macro 1706, and generates output data DOUT6 as results of the CIM operations. The output data DOUT6 are supplied as input data DIN8 of the memory macro 1708. The memory macro 1708 performs one or more CIM operations based on the input data DIN8 and one of the data signal A and data signal B stored in the memory macro 1708, and generates output data DOUT as results of the CIM operations.

One or more of the input data DIN, DIN4, DIN6, DIN8 correspond to the data signal A or data signal B described herein, and/or one or more of the output data DOUT2, DOUT4, DOUT6, DOUT correspond to the output signal Vo described herein, and similar detailed description is therefore omitted. In at least one embodiment, the described configuration of the memory macros 1702, 1704, 1706, 1708 implements a neural network. In at least one embodiment, one or more advantages described herein are achievable by the memory device 1700A.

Other configurations or quantities of elements in memory device 1700A are within the scope of the present disclosure.

FIG. 17B is a schematic diagram of a neural network 1700B, in accordance with some embodiments.

The neural network 1700B comprises a plurality of layers A-E each comprising a plurality of nodes (or neurons). The nodes in successive layers of the neural network 1700B are connected with each other by a matrix or array of connections. For example, the nodes in layers A and B are connected with each other by connections in a matrix 1712, the nodes in layers B and C are connected with each other by connections in a matrix 1714, the nodes in layers C and D are connected with each other by connections in a matrix 1716, and the nodes in layers D and E are connected with each other by connections in a matrix 1718. Layer A is an input layer configured to receive input data 1711. The input data 1711 propagate through the neural network 1700B, from one layer to the next layer via the corresponding matrix of connections between the layers. As the data propagate through the neural network 1700B, the data undergo one or more computations, and are output as output data 1719 from layer E which is an output layer of the neural network 1700B. Layers B, C, D between input layer A and output layer E are sometimes referred to as hidden or intermediate layers. The number of layers, number of matrices of connections, and number of nodes in each layer in FIG. 17B are examples. Other configurations are within the scopes of various embodiments. For example, in at least one embodiment, the neural network 1700B includes no hidden layer, and has an input layer connected by one matrix of connections to an output layer. In one or more embodiments, the neural network 1700B has one, two, or more than three hidden layers.

In some embodiments, the matrices 1712, 1714, 1716, 1718 are correspondingly implemented by the memory macros 1702, 1704, 1706, 1708, the input data 1711 corresponds to the data signal A or B, and the output data 1719 corresponds to the output signal Vo, and similar detailed description is therefore omitted. Specifically, in the matrix 1712, a connection between a node in layer A and another node in layer B has a corresponding weight. For example, a connection between node A1 and node B1 has a weight W(A1,B1) which corresponds to a weight value stored in the memory array of the memory macro 1702. The memory macros 1704, 1706, 1708 are configured in a similar manner. The weight data W in one or more of the memory macros 1702, 1704, 1706, 1708 are updated, e.g., by a processor and through the memory controller 1720, as machine learning is performed using the neural network 1700B. One or more advantages described herein are achievable in the neural network 1700B implemented in whole or in part by one or more memory macros and/or memory devices in accordance with some embodiments.

Other configurations or quantities of elements in neural network 1700B are within the scope of the present disclosure.

FIG. 17C is a schematic diagram of an integrated circuit (IC) device 1700C, in accordance with some embodiments.

The IC device 1700C is an embodiment of memory device 100 of FIG. 1 or memory device 1700A of FIG. 17A, and similar detailed description is therefore omitted.

The IC device 1700C comprises one or more hardware processors 1732, one or more memory devices 1734 coupled to the processors 1732 by one or more buses 1736. In some embodiments, the one or more hardware processors 1732 is useable as one or more components in controller 120 of FIG. 1 or memory controller 1720 in FIG. 17A, and similar detailed description is therefore omitted. In some embodiments, the one or more memory devices 1734 is useable as one or more components in memory circuit 102 of FIG. 1, memory macro 110 of FIG. 1 or one or more of memory macros 1702, 1704, 1706 or 1708 in FIG. 17A, and similar detailed description is therefore omitted.

In some embodiments, the IC device 1700C comprises one or more further circuits including, but not limited to, cellular transceiver, global positioning system (GPS) receiver, network interface circuitry for one or more of Wi-Fi, USB, Bluetooth, or the like. Examples of the processors 1732 include, but are not limited to, a central processing unit (CPU), a multi-core CPU, a neural processing unit (NPU), a graphics processing unit (GPU), a digital signal processor (DSP), a field-programmable gate array (FPGA), an application-specific integrated circuit (ASIC), other programmable logic devices, a multimedia processor, an image signal processors (ISP), or the like. Examples of the memory devices 1734 include one or more memory devices and/or memory macros described herein. In at least one embodiment, each of the processors 1732 is coupled to a corresponding memory device among the memory devices 1734.

Because the one or more of the memory devices 1734 are CIM memory devices, various computations are performed in the memory devices which reduces the computing workload of the corresponding processor, reduces memory access time, and improves performance. In at least one embodiment, the IC device 1700C is a system-on-a-chip (SOC). In at least one embodiment, one or more advantages described herein are achievable by the IC device 1700C.

Other configurations or quantities of elements in IC device 1700C are within the scope of the present disclosure.

One aspect of this description relates to a circuit. In some embodiments, the circuit includes a first dual-port cell. In some embodiments, the circuit further includes a first word line extending in a first direction, being coupled to the first dual-port cell, and being on at least a first metal layer above a front-side of a substrate. In some embodiments, the circuit further includes a second word line extending in the first direction, being coupled to the first dual-port cell, and being on at least a second metal layer below a back-side of the substrate opposite from the front-side of the substrate. In some embodiments, the circuit further includes a first bit line extending in the first direction, being coupled to the first dual-port cell, and being on at least the first metal layer. In some embodiments, the circuit further includes a second bit line extending in the first direction, being coupled to the first dual-port cell, and being on at least the first metal layer, and being separated from the first bit line in a second direction different from the first direction. In some embodiments, the circuit further includes a third bit line extending in the first direction, being coupled to the first dual-port cell, and being on at least the second metal layer.

Another aspect of this description relates to a circuit. In some embodiments, the circuit includes a first cell, a second cell adjacent to the first cell, and a first set of word lines extending in a first direction, being coupled to the first cell and the second cell, and being on at least a first metal layer above a front-side of a substrate. In some embodiments, the circuit further includes a second set of word lines extending in the first direction, being coupled to the first cell and the second cell, and being on at least a second metal layer below a back-side of the substrate opposite from the front-side of the substrate. In some embodiments, the circuit further includes a first set of bit lines extending in the first direction, being coupled to the first cell and the second cell, and being on at least the first metal layer. In some embodiments, the circuit further includes a second set of bit lines extending in the first direction, being coupled to the first cell and the second cell, and being on at least the second metal layer. In some embodiments, the first set of bit lines overlap the first cell and the second cell.

Still another aspect of this description relates to a method of fabricating a circuit. In some embodiments, the method includes fabricating a first set of transistors and a second set of transistors in a front-side of a substrate, the first set of transistors being stacked above the second set of transistors. In some embodiments, the method further includes depositing a first conductive material on the front-side of the substrate on a first metal level thereby forming a first set of conductors, the first set of conductors being electrically coupled to at least the first set of transistors, the first set of transistors being configured to receive a first word line signal or a first bit line signal from the first set of conductors. In some embodiments, the method further includes electrically coupling the first set of conductors to the first set of transistors. In some embodiments, the method further includes performing thinning on a back-side of the substrate opposite from the front-side. In some embodiments, the method further includes depositing a second conductive material on the back-side of the thinned substrate on a second metal level thereby forming a second set of conductors, the second set of conductors being electrically coupled to at least the second set of transistors, the second set of transistors being configured to receive a second word line signal or a second bit line signal from the second set of conductors. In some embodiments, the method further includes electrically coupling the second set of conductors to the second set of transistors.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A circuit, comprising:
a first dual-port cell;
a first word line extending in a first direction, being coupled to the first dual-port cell, and being on at least a first metal layer above a front-side of a substrate;
a second word line extending in the first direction, being coupled to the first dual-port cell, and being on at least a second metal layer below a back-side of the substrate opposite from the front-side of the substrate;
a first bit line extending in the first direction, being coupled to the first dual-port cell, and being on at least the first metal layer;
a second bit line extending in the first direction, being coupled to the first dual-port cell, and being on at least the first metal layer, and being separated from the first bit line in a second direction different from the first direction; and
a third bit line extending in the first direction, being coupled to the first dual-port cell, and being on at least the second metal layer.

2. The circuit of claim 1, wherein the first dual-port cell comprises:
a first pass-gate transistor of a first type, and the first pass-gate transistor including a first gate on a first level;
a second pass-gate transistor of the first type, and the second pass-gate transistor including a second gate on the first level, the second gate being separated from the first gate in at least the first direction or the second direction;
a third pass-gate transistor of a second type different from the first type, and the third pass-gate transistor including a third gate on a second level below the first level;
a fourth pass-gate transistor of the first type, and the second pass-gate transistor including a fourth gate on the first level, the fourth gate being separated from the third gate in at least the first direction or the second direction; and
a first pair of cross-coupled inverters coupled to and between the first pass-gate transistor, the second pass-gate transistor, the third pass-gate transistor and the fourth pass-gate transistor.

3. The circuit of claim 2, wherein the first dual-port cell, further comprises:
a first gate isolation layer between the first gate and the third gate; and
a second gate isolation layer between the second gate and the fourth gate.

4. The circuit of claim 2, wherein
the first word line is coupled to the first gate of the first pass-gate transistor and the second gate of the second pass-gate transistor, and being configured to supply a first word line signal to the first pass-gate transistor and the second pass-gate transistor; and
the second word line is coupled to the third gate of the third pass-gate transistor, and being configured to supply a second word line signal to the third pass-gate transistor.

5. The circuit of claim 4, wherein
the first word line comprises:
a first conductor extending in the first direction, being coupled to the first gate of the first pass-gate transistor, and being on the first metal layer; and
a second conductor extending in the first direction, being coupled to the second gate of the second pass-gate transistor, being on the first metal layer, and being separated from the first conductor in at least the first direction or the second direction; and
the second word line comprises:
a third conductor extending in the first direction, being coupled to the third gate of the third pass-gate transistor, and being on the second metal layer.

6. The circuit of claim 5, further comprising:
a first via electrically coupling the first conductor and the first gate together, the first via being between the first conductor and the first gate;
a second via electrically coupling the second conductor and the second gate together, the second via being between the second conductor and the second gate; and
a third via electrically coupling the third conductor and the third gate together, the third via being between the third conductor and the third gate.

7. The circuit of claim 2, wherein
the first bit line comprises:
a first conductor extending in the first direction, being configured to receive a first bit line signal, being on the first metal layer, and being coupled to a first source/drain of the first pass-gate transistor;
the second bit line comprises:
a second conductor extending in the first direction, being configured to receive a second bit line signal, being on the first metal layer, being coupled to a first source/drain of the second pass-gate transistor, and being separated from the first conductor in the second direction; and
the third bit line comprises:
a third conductor extending in the first direction, being configured to receive a third bit line signal, being on the second metal layer, and being coupled to a first source/drain of the third pass-gate transistor.

8. The circuit of claim 7, wherein the first dual-port cell, further comprises:
a first contact extending in the second direction, being on a third level above the front-side of the substrate, and being electrically coupled to the first source/drain of the first pass-gate transistor;
a second contact extending in the second direction, being on the third level, the second contact being electrically coupled to the first source/drain of the second pass-gate transistor;
a third contact extending in the second direction, being on a fourth level different from the third level, and being electrically coupled to the first source/drain of the third pass-gate transistor;
a fourth contact extending in the second direction, being on the fourth level, and being electrically coupled to a first source/drain of the fourth pass-gate transistor; and
a fifth contact extending in the second direction, being on the fourth level, and being electrically coupled to a first source/drain of a first transistor of the first pair of cross-coupled inverters.

9. The circuit of claim 8, further comprising:
a fourth conductor extending in the first direction, being configured to receive a supply voltage, being on the second metal layer, and being coupled to the first source/drain of the fourth pass-gate transistor and the first source/drain of the first transistor of the first pair of cross-coupled inverters, and being separated from the third conductor in at least the first direction and the second direction.

10. The circuit of claim 9, wherein the first dual-port cell further comprises:
a first via electrically coupling the first conductor and the first contact together, the first via being between the first conductor and the first contact;
a second via electrically coupling the second conductor and the second contact together, the second via being between the second conductor and the second contact;
a third via electrically coupling the third conductor and the third contact together, the third via being between the third conductor and the third contact;
a fourth via electrically coupling the fourth conductor and the fourth contact together, the fourth via being between the fourth conductor and the fourth contact; and
a fifth via electrically coupling the fourth conductor and the fifth contact together, the fifth via being between the fourth conductor and the fifth contact.

11. A circuit, comprising:
a first cell;
a second cell adjacent to the first cell;
a first set of word lines extending in a first direction, being coupled to the first cell and the second cell, and being on at least a first metal layer above a front-side of a substrate;
a second set of word lines extending in the first direction, being coupled to the first cell and the second cell, and being on at least a second metal layer below a back-side of the substrate opposite from the front-side of the substrate;
a first set of bit lines extending in the first direction, being coupled to the first cell and the second cell, and being on at least the first metal layer; and
a second set of bit lines extending in the first direction, being coupled to the first cell and the second cell, and being on at least the second metal layer;
wherein the first set of bit lines overlap the first cell and the second cell.

12. The circuit of claim 11, wherein the first cell comprises:
a first pass-gate transistor of a first type, and the first pass-gate transistor including a first gate on a first level;
a second pass-gate transistor of the first type, and the second pass-gate transistor including a second gate on the first level, the second gate being separated from the first gate in at least the first direction or a second direction different from the first direction;
a third pass-gate transistor of a second type different from the first type, and the third pass-gate transistor including a third gate on a second level below the first level;
a fourth pass-gate transistor of the first type, and the second pass-gate transistor including a fourth gate on the first level, the fourth gate being separated from the third gate in at least the first direction or the second direction; and
a first pair of cross-coupled inverters coupled to and between the first pass-gate transistor, the second pass-gate transistor, the third pass-gate transistor and the fourth pass-gate transistor.

13. The circuit of claim 12, wherein the second cell comprises:
a fifth pass-gate transistor of the first type, and the fifth pass-gate transistor including a fifth gate on the first level;
a sixth pass-gate transistor of the first type, and the sixth pass-gate transistor including a sixth gate on the first level, the sixth gate being separated from the fifth gate in at least the first direction or the second direction;
a seventh pass-gate transistor of the second type, and the seventh pass-gate transistor including a seventh gate on the second level;
an eighth pass-gate transistor of the first type, and the eighth pass-gate transistor including an eighth gate on the first level, the eighth gate being separated from the seventh gate in at least the first direction or the second direction; and
a second pair of cross-coupled inverters coupled to and between the fifth pass-gate transistor, the sixth pass-gate transistor, the seventh pass-gate transistor and the eighth pass-gate transistor.

14. The circuit of claim 13, wherein
the first cell, further comprises:
a first gate isolation layer between the first gate and the third gate; and
a second gate isolation layer between the second gate and the fourth gate; and
the second cell, further comprises:
a third gate isolation layer between the fifth gate and the seventh gate; and
a fourth gate isolation layer between the sixth gate and the eighth gate.

15. The circuit of claim 13, wherein the first set of word lines comprises:
a first word line coupled to the first gate of the first pass-gate transistor and the second gate of the second pass-gate transistor, and being configured to supply a first word line signal to the first pass-gate transistor and the second pass-gate transistor;
a second word line coupled to the fifth gate of the fifth pass-gate transistor and the sixth gate of the sixth pass-gate transistor, and being configured to supply a second word line signal to the fifth pass-gate transistor and the sixth pass-gate transistor;
a third word line coupled to the third gate of the third pass-gate transistor, and being configured to supply a third word line signal to the third pass-gate transistor; and
a fourth word line coupled to the seventh gate of the seventh pass-gate transistor, and being configured to supply a fourth word line signal to the seventh pass-gate transistor.

16. The circuit of claim 15, wherein
the first word line comprises:
a first conductor extending in the first direction, being coupled to the first gate of the first pass-gate transistor, and being on the first metal layer; and
a second conductor extending in the first direction, being coupled to the second gate of the second pass-gate transistor, being on the first metal layer, and being separated from the first conductor in at least the first direction or the second direction;
the second word line comprises:
a third conductor extending in the first direction, being coupled to the fifth gate of the fifth pass-gate transistor, and being on the first metal layer; and
a fourth conductor extending in the first direction, being coupled to the sixth gate of the sixth pass-gate transistor, being on the first metal layer, and being separated from the third conductor in at least the first direction or the second direction;
the third word line comprises:
a fifth conductor extending in the first direction, being coupled to the third gate of the third pass-gate transistor, and being on the second metal layer; and
the fourth word line comprises:
a sixth conductor extending in the first direction, being coupled to the seventh gate of the seventh pass-gate transistor, and being on the second metal layer.

17. The circuit of claim 13, wherein
the first set of bit lines comprises:
a first bit line extending in the first direction, being coupled to the first cell and the second cell, being on at least the first metal layer, and overlapping the first cell and the second cell; and
a second bit line extending in the first direction, being coupled to the first cell and the second cell, and being on at least the first metal layer, being separated from the first bit line in the second direction, and overlapping the first cell and the second cell; and
the second set of bit lines comprises:
a third bit line extending in the first direction, being coupled to the first cell, being on at least the second metal layer, and being overlapped by the first cell; and
a fourth bit line extending in the first direction, being coupled to the second cell, being on at least the second metal layer, and being overlapped by the second cell.

18. The circuit of claim 17, wherein
the first bit line comprises:
a first conductor extending in the first direction, being configured to receive a first bit line signal, being on the first metal layer, and being coupled to a first source/drain of the first pass-gate transistor and a fifth source/drain of the fifth pass-gate transistor;
the second bit line comprises:
a second conductor extending in the first direction, being configured to receive a second bit line signal, being on the first metal layer, being coupled to a first source/drain of the second pass-gate transistor and a sixth source/drain of the sixth pass-gate transistor, and being separated from the first conductor in the second direction;
the third bit line comprises:
a third conductor extending in the first direction, being configured to receive a third bit line signal, being on the second metal layer, and being coupled to a first source/drain of the third pass-gate transistor; and
a fourth conductor extending in the first direction, being configured to receive a fourth bit line signal, being on the second metal layer, and being coupled to a first source/drain of the seventh pass-gate transistor.

19. The circuit of claim 18, further comprising:
a fifth conductor extending in the first direction, being configured to receive a supply voltage, being on the second metal layer, and being coupled to the first source/drain of the fourth pass-gate transistor, a first source/drain of a first transistor of the first pair of cross-coupled inverters, the first source/drain of the eighth pass-gate transistor and a first source/drain of a first transistor of the second pair of cross-coupled inverters, and being separated from the third conductor and the fourth conductor in the second direction.

20. A method of fabricating a circuit, the method comprising:
fabricating a first set of transistors and a second set of transistors in a front-side of a substrate, the first set of transistors being stacked above the second set of transistors;
depositing a first conductive material on the front-side of the substrate on a first metal level thereby forming a first set of conductors, the first set of conductors being electrically coupled to at least the first set of transistors, the first set of transistors being configured to receive a first word line signal or a first bit line signal from the first set of conductors;
electrically coupling the first set of conductors to the first set of transistors;
performing thinning on a back-side of the substrate opposite from the front-side;
depositing a second conductive material on the back-side of the thinned substrate on a second metal level thereby forming a second set of conductors, the second set of conductors being electrically coupled to at least the second set of transistors, the second set of transistors being configured to receive a second word line signal or a second bit line signal from the second set of conductors; and
electrically coupling the second set of conductors to the second set of transistors.
